(19) United States
(12) Patent Application Publication
(10) Pub. No.: US 2009/0300461 A1
(43) Pub. Date: Dec. 3, 2009

(54) DEVICE, METHOD AND COMPUTER PROGRAM PRODUCT FOR COMMUNICATION

(76) Inventors: Gadi Shor, Tel Aviv (IL); Sorin Goldenberg, Ness Ziona (IL)

Correspondence Address: Pearl Cohen Zedek Latzer, LLP, 1500 Broadway, 12th Floor, New York, NY, 10036, US

(21) Appl. No.: 12/473,287

(22) Filed: May 28, 2009

Related U.S. Application Data
(60) Provisional application No. 61/093,374, filed on Sep. 1, 2008.
(60) Provisional application No. 61/056,886, filed on May 29, 2008.

(51) Int. Cl. H03M 13/05; G06F 11/10

(52) U.S. Cl. 714/752; 714/E11.032

(57) ABSTRACT

A transmitter may include an encoder configured to encode a data bit vector to provide an codeword that includes a first codeword portion and a second codeword portion; wherein the first codeword portion is decodable by a first parity check process to yield the data bit vector; wherein the codeword is decodable by a second parity check process to yield the data bit vector; and a communication module, for transmitting the codeword.

### CROSS REFERENCE TO RELATED APPLICATIONS

This application claims the benefit of U.S. Application Ser. No. 61/093,374, filed on Sep. 1, 2008 (and entitled “Device, Method And Computer Program Product For WiMedia Very High Data Rates”) and of U.S. Application Ser. No. 61/056,886, filed on May 29, 2008 (and entitled “Device, Method And Computer Program Product For WiMedia Very High Data Rates”), each of which are incorporated in their entirety herein by reference.

### BACKGROUND OF THE INVENTION

Transmission of data using parity check processes includes transmission of a codeword that includes information (also referred to as data) that can be arranged as a data bit vector, as well as additional redundancy information, which enables testing of the received codeword at the receiving party side using different parity checks, and correcting errors that may be encountered through transmission. A group of such parity check processes are known as low-density parity check (LDPC) processes. A group of LDPC processes uses different LDPC codes.

The encoded information is usually modulated and transmitted over a communication channel. An example for such modulation that is known in the art is 16 Quadrate Amplitude Modulation (QAM modulation), which is represented in FIG. 7. Other modulations, as well as different QAM modulations, Dual-Carrier Modulation (DCM) and Modified Dual-Carrier Modulation (MDCM) modulations, and so forth may be used for modulating the encoded information for transmission of which.

### SUMMARY OF THE INVENTION

A transmitter is provided. It may include, for example: (a) an encoder configured to encode a data bit vector to provide an codeword that includes a first codeword portion and a second codeword portion; wherein the first codeword portion is decodable by a first parity check process to yield the data bit vector; wherein the codeword is decodable by a second parity check process to yield the data bit vector; and (b) a communication module, for transmitting the codeword.

A method for transmitting information is provided. The method can include, for example: (a) encoding a data bit vector to provide an codeword that includes a first codeword portion and a second codeword portion; wherein the first codeword portion is decodable by a first parity check process to yield the data bit vector; wherein the codeword is decodable by a second parity check process to yield the data bit vector; and (b) transmitting the codeword.

A receiver is provided. It may include, for example: (a) a communication module configured to attempt to receive a first codeword portion and a second codeword portion of a transmitted codeword, wherein the first codeword portion is of a first length; (b) a processor for selecting between a first parity check process and a second parity check process, wherein the first parity check process includes parity check of messages of the first length and the second parity check process includes parity check for longer messages; and (c) a decoder configured to decode at least a portion of the codeword by the selected parity check process, to receive a decoded data bit vector.

A method for receiving information provided. The method can include, for example: (a) attempting to receive a first codeword portion and a second codeword portion of a transmitted codeword, wherein the first codeword portion is of a first length; (b) selecting between a first parity check process and a second parity check process, wherein the first parity check process includes parity check of messages of the first length and the second parity check process includes parity check for longer messages; and (c) decoding at least a portion of the codeword by the selected parity check process, to receive a decoded data bit vector.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 illustrates a transmitter, according to an embodiment of the invention;

FIG. 2 illustrates a method for transmitting information, according to an embodiment of the invention;

FIG. 3 illustrates a receiver, according to an embodiment of the invention;

FIG. 4 illustrates a timing diagram which is implemented by a decoder, according to an embodiment of the invention;

FIG. 5 illustrates a decoder, according to an embodiment of the invention;

FIG. 6 illustrates a method for receiving information, according to an embodiment of the invention;

FIG. 7 is a representation of a prior art constellation of a 16-QAM modulation scheme;

FIGS. 8A-8I are graphical representations of various LDPC codes according to various embodiments of the invention; and

FIGS. 9I-9A illustrate tables A, B, C, D, E, F, G, H and I—each representing an LDPC code, according to various embodiments of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

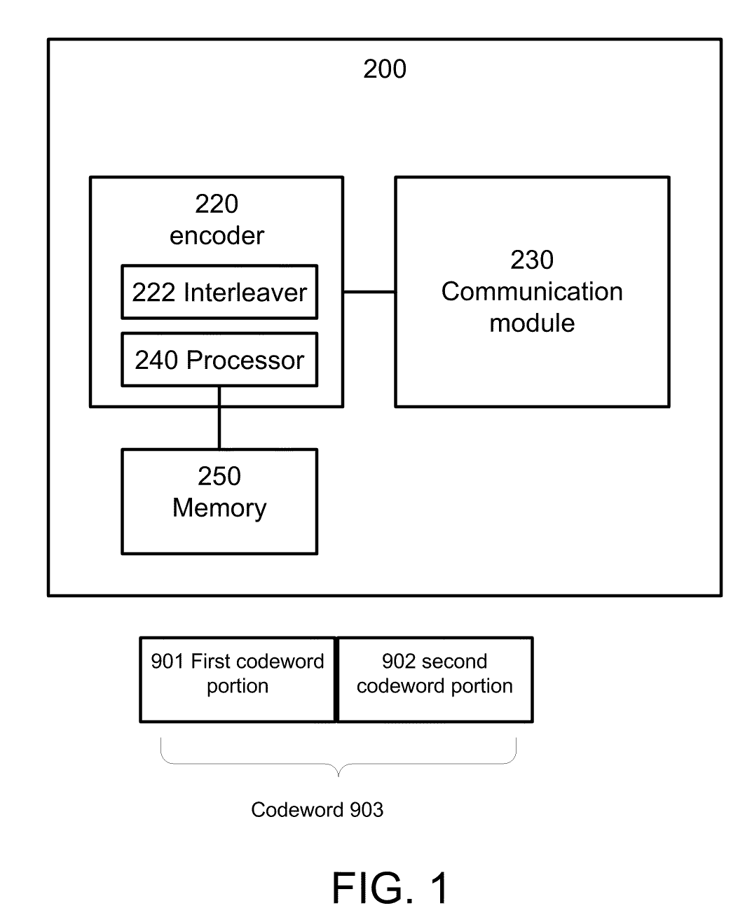

FIG. 1 illustrates transmitter 200, according to an embodiment of the invention. It is noted that, according to several embodiments of the invention, transmitter 200 can carry out methods described herein such as method 500. It is noted that transmitter 200 may be implemented in a single unit with a receiver (which may and may not have the functionalities of receiver 300), but this is not necessarily so. FIG. 1 also illustrates codeword 903 that include first codeword portion 901 and second codeword portion 902.

It is noted that, according to an embodiment of the invention, transmitter 200 and/or components thereof (e.g. encoder 220, and at least some modules of communication module 230) may be implemented in software being operated on processor 240 (a general purpose processor or a dedicated processor). Processor 240 is illustrated as being a part of encoder 220, but it is noted that it may operate only some of the functionalities of encoder 220, as well as functionalities of other modules such as communication module 230. According to an embodiment of the invention, transmitter 200 may include memory module 250 which may store different types of information. Memory 250 may store information process information used for the encoding, and/or other functionalities of modules of transmitter 200. Memory 250 may also be used for including or storing instructions, e.g., computer-executable instructions, which when executed by a processor or controller, carry out methods disclosed herein. Transmitter 200 may include an article such as a computer or processor readable medium, or a computer or processor storage medium, such as for example memory 250 (which may be implemented as, e.g. a disk drive, or a USB flash memory), encoding, including or storing instructions, e.g., computer-executable instructions, which when executed by a processor or controller, carry out methods disclosed herein.

Transmitter 200 may include at least one encoder 220 which is configured to encode a data bit vector to provide an codeword that includes a first codeword portion (which has a first length) and a second codeword portion (which has a second length, which may and may not be shorter than the first length); wherein the first codeword portion is decodable by a first parity check process to yield the data bit vector; wherein the codeword is decodable by a second parity check process to yield the data bit vector; and at least one communication module 230, for transmitting the codeword.

Transmitter 200 may include additional components such as components that are known in the art when implementing communication devices (e.g. a power source, different interfaces, and so forth). Such additional components, if not essential to the understanding of the invention, are not illustrated in the drawings or individually detailed, for the clarity of the disclosure.

It is noted that according to an embodiments of the invention, encoder 220 may be implemented by multiple encoding modules (not illustrated) which may and may not operate in parallel, for encoding different portions of the data bit vector (or of multiple data bit vectors), and/or for encoding portions of the data bit vector (or data bit vectors) in multiple encoding stages. It is noted that different techniques of implementing multiple encoding modules may be implemented by a person who is skilled in the art.

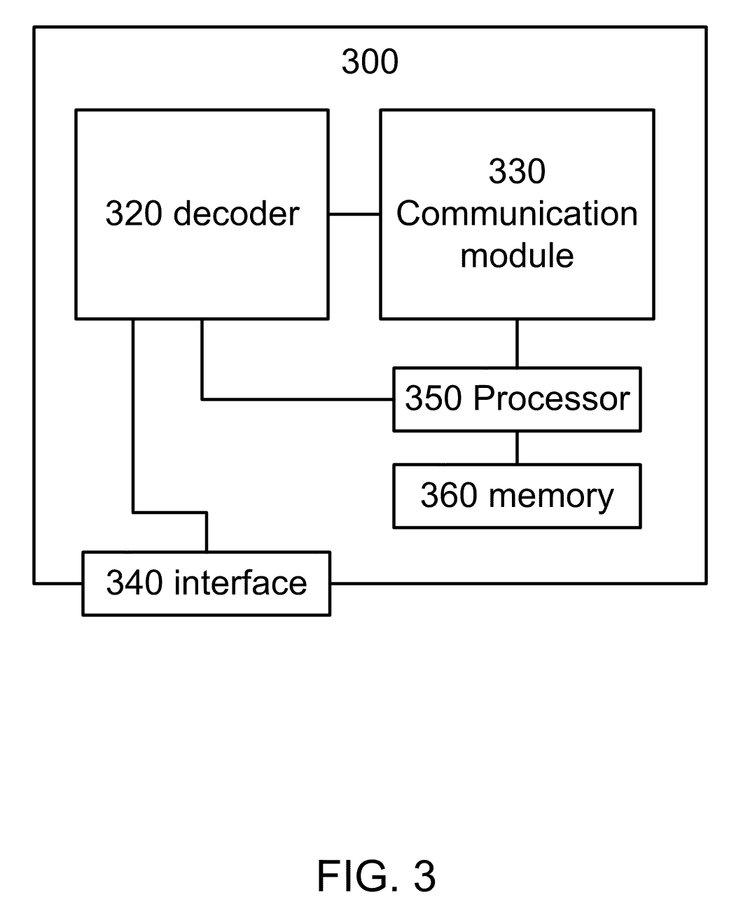

It is noted that the data bit vector to be encoded may be received from an external source, or generated by one or more components of transmitter 200. According to an embodiment of the invention, the encoder may include an input interface (not shown) for receiving the data bit vector from an external source. It is noted that transmitter 200 may not transmit the data bit vector itself, but rather an encoded version of which—referred to as a codeword—that may include parity information so as to improve the chances of receiving the correct data bit vector at a receiving end (e.g. a receiver such as receiver 300, FIG. 3), after being decoded.

It is noted that the data bit vector may be an ordered string of binary bits, but it is not necessarily so. It is noted that the receiving (or the generating) of the data bit vector may be a part of a recurring process of receiving (or generating) a stream of data to be transmitted. According to such an implementation, the stream of data may be divided into data bit vectors, or the dividing into data bit vectors may be carried out locally by transmitter 200.

The length of the data bit vector may conveniently match a predetermined fixed length, which may be used in an encoding process. For example, in a low-density parity-check (LDPC) transmission scheme, standard lengths which are being used are 648, 1296 and 1944 bits per data bit vector in IEEE 802.11n Wireless LAN Medium Access Control MAC and Physical Layer PHY specifications; IEEE 802.11n-D1.0, 2006; and 576-2304 bits per data bit vector in IEEE 802.16e Air Interface for Fixed and Mobile Broadband Wireless Access Systems.

It is noted that encoder 220 may conveniently encode the data bit vector using a predetermined encoding process, which is independent of the content of the specific data bit vector encoded. For example, such an encoding process may be an equivalent of multiplying the data bit vector (when it is written as a vector) by a predetermined generator matrix, to provide a vector that includes the codeword information. In such a case, the generator matrix may be the same for every data bit vector that may be encoded.

It is noted that the encoder may conveniently encode many data bit vectors (some of which may be encoded at least partially concurrently, according to an embodiment of the invention), wherein all the data bit vectors encoded are encoded using the same predetermined encoding process. It should be noted that such a predetermined encoding process may matches a predetermined decoding process that is used by a receiver of the codeword.

It is noted that conveniently, both the first and the second parity check processes may be independent of the content of the specific data bit vector. For example, such a decoding processes may include verification processes which are equivalents of multiplying the codeword or variations thereof (or first codeword portion or variations thereof, respectively), when written as a vector, by the corresponding predetermined decoding matrix, to provide a vector that includes the original data bit vector information. In such a case, the decoding matrixes may be the same for every data bit vector that may be encoded.

It is noted that encoder 220 may conveniently be configured to encode many data bit vectors, wherein all the data bit vectors encoded are decodable using the same predetermined first and second decoding processes.

Conveniently, each of the first and the second codeword portions may be an undivided sequence of the codeword (e.g. the first codeword portion may include the first 1024 bits of the codeword, and the second codeword portion may include the remainder of the codeword), even though this is not necessarily so. It is noted that according to different embodiments of the invention, encoder 220 (or another module such as dedicated interleaver 222) may and may not interleave information (e.g. bits) between the first and the second codeword portions when generating the first and the second codeword portions. It is noted that, according to an embodiment of the invention, an interleaving is carried out by encoder 220 during the encoding of the codeword (e.g. by a proper design of the encoding matrix).

It is noted that the second codeword portion may include information that is duplication of a part of the first codeword portion, but this is not necessarily so. Conveniently, the first and the second codeword portions may include substantially different redundancy information.

According to an embodiment of the invention, encoder 220 may be adapted to provide the codeword that is decodable by a second first low-density parity check (LDPC) process to yield the data bit vector, wherein the first codeword portion is decodable using a first LDPC process to yield the data bit vector.

It is noted that, according to an embodiment of the invention, encoder 220 may be adapted to provide the codeword which may and may not be decodable by a second LDPC process that complies with the WIMEDIA standard and/or conventions to yield the data bit vector, wherein the first codeword portion is decodable using a first LDPC process that complies with the WIMEDIA standard and/or conventions to yield the data bit vector.

The encoding of the data bit vector by encoder 220 could be viewed, according to an embodiment of the invention, as creating the first codeword portion that includes information of the data bit vector (either in its original form or a processed form of which), as well as redundancy information (which is conveniently parity-check information), as well as the second codeword portion that includes additional redundancy information (which is conveniently additional parity-check information).

It is noted that some such codes that may be used for encoding, according to several embodiments of the invention, are disclosed in relation to tables A through H.

Referring now to the transmitting of the codeword by communication module 230. Communication module 230 may be adapted, according to different embodiments of the invention, to transmit the codeword (and potentially other information as well) using one or more of many transmission techniques that are known in the art—such as but not limited to wired transmission, wireless transmission, direct transmission, indirect transmission, band-hopping transmission, spread spectrum transmission, bursts transmission, and so forth.

It is noted that, according to an embodiment of the invention, communication module 230 may transmit the codeword in response to the outcomes a determination (which is usually carried out by transmitter 200, but may also be received from an external source such as a receiver) whether to transmit the codeword, or only the first code-word portion (which is, as aforementioned, decodable by itself).

Such determination whether to transmit the codeword or just the first codeword portion (or, according to an embodiment of the invention, to transmit a codeword that includes the first codeword portion and a part of the second codeword portion) may depend on different factors, such as a state of encoder 220 (and/or communication module 230), a state of one or more receivers of the transmission, a state of a communication channel used for transmission, and so forth. Such determination may be implemented, for example, if in some scenarios transmission of additional redundancy information is enabled, and in other it is disabled or non-beneficial. For example, the determining may depend on available bandwidth of the communication channel, on channel quality (e.g. bit-error-rate of the channel), on capabilities of a receiver, and so forth.

According to an embodiment of the invention, communication module 230 may be adapted (and possibly configured) to transmit the first and the second codeword portions in different communication channels (e.g. the first codeword portion in one or more first communication channels, and the second codeword portion in one or more second communication channels). For example, as the second codeword portion may include additional redundancy information, which is not necessary for a successful decoding of the data bit vector (at least in some scenarios), it may be transmitted in a communication channel with lesser quality. According to an embodiment of the invention, it is noted that all expected receivers (e.g. both “standard” or “regular” receivers, and “dedicated” receivers) are expected to be able to receive the first codeword portion on the first communication channel, to which additional information can not be added (e.g. due to channel bandwidth, or receiver design), while some of the possible expected receivers (e.g. receiver 300) may implement reception of additional redundancy information using the other second communication channel.

According to an embodiment of the invention, communication module 230 may be adapted to transmit the first codeword portion in a first communication channel (e.g. in data sub-channels or sub-carries of which), and transmitting the second codeword portion in one or more sub-channels (or sub-carriers) of the first communication channel in which the first codeword portion is not transmitted (e.g. to transmit the second codeword portion in the some or all of the guard tones of the first communication channel).

According to an embodiment of the invention, communication module 230 may be adapted to transmit the first codeword portion in a first communication channel (which may be a WIMEDIA compliant channel, but not necessarily so)—e.g. using the data tones of the communication channel, while transmitting the second codeword portion using the guard-tones of the first communication channel. For example, according to an embodiment of the invention, the first codeword portion may be transmitted over 100 data tones used in a WIMEDIA compliant channel, while the second codeword portion may be transmitted over 10 guard tones used in a WIMEDIA compliant channel. According to an embodiment of the invention, not all the guard tones are used for transmission of the second codeword portion, e.g. so that some guard tones may serve as regular guard tones.

It is noted according to different embodiments of the invention, communication module 230 may implement different types of modulations, without limiting the scope of the invention. According to an embodiment of the invention, communication module 230 can transmit the codeword using quadrature amplitude modulation (QAM) modulation of an order of at least 16 (e.g. 16-QAM, 256-QAM). In such modulation, transmission of different symbols may be characterized with different error-rates.

According to an embodiment of the invention in which such modulation is used (or other modulation in which transmission of different bits or symbols is expected to have different error rates), encoder 220 can provide the codeword in which information of a first bit is more useful for at least one of the first and the second parity-check processes than information of a second bit, wherein communication module 230 transmits the first bit in a first symbol and the second bit in a second symbol, wherein the first symbol is less susceptible to errors during the transmitting than the second symbol.

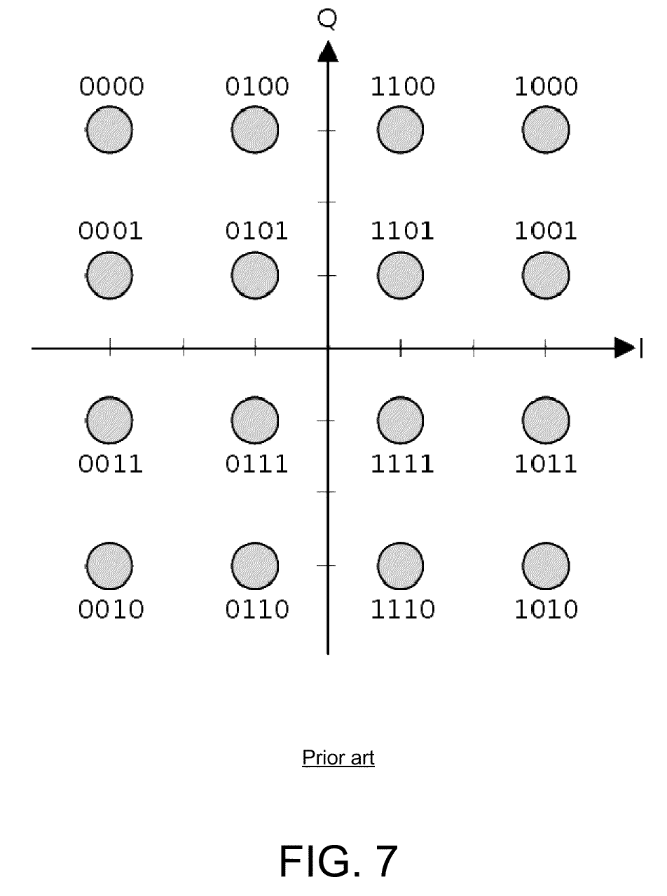

It is noted that since the transmitting is conveniently sequential, the matching of such “useful bits” to such “more secure symbols” should usually be implemented during the encoding process. Referring, for example, to the 16-QAM constellation diagram offered in FIG. 7, the first symbol may be any symbols out of symbols 0000, 0100, 1011 and 1110, while the second symbol may be any of 0101, 1101, 0111, and 1111. This may require an embodiment of the invention in which the encoding is directed to place the “1”s and the “0” in the “right” places in the code-word. Other coding schemes may be used.

It is noted that codes offered below which may be used for the encoding and which are more efficient in 16-QAM modulation than codes which are not designed for such modulation, are also efficient for other modulations such as QPSK and 64-QAM.

It is noted that communication module 230 may also efficiently transmit the codeword, according to an embodiment of the invention, using DCM and MDCM.

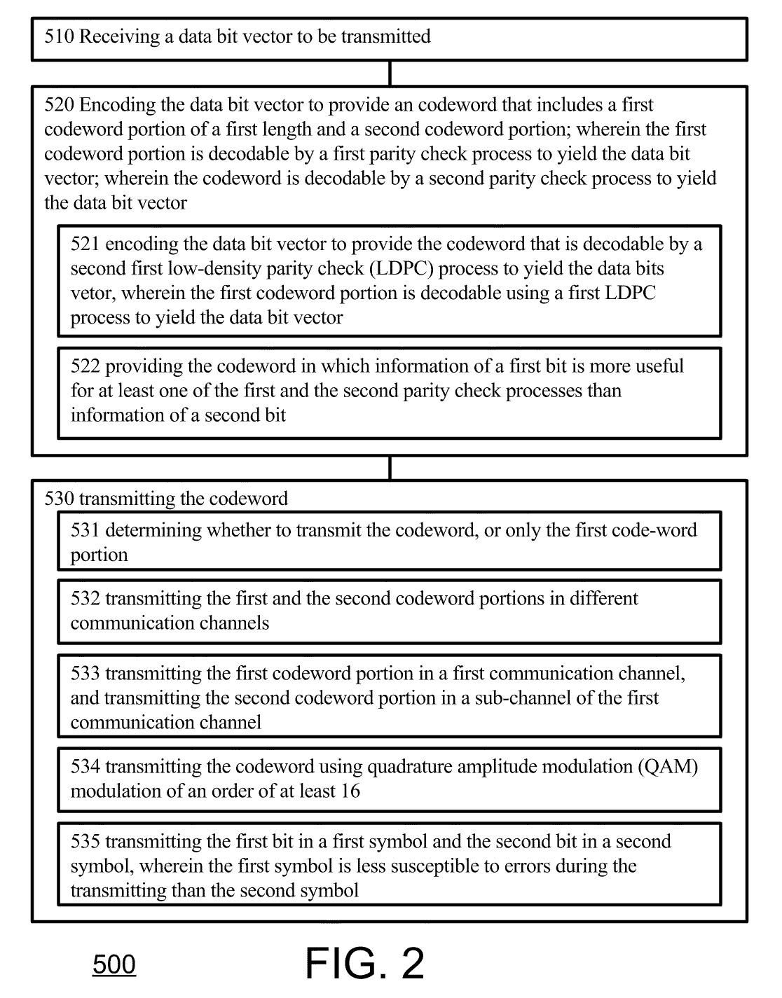

FIG. 2 illustrates method 500 for transmitting information, according to an embodiment of the invention.

According to an embodiment of the invention, method 500 may start by receiving a data bit vector to be transmitted. According to method 500, the data bit vector may not be transmitted as is, but rather an encoded version of which—a codeword—which include parity information so as to improve the chances of receiving the correct data bit vector at the receiving end, after being decoded.

It is noted that the data bit vector may be an ordered string of binary bits, but it is not necessarily so. It is noted that the receiving of the data bit vector may be a part of a recurring process of receiving a stream of data to be transmitted. According to such an implementation, the stream of data may be divided into data bit vectors, or the dividing into data bit vectors may be carried out locally (by a system that carries out other stages of method 500). It is noted that the data bit vector may not necessarily be received from an external source, as it could be generated locally.

The length of the data bit vector may conveniently match a predetermined fixed length, which is used in an encoding process. For example, in a low-density parity-check (LDPC) transmission scheme, standard lengths which are being used are 648, 1296 and 1944 bits per data bit vector in IEEE 802.11n Wireless LAN Medium Access Control MAC and Physical Layer PEY specifications; IEEE 802.11n-D1.0, 2006; and 576-2304 bits per data bit vector in IEEE 802.16e Air Interface for Fixed and Mobile Broadband Wireless Access Systems.

Method 500 continues (or starts) with stage 520 of encoding a data bit vector (e.g. the data bit vector received in stag 510), to provide an codeword that includes a first codeword portion (which is of a first length) and a second codeword portion (which is of a second length that may and may not be shorter than the first length); wherein the first codeword portion is decodable by a first parity check process to yield the data bit vector; wherein the codeword is decodable by a second parity check process to yield the data bit vector.

Referring to the examples set forth in the previous figures, the encoding may be carried out by an encoder such as encoder 220, although other devices may be used.

It is noted that the encoding is conveniently carried out by a predetermined encoding process, which is independent on the content of the specific data bit vector encoded. For example, such an encoding process may be an equivalent of multiplying the data bit vector (when it is written as a vector) by a predetermined generator matrix, to provide a vector that includes the codeword information. In such a case, the generator matrix is conveniently the same for every data bit vector that may be encoded.

According to an embodiment of the invention, method 500 may include encoding many data bit vectors, wherein all the data bit vectors encoded are encoded using the same predetermined encoding process. It should be noted that conveniently, such a predetermined encoding process matches a predetermined decoding process that is used by a receiver of the codeword.

It is noted that conveniently, both the first and the second parity check processes are independent of the content of the specific data bit vector. For example, such decoding processes may include verification processes which are equivalents of multiplying the codeword or variations thereof (or first codeword portion or variations thereof, respectively), when written as a vector, by the corresponding predetermined decoding matrix, to provide a vector that includes the original data bit vector information. In such a case, the decoding matrixes are conveniently the same for every data bit vector that may be encoded.

According to an embodiment of the invention, method 500 may include encoding many data bit vectors, wherein all the data bit vectors encoded are decodable using the same predetermined first and second decoding processes.

Conveniently, each of the first and the second codeword portions may be an undivided sequence of the codeword (e.g. the first codeword portion may include the first 1024 bits of the codeword, and the second codeword portion may include the remainder of the codeword), even though this is not necessarily so. The generating of the first and the second codeword portions may and may not include interleaving of information (e.g. bits) between the first and the second codeword portions. It is noted that, according to an embodiment of the invention, an interleaving is implemented during the encoding of the codeword (e.g. by a proper design of the encoding matrix).

It is noted that the second codeword portion may include information that is a duplication of a part of the first codeword portion, but this is not necessarily so. Conveniently, the first and the second codeword portions may include substantially different redundancy information.

According to an embodiment of the invention, the encoding of the data bit vector may include stage 521 of encoding the data bit vector to provide the codeword that is decodable by a second first low-density parity check (LDPC) process to yield the data bit vector, wherein the first codeword portion is decodable using a first LDPC process to yield the data bit vector.

It is noted that, according to an embodiment of the invention, the encoding of the data bit vector may include the data bit vector to provide the codeword that includes the first codeword portion and the second codeword portion; wherein the first codeword portion is decodable using a first low-density parity check (LDPC) process that complies with the WIMEDTA standard and/or conventions to yield the data bit vector; wherein the codeword may also (but not necessarily) be decodable by a second LDPC process that complies with the WMEFDIA standard and/or conventions to yield the data bit vector.

The encoding of the data bit vector could be viewed, according to an embodiment of the invention, as creating the first codeword portion that includes information of the data bit vector (either in its original form or a processed form of which), as well as redundancy information (which is conveniently parity-check information), as well as the second codeword portion that includes additional redundancy information (which is conveniently additional parity-check information).

It is noted that some such codes that may be used for encoding, according to several embodiments of the invention, are disclosed in relation to tables A through H.

After the encoding of the data bit vector to provide the codeword, stage 530 may be carried out, that includes transmitting the codeword. The transmitting may be carried out in any of many transmission techniques that are known in the art—such as but not limited to wired transmission, wireless transmission, direct transmission, indirect transmission, band-hopping transmission, spread spectrum transmission, bursts transmission, and so forth. Referring to the examples set forth in the previous figures, the transmitting may be carried out by a communication module, such as communication module 230.

It is noted that, according to an embodiment of the invention, the transmitting of the codeword may depend on the outcomes of stage 531 of method 530, in which it is determined whether to transmit the codeword, or only the first code-word portion (which is, as aforementioned, decodable by itself).

Such determination may depend on different factors, such as a state of an encoder (and/or transmitter) that carries out stages of method 500, a state of one or more receivers of the transmission, a state of a communication channel used for transmission, and so forth. Such determination may be implemented, for example, if in some scenarios transmission of additional redundancy information is enabled, and in other it is disabled or non-beneficial. For example, the determining may depend on available bandwidth of the communication channel, on channel quality (e.g. bit-error-rate of the channel), on capabilities of a receiver, and so forth.

According to an embodiment of the invention, stage 530 may include stage 532 of transmitting the first and the second codeword portions in different communication channels (e.g. the first codeword portion in at least one first communication channel, and the second codeword portion in at least one second communication channel).

For example, as the second codeword portion may include additional redundancy information, which is not necessary for a successful decoding of the data bit vector (at least in some scenarios), it may be transmitted in a communication channel with lesser quality. According to an embodiment of the invention, it is noted that all expected receivers are expected to be able to receive the first codeword portion on the first communication channel, to which additional information can not be added (e.g. due to channel bandwidth, or receiver design), while some of the possible expected receivers may implement reception of additional redundancy information using the other second communication channel.

According to an embodiment of the invention, the transmitting may include stage 533 of transmitting the first codeword portion in a first communication channel, and transmitting the second codeword portion in at least one sub-channel (or sub-carried) of the first communication channel, in which the first codeword portion is not transmitted.

According to an embodiment of the invention, stage 533 may include transmitting the first codeword portion in at least one first communication channel (which may be a WIMEDIA compliant channel, but not necessarily so)—e.g. using the data tones of the communication channel, while transmitting the second codeword portion using the guard-tones of the first communication channel. It is noted that transmission of information using several sub-channels is known in the art, and any technique to do so may be implemented for transmission of a codeword portion over several sub-channels (or sub-carriers) according to different embodiments of the invention.

It is noted that the transmission may be carried out using different modulations, without limiting the scope of the invention. According to an embodiment of the invention, the transmitting may include stage 535 of transmitting the codeword using quadrature amplitude modulation (QAM) modulation of an order of at least 16 (e.g. 16-QAM, 256-QAM). In such modulation, transmission of different symbols may be characterized with different error-rates.

According to an embodiment of the invention in which such modulation is used (or other modulation in which transmission of different bits or symbols is expected to have different error rates), the encoding of the data bit vector to provide the codeword may include stage 522 of providing the codeword in which information of a first bit is more useful for at least one of the first and the second parity-check processes than information of a second bit, wherein the transmitting may further include stage 535 of transmitting the first bit in a first symbol and the second bit in a second symbol, wherein the first symbol is less susceptible to errors during the transmitting than the second symbol.

It is noted that since the transmitting is conveniently sequential, the matching of such “useful bits” to such “more secure symbols” should usually be implemented during the encoding process.

Referring, for example, to the 16-QAM constellation diagram offered in FIG. 7, the first symbol may be any symbols out of symbols 0000, 0100, 1011 and 1110, while the second symbol may be any of 0101, 1101, 0111, and 1111. In one embodiment this may entail the encoding being directed to place the “1”s and the “0” in the “right” places in the code-word.

It is noted that codes offered below which may be used for the encoding and which are more efficient in 16-QAM modulation than codes which are not designed for such modulation, are also efficient for other modulations such as QPSK and 64-QAM. It is noted that if some modulations, there may be more than two degrees of susceptibility to errors during transmission, wherein additional degrees of utilizing the bits of the codeword may be used.

It is noted that according to an embodiment of the invention, the transmitting may also be efficiently implemented using dual carrier modulation (DCM) and modified dual-carrier modulation (MDCM) (which may be preceded by modulation the codeword using MDCM or DCM modulation).

FIG. 3 illustrates receiver 300, according to an embodiment of the invention. Receiver 300 may include at least one communication module 330 that may be configured to attempt to receive a first codeword portion and a second codeword portion of a transmitted codeword, wherein the first codeword portion is of a first length; at least one processor 350 (which may and may not be a part of decoder 320), for selecting between a first parity check process and a second parity check process, wherein the first parity check process may include parity check of messages of the first length and the second parity check process may include parity check for longer messages; and at least one decoder 320 that may be configured to decode at least a portion of the codeword by the selected parity check process, to receive a decoded data bit vector.

Receiver 300 may include additional components such as components that are known in the art when implementing communication devices (e.g. a power source, different interfaces, and so forth). Such additional components, if not essential to the understanding of the invention, are not illustrated in the drawings or individually detailed, for the clarity of the disclosure.

It is noted that according to an embodiments of the invention, decoder 320 may be implemented by multiple decoding modules (not illustrated) which may and may not operate in parallel, for decoding different portions of the codeword (or of multiple codewords), and/or for decoding portions of the codeword (or codewords) in multiple decoding stages. It is noted that different techniques of implementing multiple decoding modules may be implemented by a person who is skilled in the art.

It is noted that receiver 300 may implement one or more embodiments of method 600, but this is not necessarily so. Also, receiver 300 may be implemented together with a transmitter (such as transmitter 200 but not necessarily), for providing a transceiver. According to such an embodiment of the invention, components described separately for receiver 300 and transmitter 200 may be integrated into combined component (e.g. a transmission/reception communication module),

It is noted that receiver 300 may be used for receiving information which is transmitted substantially as by a transmitter such as transmitter 200, but this is not necessarily so.

It is noted that, according to an embodiment of the invention, receiver 300 and/or components thereof (e.g. decoder 320, and at least some modules of communication module 330) may be implemented in software being operated on processor 540 (a general purpose processor or a dedicated processor). Processor 540 is illustrated as distinct from decoder 320, but it is noted that it may be a part of which, it may operate only some of the functionalities of decoder 320, as well as functionalities of other modules such as communication module 330. According to an embodiment of the invention, receiver 300 may include memory module 360 which may store different types of information. Memory 360 may store information process information used for the encoding, and/or other functionalities of modules of receiver 300. Memory 360 may also be used for including or storing instructions, e.g., computer-executable instructions, which when executed by a processor or controller, carry out methods disclosed herein. Receiver 300 may include an article such as a computer or processor readable medium, or a computer or processor storage medium, such as for example memory 360 (which may be implemented as, e.g. a disk drive, or a USB flash memory), encoding, including or storing instructions, e.g., computer-executable instructions, which when executed by a processor or controller, carry out methods disclosed herein.

Pertaining to an embodiment of the invention, it is noted that a receiver (that may and may not be receiver 300) may include: (a) a communication module (which may and may not be communication module 330) which may be configured to attempt to receive a first codeword portion and a second codeword portion of a transmitted codeword; (b) a processor (which may and may not be processor 350) for selecting between a first parity check process and a second parity check process, wherein the first parity check process may include parity check of the first codeword and the second parity check process comprises parity check of a combination of the first codeword portion and at least one bit of the second codeword portion; and a decoder (which may and may not be decoder 320) that may be configured to decode at least a portion of the codeword by the selected parity check process, to receive a decoded data bit vector. It is noted that the embodiment of the invention that pertain to receiver 300 or to components thereof may also apply, where applicable and mutatis mutandis, to said receiver.

It is noted that an attempt to receiver by communication module 330 may conveniently come before (or concurrent with) receiving the respective codeword portions by communication module 330; however, such receiving of either one of the codeword portions, or parts thereof, may be unsuccessful. It is noted that the attempting may be continuous, to receive a sequence of transmitted codewords, wherein for some codewords an attempt is made to receive both codeword portions, while for other codewords an attempt is made to receive only the first codeword portion (e.g. due to channel limitations, available computational power, and so forth).

It is noted that the reception (and/or attempts to receive) by communication module 330 is typically carried out according to a communication protocol that is shared with a transmitter of the information, but this need not be the case.

According to an embodiment of the invention, communication module 330 may be adapted to attempt to receive the first and the second codeword portions in different communication channels (or different sub-channels—or sub-carriers—of one or more communication channels).

According to an embodiment of the invention, communication module 330 may be adapted to attempt to receive the first codeword portion in a first communication channel, and to attempt to receive the second codeword portion in at least one sub-channel of the first communication channel in which the first codeword portion is not transmitted.

According to an embodiment of the invention, communication module 330 may be adapted to attempt to receive the first and/or the second codeword portions in accordance with a WTMDIA compliant transmission scheme. According to an embodiment of the invention, communication module 330 may be adapted to attempt to receive the first codeword portion in data sub-channels of a communication channel (which may be a WIMEDIA compliant communication channel), and attempting to receive the second codeword portion in some or all of the guard tones of the same communication channel.

Processor 350 may select between the parity check processes. It is noted that the selecting by processor 350 may be due to different types of considerations and/or selections rules.

According to an embodiment of the invention, processor 350 may be adapted to select between the first and the second parity check process in response to a result of an evaluation of a reception of at least one of the first and the second codeword portions. According to an embodiment of the invention, processor 350 may be adapted to select between the first and the second parity check processes in response to a result of an evaluation of a reception of at least one of the first and the second codeword portions.

A non-exhaustive sample of several examples to such evaluations is offered below.

According to an embodiment of the invention, the reception of the first codeword portion is evaluated, e.g. to determine whether additional redundancy information is at all required (for example, using additional information may require unnecessary computational power).

According to an embodiment of the invention, a reception of the second codeword portion is evaluated, e.g. to determine whether the second codeword portion was received in an acceptable quality (e.g. if it is transmitted in a problematic channel).

It is noted that according to an embodiment of the invention, even if the second codeword portion was received only partly (e.g. information for some guard sub-carriers was received, but not from others), utilizing the part that did arrive may improve results of future decoding of the codeword.

Also, it is noted that the second codeword portion is not necessarily transmitted, and in such case an evaluation of the reception of the second codeword portion may indicate that it was not transmitted (e.g. in scenarios in which receiver 300 is capable of receiving communication from several types of transmitters, and not all of those types can transmit codewords that includes both first and second codeword portions as herein disclosed).

According to an embodiment of the invention, processor 350 may be adapted to select between the first parity check process which is a first low-density parity check (LDPC) process and the second parity check process which is a second LDPC process. Also, other components (e.g. decoder 320) may also be adapted to handle such LPDC processes (and possibly the corresponding communication schemes).

According to an embodiment of the invention, processor 350 may be adapted to select between a first parity check process which is equivalent to processing the first codeword portion based on a first parity check matrix H and a second parity check process which is equivalent to processing the codeword based on a second parity check matrix H′, that includes the first parity check matrix. Also, other components (e.g. decoder 320) may also be adapted to handle such parity check processes (and possibly the corresponding communication schemes).

It is noted the processing of a codeword (or a portion therefore) based on a parity check matrix may conveniently include providing a variation of the codeword (in which errors are corrected) that when being multiplied by that parity check process provides a null vector.

For example, the second parity check matrix H′ may be written as

$${H}^{′} = [ \begin{matrix}H & 0 \\ C & D\end{matrix} ] ,$$

wherein H is the first parity check matrix, 0 represent a null matrix, C is a matrix corresponding to the fundamental data bit vector bits and D is matrix corresponding to the expanded parity bits. According to an embodiment of the invention, the matrix D may have a dual diagonal structure such as

$$D = [ \begin{matrix}{I}^{1} & {I}^{0} & & \\ {I}^{0} & {I}^{0} & {I}^{0} & \\ 0 & & {I}^{0} & {I}^{0} \\ {I}^{1} & & & {I}^{0}\end{matrix} ] .$$

For example, if the first parity-check matrix H has the following structure: H=[A B], where A is an m_{b}×(n_{b}−m_{b}) block matrix corresponding to the information bits and B is an m_{b}×m_{b} block matrix corresponding to the parity bits. For sake of simple linear complexity encoding of the fundamental code, the block matrix B may have has the dual diagonal structure:

$$B = [ \begin{matrix}{I}^{1} & {I}^{o} & & & & \\ 0 & {I}^{0} & {I}^{0} & & & \\ ⋮ & & {I}^{0} & & & \\ {I}^{0} & & & ⋱ & & \\ ⋮ & & & & {I}^{0} & \\ 0 & & & & {I}^{0} & {I}^{0} \\ {I}^{1} & & & & & {I}^{0}\end{matrix} ] .$$

In the first block column of B, the first and last block entries are I¹, block entry [m_{b}/2] is I⁰ and the rest of the block entries in the column are 0. Therefore, referring to the aforementioned form of the second parity check matrix H′, C may be a q×m_{b} block matrix corresponding to the fundamental data bit vector bits and D may be a q×q block matrix corresponding to the expanded parity bits (where q is the number of extension blocks, e.g. 4). It is noted that block matrix is a matrix that is constructed from equal sized blocks, wherein each symbol in the above matrix notation represents a block (e.g. a 30×30 block).

It is noted that according to different embodiments of the invention, the second parity check process may be equivalent to processing the codeword based on the second parity check matrix which is substantially the second parity check process matrix as set out in one of tables A, B, C, D, E, F, G, H, and I. It is noted that conveniently, the first parity check process may be equivalent to processing the first codeword portion based on the first parity check matrix which is substantially the first parity check process matrix H as set out in one of tables A, B, C, D, E, F, G, H, and I, according to the aforementioned structure

$${H}^{′} = [ \begin{matrix}H & 0 \\ C & D\end{matrix} ] ,$$

wherein H′ is the matrix set forth in the corresponding table. It is noted that the first parity check matrix H in the tables A-H may correspond to a standard parity check process that is accepted in the art. Other matrices, different from those shown in tables A-H, may be used.

Referring now to decoder 320, it is noted that the at least a portion of the bits which are being decoded may conveniently be the first codeword portion, if the first parity check process has been selected, and may conveniently be the entire codeword (including both the first codeword portion and the second codeword portion) if the second parity check process has been selected. However, another portion of the codeword may be decoded, e.g. if one or both of the codeword portions has not been received in its entirety.

According to an embodiment of the invention, the decoding of the at least codeword portion—and possibly the entire codeword—is carried out by multiple decoding modules (which may be included in one or more decoders 320), that operate concurrently. According to an embodiment of the invention, such a parallel decoding is carried out without implementing stall cycles. This may be achieved if the code used for the encoding/decoding is designed to facilitate such parallel decoding, and is especially true if belief propagation decoding is used for the decoding.

In belief propagation, values from check node and variable nodes may be read and written iteratively, so that certain memory value needs to be written, before it can be read to another cycle. According to an embodiment of the invention, the code used for the parity check process (and especially the second parity check process) enables writing of values before they are required to be read.

It is noted that the operation of decoder 320 is mainly dependent on one or more processing units of which, and of one or more memory units of which. The performance of decoder 320 is dependent on the number of processing units, and on an efficiency of the utilization of the processing units (which is usually depending on the parity check process being implemented, as well on the design of relations and parallel operation between processing units or modules).

For efficient processor utilization, the following code properties are desirable: (a) regular row degree, and/or (b) design for stall-free decoding.

According to an embodiment of the invention, receiver 300 (and possibly decoder 320) includes a messages memory (not illustrated in FIG. 3), which can be implemented, according to an embodiment of the invention, using 3 banks of memory, e.g. so as to allow efficient memory synthesis.

It is noted that as the rate of the code increases, the check node degree (dc) increases and the number of layers decreases. Therefore, in such codes, and especially those of higher rates, unless taken care by the code design, stall clocks need to be inserted in order to wait for the processed data to be written back to the memory. In such case, the number of iterations decreases and the performance degrades.

According to an embodiment of the invention, the second parity check process (such as but not necessarily, as set forth in the codes of tables A though H) that facilitates dc/3+5 clocks separation between successive accesses to a variable, and thus no stall clocks are needed. This facilitates pipelining by decoder 320, which is important for the design of high-speed logic.

According to an embodiment of the invention, an initialization phase for layered decoding may include the following settings (other settings may be used):

Qᵥ=Pᵥ(LLRs); and

R_{cv}=0

The iterations according to such an embodiment of the invention may include the following stages (other stages or series of stages may be used):

$$I . {Q}_{vc} = {Q}_{v} - {R}_{cv}$$

$$II . S G N = {\prod }_{v ∈ N ( c )} sign ( {Q}_{vc} )$$

$$S = {\sum }_{v ∈ N ( c )} φ ( \vert {Q}_{vc} \vert ) , φ ( x ) = log ( \frac{{e}^{x} + 1}{{e}^{x} - 1} )$$

$$III . {R}_{cv} = SGN \cdot sign ( {Q}_{vc} ) \cdot φ ( S - φ ( \vert {Q}_{vc} \vert ) )$$

$$IV . {Q}_{v} = {Q}_{vc} + {R}_{cv}$$

$$V . sign ( {Q}_{v} ) {Hc}^{T} = 0 ?$$

The symbols used in the representation of the layered decoding may be, for example:
i. Pv—log likelihood ratio (LLR) of the channel observation for variable node v
ii. Qvc—LLRs of the message from variable node v to check node c
iii. Rcv—LLRs of the message from check node c to variable node v
iv. Qv—soft decoding result for variable node v
v. H—parity check matrix (for which H′ can also be used, according to an embodiment of the invention)
vi. c—codeword
vii. T—transpose.

The other symbols are defined by the equations themselves.

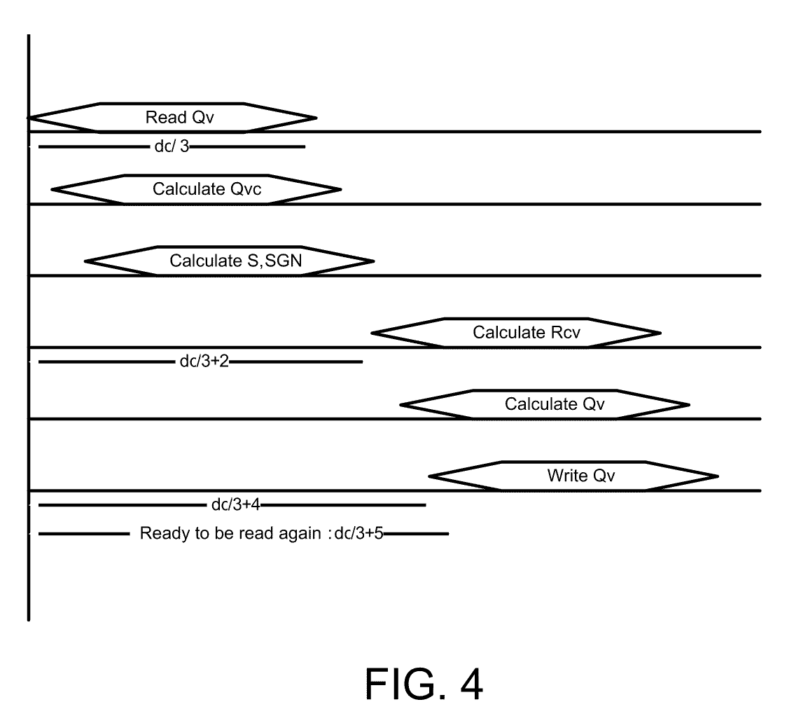

FIG. 4 illustrates a timing diagram that is implemented by decoder 320, according to an embodiment of the invention.

According to an embodiment of the invention, on each clock 90 edges are processed in parallel (Layer of 30 checks, 3 edges per check) by decoder 320. Three edges are processed in one clock, thus each stage of processing requires dc/3 clocks. Other specific numbers of edges processed, and other values may be used.

It is noted that in one embodiment S and SGN should be calculated over all dc variables before calculating Rcv, and that each processing, Read, Write stage introduces one more delay clock. In other embodiments, this need not occur.

Overall, the variables that were read in clock T, are ready to be read again in clock T+dc/3+5, according to such an embodiment of the invention.

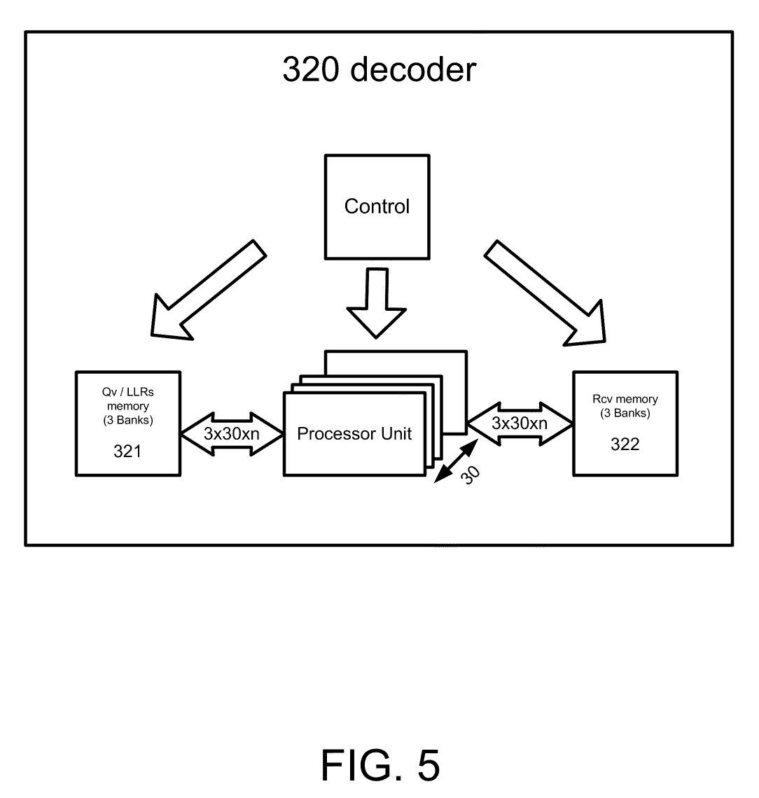

FIG. 5 illustrates decoder 320, according to an embodiment of the invention.

According to an embodiment of the invention, decoder 320 implements 3 buffers of memory: Log-likelihood ratio (LLRs) Input Buffer and Qvs Storage Buffer (collectively denoted 321), and Rcvs-Storage Buffer 322. Each of the buffers can be implemented using for example 3 banks of memory (e.g. Qv/LLRs Memory: Sub-block 1, 1=0 . . . 43, is stored in block mod(1,3), address div(1,3)). Other buffer and storage schemes may be used.

It is noted that this implementation does not require breaking the memory into a large number of small size banks that cause inefficient synthesis.

According to an embodiment of the invention, receiver 300 may further include interface 340 for providing the decoded data bit vector to an external system. The decoding may also be carried out before other stages of utilizing the decoded data bit vector by receiver 300, such as printing it, writing it to a tangible medium, displaying it, and so forth.

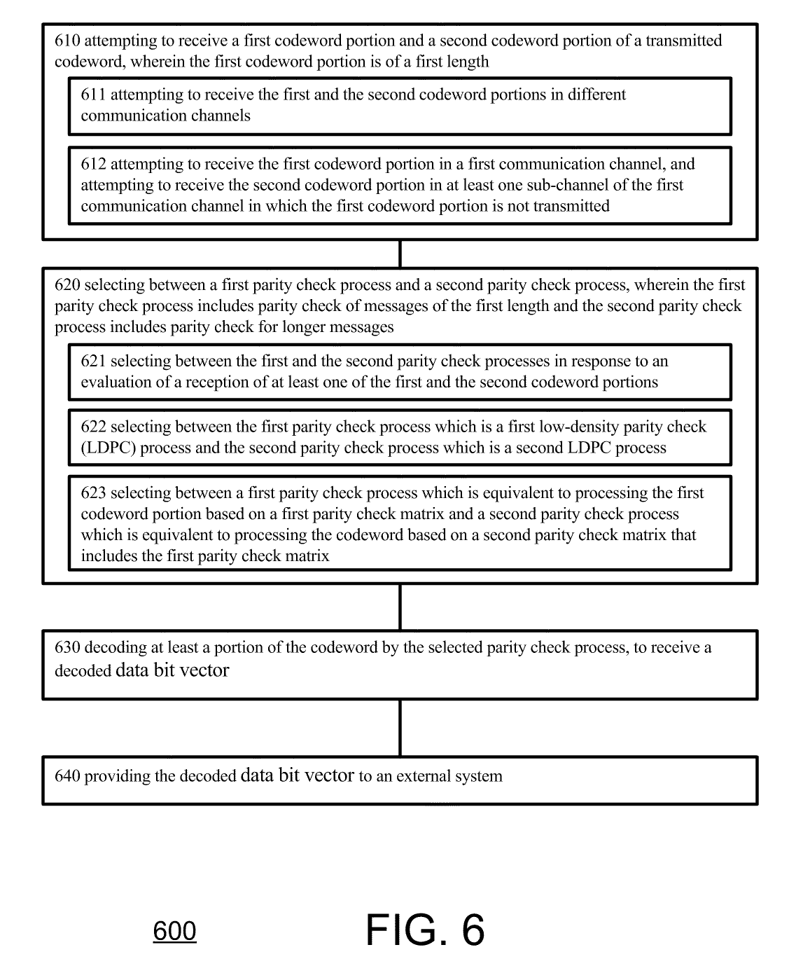

FIG. 6 illustrates method 600 for receiving information, according to an embodiment of the invention. According to an embodiment of the invention, method 600 is carried out by receiver 300, and different embodiments of method 600 may be implemented by receiver 300, and vice versa. However, other receivers may be used. It is noted that method 600 may be used for receiving information which is transmitted substantially as disclosed in method 500, but this is not necessarily so.

Method 600 starts with stage 610 of attempting to receive a first codeword portion and a second codeword portion of a transmitted codeword, wherein the first codeword portion is of a first length. Referring to examples set forth in the previous drawings, stage 610 is conveniently carried out by a receiver, such as, for example, communication module 330.

It is noted that the attempt of stage 610 may be carried out before (or concurrent with) receiving the respective codeword portions; however, such receiving of either one of the codeword portions, or parts thereof, may be unsuccessful. It is noted that the attempting may be continuous, to receive a sequence of transmitted codewords, wherein for some codewords an attempt is made to receive both codeword portions, while for other codewords an attempt is made to receive only the first codeword portion (e.g. due to channel limitations, available computational power, and so forth).

It is noted that the reception (and/or attempts to receive) are usually carried out according to a communication protocol that is shared with a transmitter of the information.

According to an embodiment of the invention, the attempting to receive may include stage 611 of attempting to receive the first and the second codeword portions in different communication channels (or different sub-channels—or sub-carriers—of one or more communication channels).

According to an embodiment of the invention, the attempting to receive may include stage 622 of attempting to receive the first codeword portion in a first communication channel, and attempting to receive the second codeword portion in at least one sub-channel of the first communication channel in which the first codeword portion is not transmitted.

According to an embodiment of the invention, the attempt to receive may include attempting to receive the first and/or the second codeword portions in accordance with a WIMEDIA compliant transmission scheme. According to an embodiment of the invention, the attempting may include attempting to receive the first codeword portion in data, sub-channels of a communication channel (which may be a WIMEDIA compliant communication channel), and attempting to receive the second codeword portion in some or all of the guard tones of the same communication channel.

In stage 620 a selecting between a first parity check process and a second parity check process is carried out, wherein the first parity check process may include parity check of messages of the first length and the second parity check process may include parity check for longer messages (usually a predetermined length, but possibly a range of lengths). It is noted that the selecting of 620 may be due to different types of considerations and/or selections rules. Referring to the examples set forth in the previous drawings, the selecting may be carried out by a decoder such as decoder 320, by a dedicated selection module, or by another processor. The selecting may also be implemented, according to an embodiment of the invention, by an external system (or in response to instructions of which, or of a human).

According to an embodiment of the invention, the selecting is responsive to a result of an evaluation of a reception of at least one of the first and the second codeword portions. According to an embodiment of the invention, stage 620 may include stage 621 of selecting between the first and the second parity check processes in response to a result of an evaluation of a reception of at least one of the first and the second codeword portions.

A non-exhaustive sample of several examples to such evaluations is offered below.

According to an embodiment of the invention, the reception of the first codeword portion is evaluated, e.g. to determine whether additional redundancy information is at all required (for example, using additional information may require unnecessary computational power).

According to an embodiment of the invention, a reception of the second codeword portion is evaluated, e.g. to determine whether the second codeword portion was received in an acceptable quality (e.g. if it is transmitted in a problematic channel).

It is noted that according to an embodiment of the invention, even if the second codeword portion was received only partly (e.g. information for some guard sub-carriers was received, but not from others), utilizing the part that did arrive may improve results of future decoding of the codeword.

Also, it is noted that the second codeword portion is not necessarily transmitted, and in such case an evaluation of the reception of the second codeword portion may indicate that it was not transmitted (e.g. in scenarios in which a receiver that implements method 600 is capable of receiving communication from several types of transmitters, and not all of those types can transmit codewords that includes both first and second codeword portions as herein disclosed).

According to an embodiment of the invention, the selecting may include stage 622 of selecting between the first parity check process which is a first low-density parity check (LDPC) process and the second parity check process which is a second LDPC process.

According to an embodiment of the invention, the selecting may include stage 623 of selecting between a first parity check process which is equivalent to processing the first codeword portion based on a first parity check matrix H and a second parity check process which is equivalent to processing the codeword based on a second parity check matrix H′, that includes the first parity check matrix.

For example, the second parity check matrix H′ may be written as

$${H}^{′} = [ \begin{matrix}H & 0 \\ C & D\end{matrix} ] ,$$

wherein H is the first parity check matrix, 0 represent a null matrix, C is a matrix corresponding to the fundamental data bit vector bits and D is matrix corresponding to the expanded parity bits. According to an embodiment of the invention, the matrix D may have a dual diagonal structure such as

$$D = [ \begin{matrix}{I}^{1} & {I}^{0} & & \\ {I}^{0} & {I}^{0} & {I}^{0} & \\ 0 & & {I}^{0} & {I}^{0} \\ {I}^{1} & & & {I}^{0}\end{matrix} ] .$$

For example, if the first parity-check matrix H has the following structure: H=[A B], where A is an m_{b}×(n_{b}−m_{b}) block matrix corresponding to the information bits and B is an m_{b}×m_{b} block matrix corresponding to the parity bits. For sake of simple linear complexity encoding of the fundamental code, the block matrix B may have has the dual diagonal structure:

$$B = [ \begin{matrix}{I}^{1} & {I}^{o} & & & & \\ 0 & {I}^{0} & {I}^{0} & & & \\ ⋮ & & {I}^{0} & & & \\ {I}^{0} & & & ⋱ & & \\ ⋮ & & & & {I}^{0} & \\ 0 & & & & {I}^{0} & {I}^{0} \\ {I}^{1} & & & & & {I}^{0}\end{matrix} ] .$$

In the first block column of B, the first and last block entries are I¹, block entry [m_{b}/2] is I⁰ and the rest of the block entries in the column are 0. Therefore, referring to the aforementioned form of the second parity check matrix H′, C may be a q×m_{b} block matrix corresponding to the fundamental data bit vector bits and D may be a q×q block matrix corresponding to the expanded parity bits (where q is the number of extension blocks, e.g. 4). It is noted that block matrix is a matrix that is constructed from equal sized blocks, wherein each symbol in the above matrix notation represents a block (e.g. a 30×30 block).

It is noted that according to different embodiments of the invention, the second parity check process may be equivalent to processing the codeword based on the second parity check matrix which is substantially the second parity check process matrix as set out in one of tables A, B, C, D, E, F, G, or H. It is noted that conveniently, the first parity check process may be equivalent to processing the first codeword portion based on the first parity check matrix which is substantially the first parity check process matrix H as set out in one of tables A, B, C, D, E, F, G, or H, according to the aforementioned structure

$${H}^{′} = [ \begin{matrix}H & 0 \\ C & D\end{matrix} ] ,$$

wherein H′ is the matrix set forth in the corresponding table. It is noted that the first parity check matrix H in the tables A-H may correspond to a standard parity check process that is accepted in the art.

In stage 630 a decoding at least a portion of the codeword by the selected parity check process, to receive a decoded data bit vector, is carried out. It is noted that the at least a portion being decoded may conveniently be the first codeword portion, if the first parity check process has been selected, and may conveniently be the entire codeword (including both the first codeword portion and the second codeword portion) if the second parity check process has been selected, However, another portion of the codeword may be decoded, e.g. if one or both of the codeword portions has not been received in its entirety.

Referring to the examples set forth in the previous drawings, the decoding is conveniently carried out by a decoder such as decoder 320.

According to an embodiment of the invention, the decoding of the at least codeword portion—and possibly the entire codeword—is carried out by multiple decoding modules, that operate concurrently. According to an embodiment of the invention, such a parallel decoding is carried out without implementing stall cycles. This may be achieved if the code used for the encoding/decoding is designed to facilitate such parallel decoding, and is especially true if belief propagation decoding is used for the decoding.

In belief propagation, values from check node and variable nodes are being read and written iteratively, so that certain memory value needs to be written, before it can be read to another cycle. According to an embodiment of the invention, the code used for the parity check process (and especially the second parity check process) enables writing of values before they are required to be read.

According to an embodiment of the invention, Stage 640 may be carried out, in which providing the decoded data bit vector to an external system. Stage 630 may be carried out before other stages of utilizing the decoded data bit vector, such as printing it, writing it to a tangible medium, displaying it, and so forth. Referring to the examples set forth in the previous figures, the providing may be carried out by an interface such as interface 340.

Referring to both transmitter 200 (and/or method 500 for transmission of information) and receiver 300 (and/or method 600 of receiving of information), according to an embodiment of the invention each of the transmitter and the receiver can independently decide if using a basic parity check code (corresponding to the first parity check process) or an extended code (corresponding to the second parity check process) which utilize the second codeword portion in order to increase the amount of redundancy information.

Conveniently, the transmitter can transmit both of the first and the second codeword portions, while the receiver only receive and/or utilize the first codeword portion, or conversely, the transmitter can transmit only the basic codeword (corresponding to the first codeword portion), while the receiver may attempt to receive both the first and the second codeword portions.

However, in one embodiment, the utilization of the second codeword portion is enabled only when at least a portion of it is transmitted, received, and used for decoding.

Referring to both encoding (by encoder 220 or otherwise) and decoding (by decoder 320 or otherwise), it is noted that the corresponding process can be extended for more than two codeword portions.

For example, considering three codeword portions, the encoding may include encoding a data bit vector to provide an codeword that includes a first codeword portion, a second codeword portion, and a third codeword portion; wherein the first codeword portion is decodable by a first parity check process to yield the data bit vector; wherein a codeword portion that consists of the first and the second codeword portions is decodable by a second parity check process, and wherein the codeword is decodable by a second parity check process to yield the data bit vector. This may be easily extended for more than three portions, conveniently where each group of consecutive codeword portions is decodable using a different parity check process. The decoding by decoder 320 or otherwise (and the preceding selecting) can match those changes, mutatis mutandis.

It is noted that for codewords of more than three codeword portions, non-consecutive groups of codeword portions (which conveniently include the first codeword portion) may also be decodable according to yet another parity check processes.

It is noted that the basic code (corresponding to the first parity check process) is conveniently a good code, in the meaning used in the art.

It is noted that separating the codeword into to portion wherein the first codeword portion may be decoded independently of the second codeword portion enables a trade-off between (a) the complexity of implementing the support in guard tones transmission and/or reception; and (b) performance. It is noted that the extended code (which corresponds to the second parity check process) is a lower rate code, as more redundancy bits are added to the original code.

The properties of the extended code are such that: (a) if transmitted or received without the additional redundancy bits, the performance will be exactly equivalent to the original good code, and (b) if transmitted and received with the additional redundancy bits, the performance will be better than the original code.

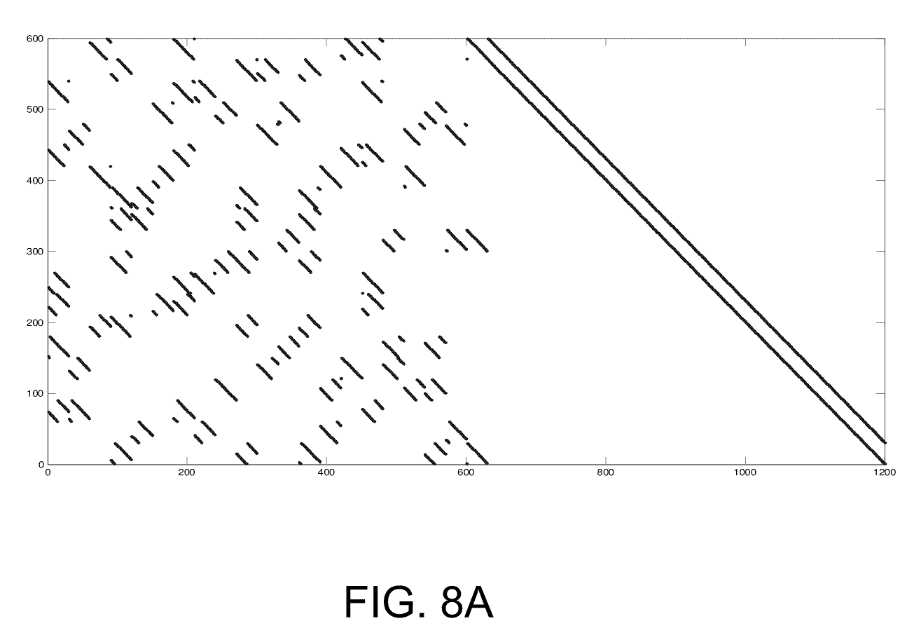

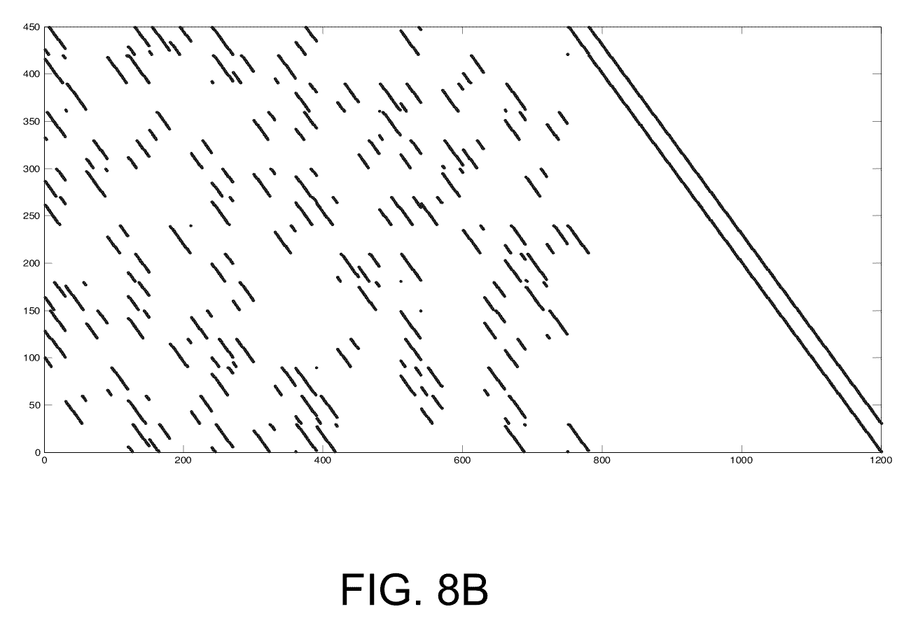

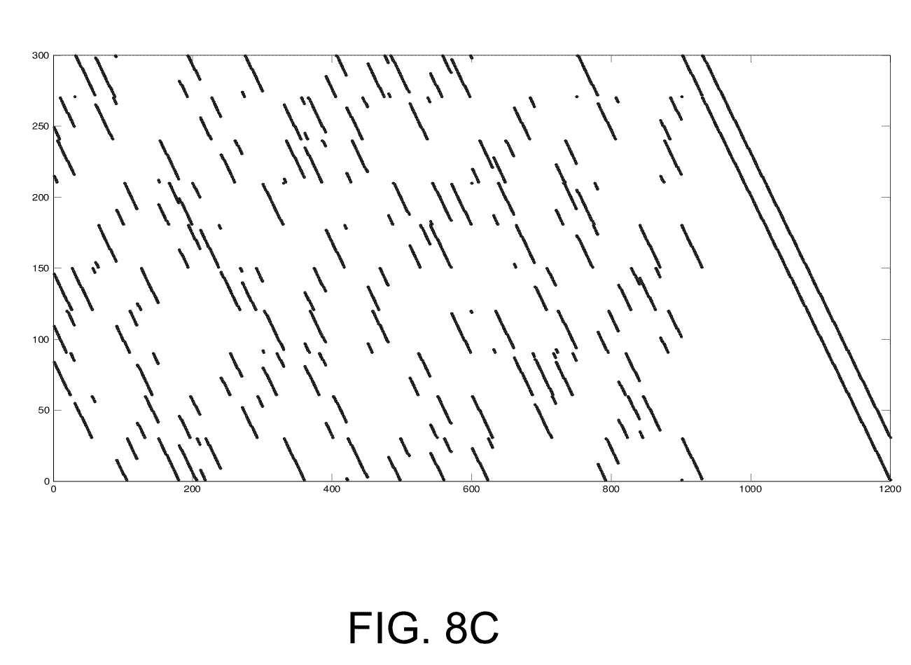

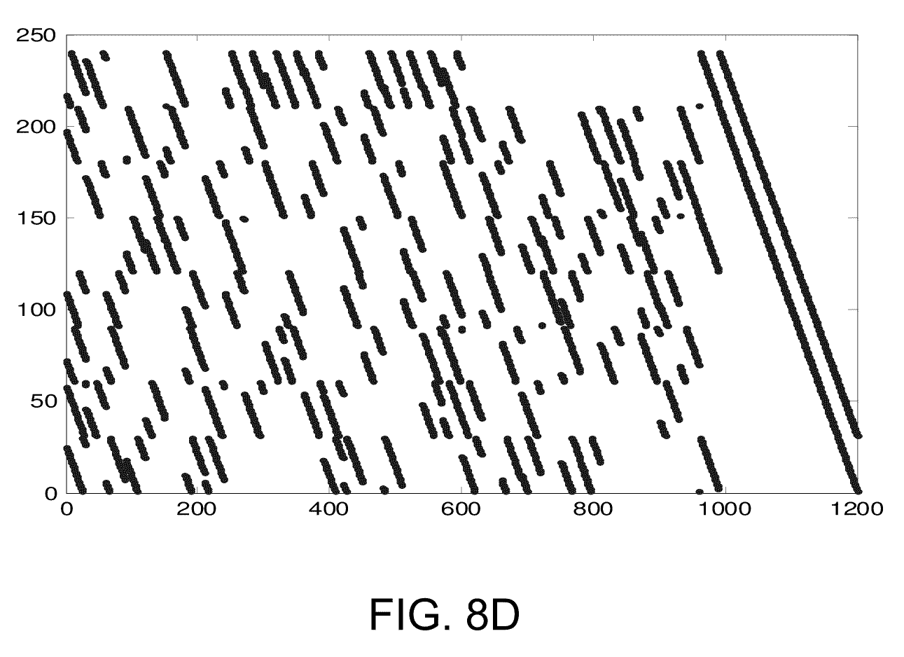

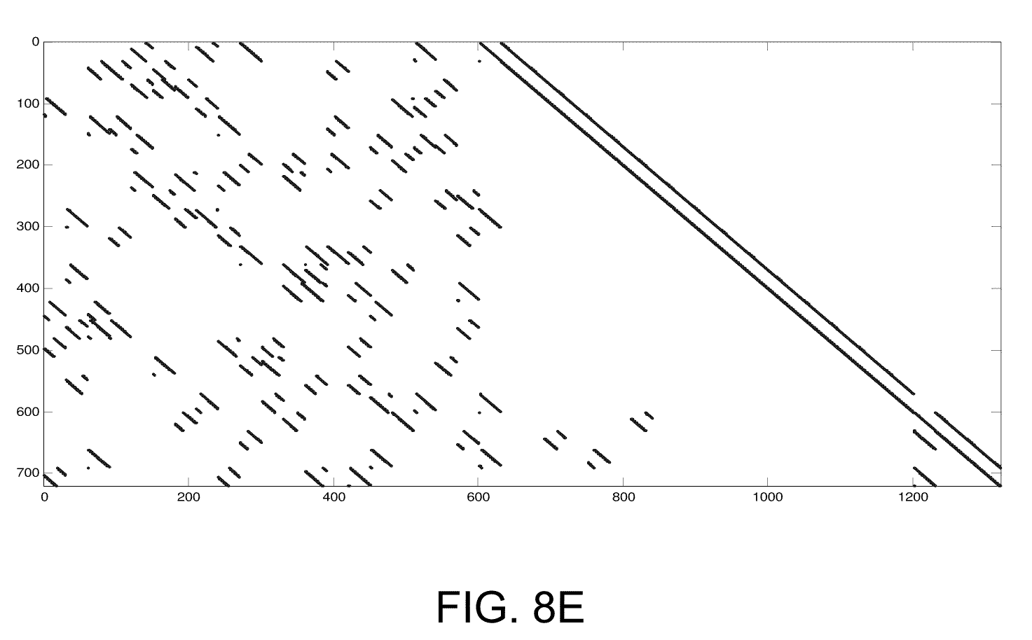

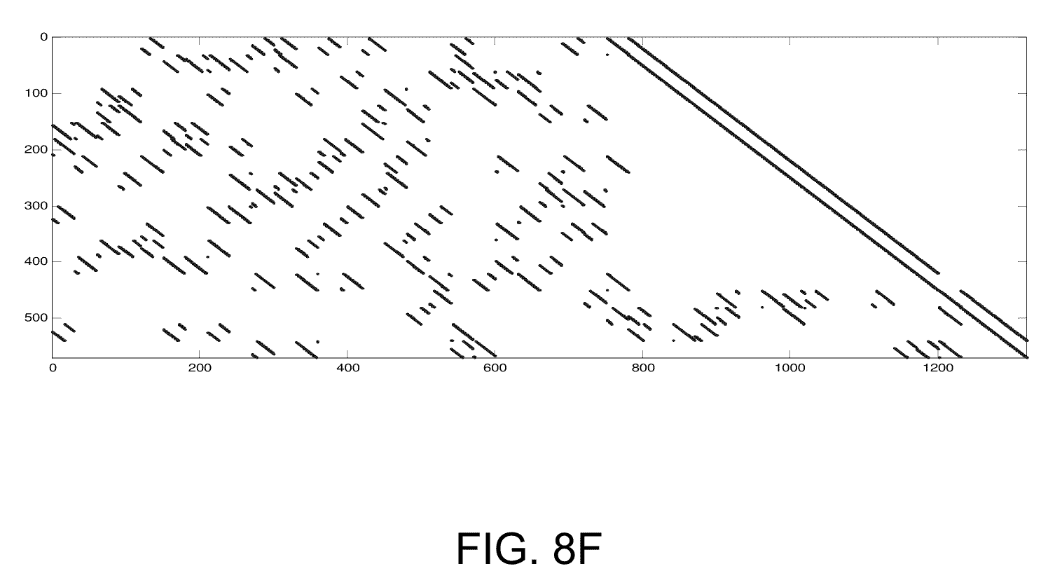

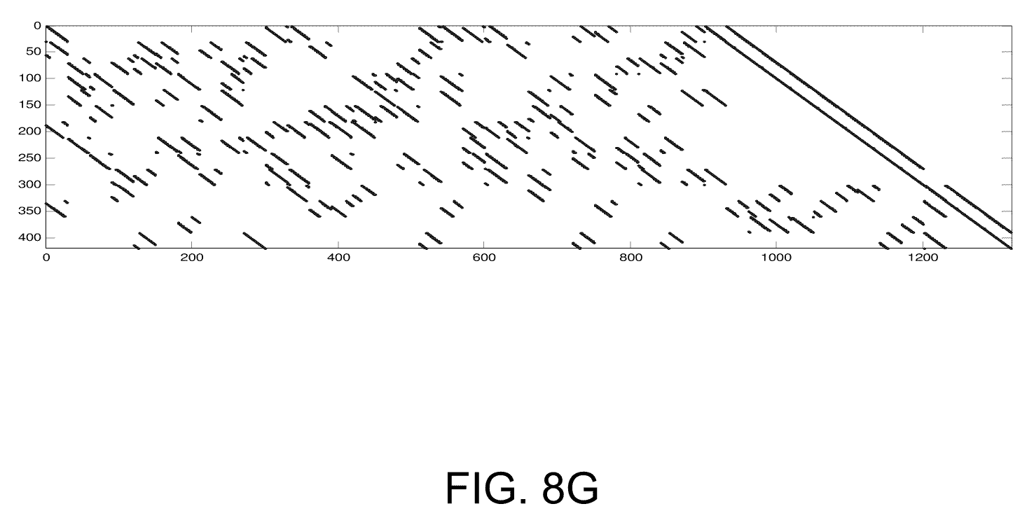

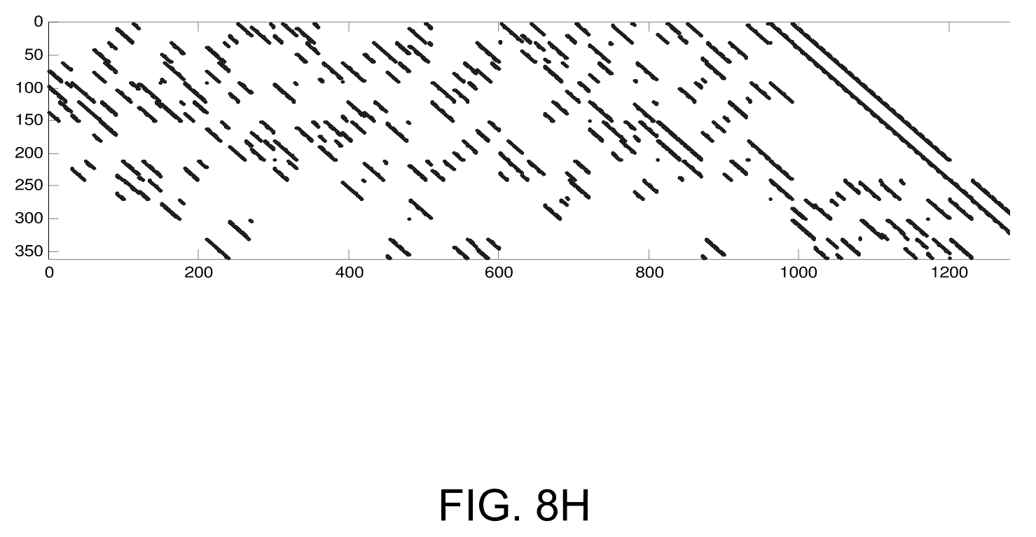

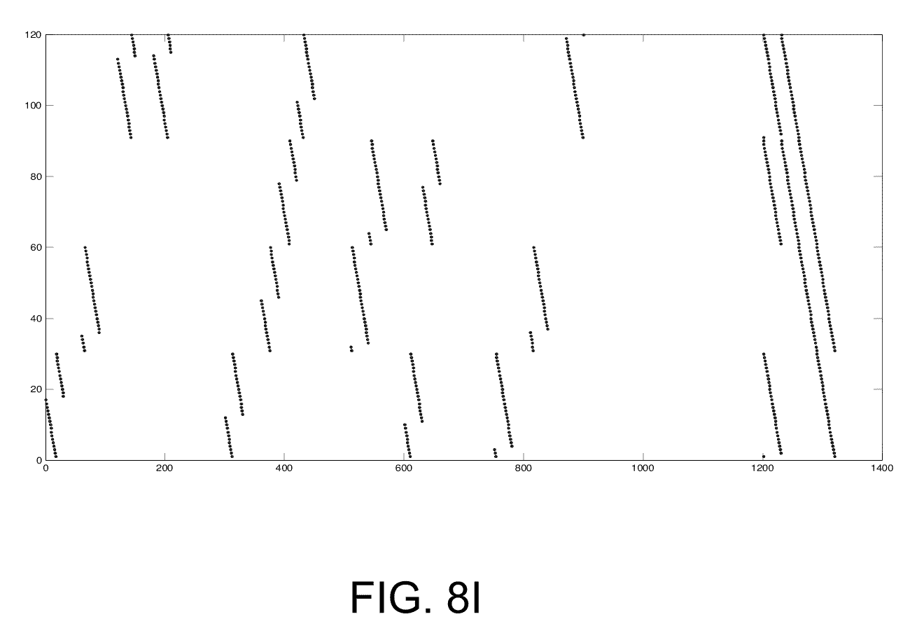

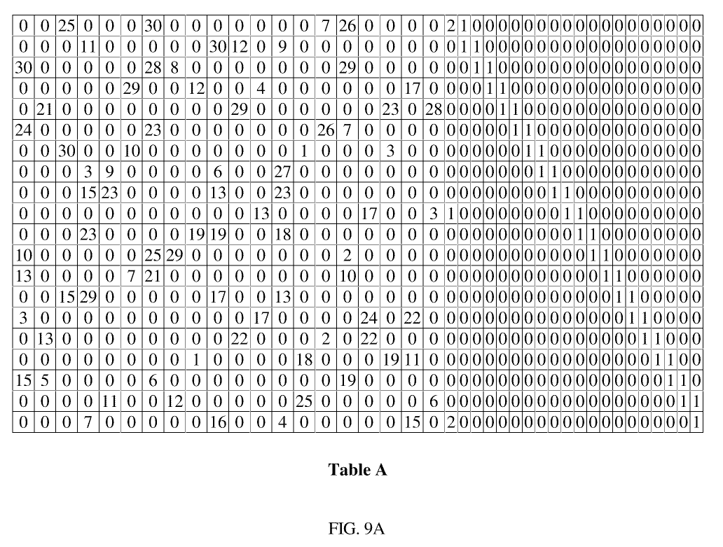

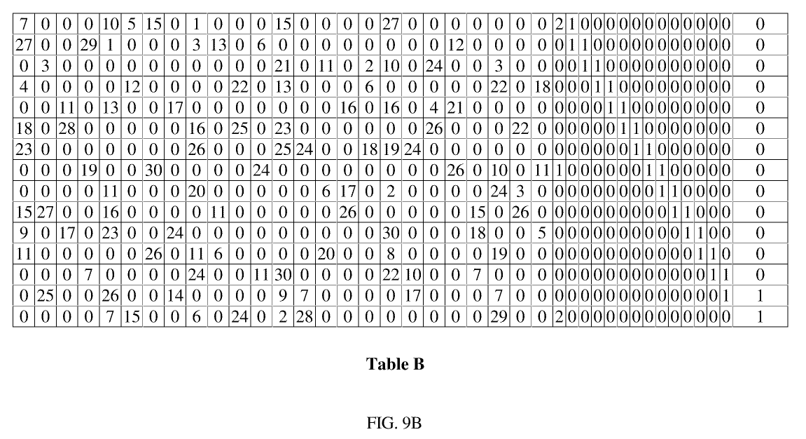

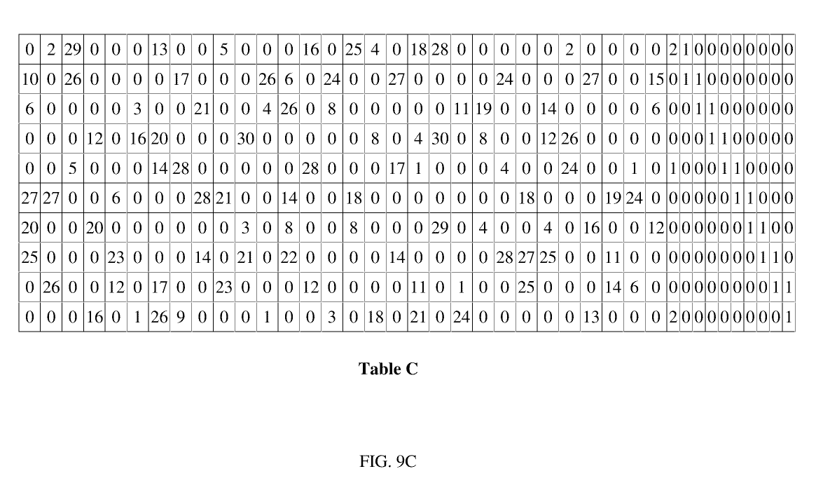

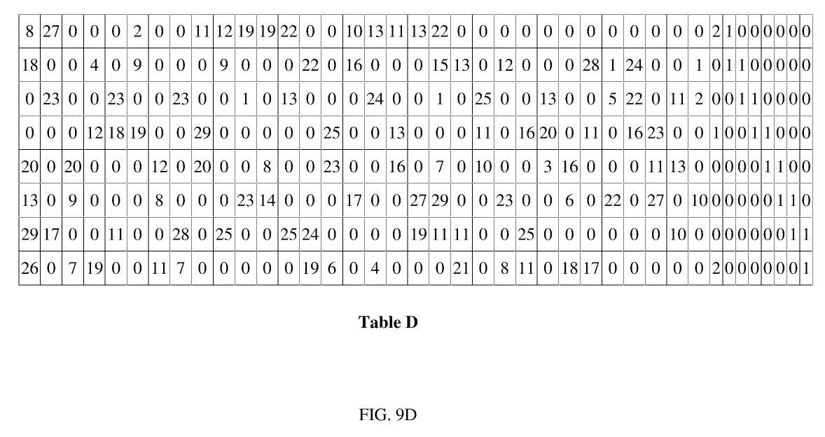

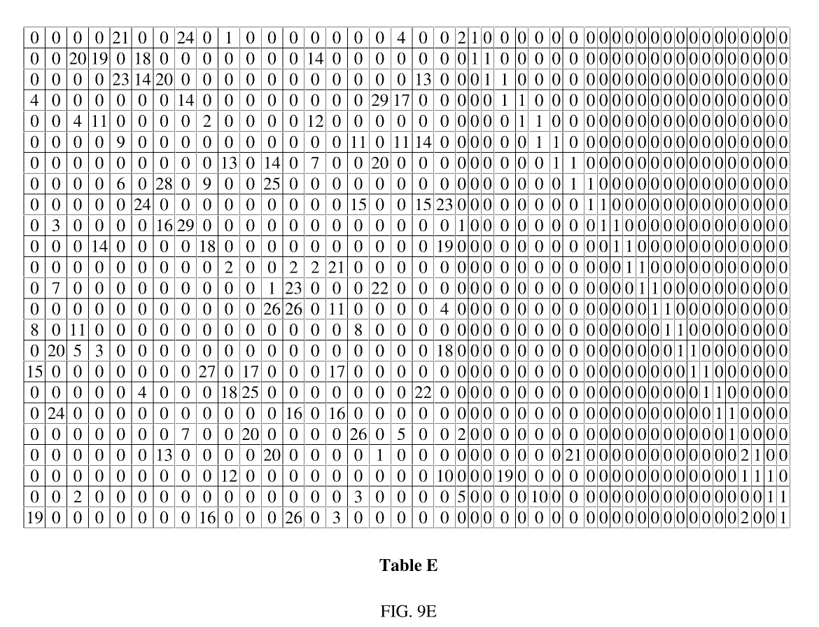

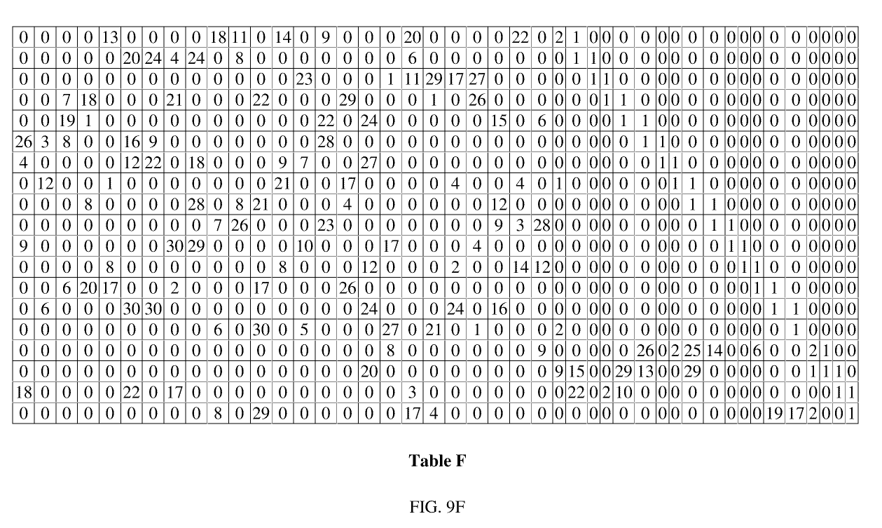

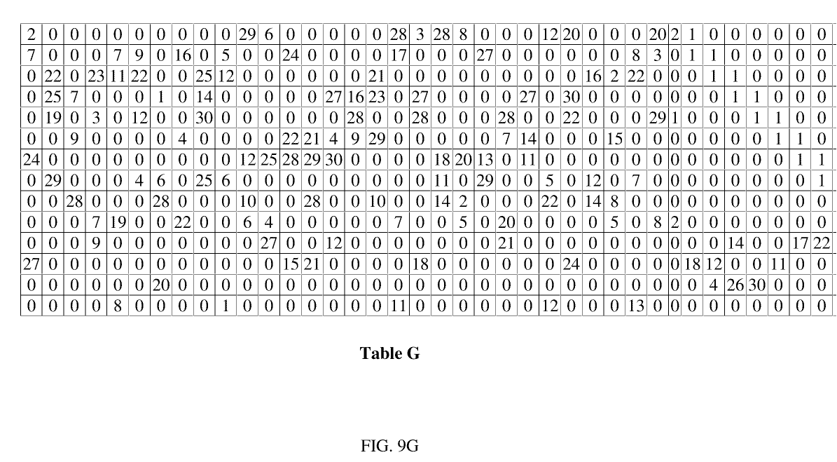

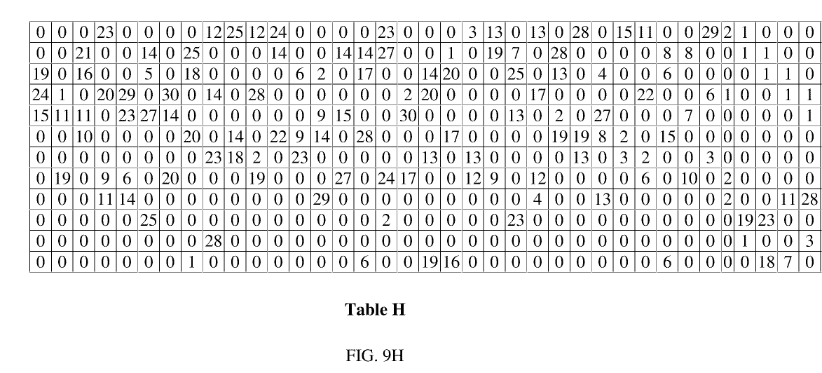

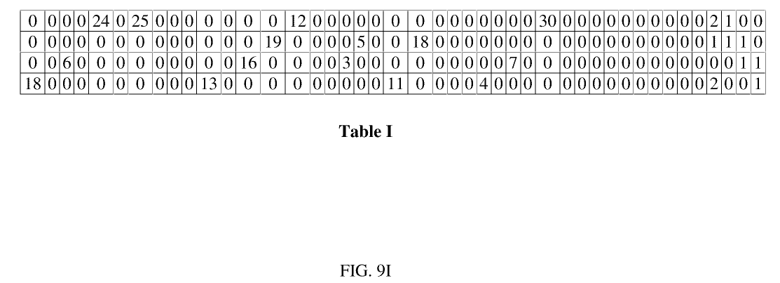

FIGS. 9I-9A illustrate tables A through I—each representing an LDPC code. FIGS. 8A-8I are graphical representations of the LDPC codes.

Referring to the notation used in tables A-I, the disclosed coded may be defined by a parity-check matrix H′ of size m×n, where n is the length of the code and m is the number of parity check bits in the code. The number of systematic bits is k=n−m.

In each of tables A-I, a matrix H′ is defined, such that:

$${H}^{′} = [ \begin{matrix}{P}_{0 , 0} & {P}_{0 , 1} & {P}_{0 , 2} & … & {P}_{0 , {n}_{b} - 1} \\ {P}_{1 , 0} & {P}_{1 , 1} & {P}_{1 , 2} & … & {P}_{1 , {n}_{b} - 1} \\ {P}_{2 , 0} & {P}_{2 , 1} & {P}_{2 , 2} & … & {P}_{2 , {n}_{b} - 1} \\ … & … & … & … & … \\ {P}_{{m}_{b} - 1 , 0} & {P}_{{m}_{b} - 1 , 1} & {P}_{{m}_{b} - 1 , 2} & … & {P}_{{m}_{b} - 1 , {n}_{b} - 1}\end{matrix} ]$$

Where Pi,j is one of a set of z×z permutation matrices or a z×z zero matrix, and z=30. Each permutation matrix is a cyclically right shifted identity matrix, denoted as I^{s} for shift s, where s is an integer between 0 and z−1. Thus, the matrix H′ is composed of m_{b} block rows and n_{b} block columns, where n=z×n_{b} and m=z×m_{b}. Hence, it can be concisely described by a m_{b}×n_{b} matrix where entry (i,j) contains either 0 if P_{i,j}=0 or 1+s if P_{i,j}=I^{s}.

It is noted that on top of the numeral representation, a graphical representation of each of the codes of tables A-I is provided in a corresponding figure: FIG. 8A corresponds to the code of table A, FIG. 8B corresponds to the code of table B, FIG. 8C corresponds to the code of table C, FIG. 8D corresponds to the code of table D; FIG. 8E corresponds to the code of table E, FIG. 8F corresponds to the code of table F, FIG. 8G corresponds to the code of table G, FIG. 8H corresponds to the code of table H; and FIG. 8I corresponds to the code of table I. In each of FIGS. 8A through 8I a colored dot indicates a value of “1” in the corresponding location in the matrix, and a blank dot indicated a value of “0”.

It is noted that table A is also representable as an ordered set of vectors, each of which represent a line of table A:

[0,0,25,0,0,0,30,0,0,0,0,0,0,0,7,26,0,0,0,0,2, 1,0,00,0,0,0,0,0,0,0,0,0,0,0,0,0,0,0,0]; [0,0,0,11,0,0,0,0,0,30,12,0,9,0,0,0,0,0,0,0,0,1,1,0,0,0,0,0,0,0,0,0,0,0,0,0,0,0,0,0]; [30,0,0,0,0,0,28,8,0,0,0,0,0,0,0,29,0,0,0,0,0,0,1,1,0,0,0,0,0,0,0,0,0,0,0,0,0,0,0,0]; [0,0,0,0,0,29,0,0,12,0,0,4,0,0,0,0,0,0,17,0,0,0,0,0,1,0,0,0,0,0,0,0,0,0,0,0,0,0,0,0,0]; [0,21,0,0,0,0,0,0,0,0,29,0,0,0,0,0,0,23,0,28,0,0,0,0,1,1,0,0,0,0,0,0,0,0,0,0,0,0,0,0,0,0]; [24,0,0,0,0,0,23,0,0,0,0,0,0,0,26,7,0,0,0,0,0,0,0,0,0,1,1,0,0,0,0,0,0,0,0,0,0,0,0,0,0]; [0,0,30,0,0,10,0,0,0,0,0,0,0,1,0,0,0,3,0,0,0,0,0,0,0,1,1,0,0,0,0,0,0,0,0,0,0,0,0]; [0, 0,0,3,9,0,0,0,0,6,0,0,27,0,0,0,0,0,0,0,0,0,0,0,0,0,0,1,1,0,0,0,0,0,0,0,0,0,0,0]; [0,0,0, 15,23,0,0,0,0,13,0,0,23,0,0,0,0,0,0,0,0,0,0,0,0,0,0,0,1,1,0,0,0,0,0,0,0,0,0,0]; [0,0,0, 0,0,0,0,0,0,0,0,13,0,0,0,0,17,0,0,3,1,0,0,0,0,0,0,0,0,1,1,0,0,0,0,0,0,0,0,0]; [0,0,0, 23,0,0,0,0,19,19,0,0,18,0,0,0,0,0,0,0,0,0,0,0,0,0,0,0,0,0,1,1,0,0,0,0,0,0,0,0]; [10,0, 0,0,0,0,25,29,0,0,0,0,0,0,0,2,0,0,0,0,0,0,0,0,0,0,0,0,0,0,0,1,1,0,0,0,0,0,0,0]; [13,0, 0,0,0,7,21,0,0,0,0,0,0,0,0,10,0,0,0,0,0,0,0,0,0,0,0,0,0,0,0,0,1,1,0,0,0,0,0,0]; [0,0, 15,29,0,0,0,0,0,17,0,0,13,0,0,0,0,0,0,0,0,0,0,0,0,0,0,0,0,0,0,0,0,1,1,0,0,0,0,0]; [3,0, 0,0,0,0,0,0,0,0,0,17,0,0,0,0,24,0,22,0,0,0,0,0,0,0,0,0,0,0,0,0,0,0,1,1,0,0,0,0]; [0,13, 0,0,0,0,0,0,0,0,22,0,0,0,2,0,22,0,0,0,0,0,0,0,0,0,0,0,0,0,0,0,0,0,0,1,1,0,0,0]; [0,0,0, 0,0,0,0,0,1,0,0,0,0,18,0,0,0,19,11,0,0,0,0,0,0,0,0,0,0,0,0,0,0,0,1,1,0,0]; [15,5,0, 0,0,0,6,0,0,0,0,0,0,0,0,19,0,0,0,0,0,0,0,0,0,0,0,0,0,0,0,0,0,0,0,0,0,1,1,0]; [0,0,0,0, 11,0,0,12,0,0,0,0,0,25,0,0,0,0,0,6,0,0,0,0,0,0,0,0,0,0,0,0,0,0,0,0,0,0,1,1]; [0,0,0,7, 0,0,0,0,0,16,0,0,4,0,0,0,0,0,15,0,2,0,0,0,0,0,0,0,0,0,0,0,0,0,0,0,0,0,0,1]

It is noted that table B is also representable as an ordered set of vectors, each of which represent a line of table B:

[7,0,0,0,10,5,15,0,1,0,0,0,15,0,0,0,0,27,0,0,0,0,0,0,0,2,1,0,0,0,0,0,0,0,0,0,0,0,0,0]; [27,0,0,29,1,0,0,0,3,13,0,6,0,0,0,0,0,0,0,0,12,0,0,0,0,0,1,1,0,0,0,0,0,0,0,0,0,0,0,0]; [0,3,0,0,0,0,0,0,0,0,0,0,21,0,11,0,2,10,0,24,0,0,3,0,0,0,0,1,1,0,0,0,0,0,0,0,0,0,0,0]; [4,0,0,0,0,12,0,0,0,0,22,0,13,0,0,0,6,0,0,0,0,0,22,0,18,0,0,0,1,1,0,0,0,0,0,0,0,0,0, 0]; [0,0,11,0,13,0,0,17,0,0,0,0,0,0,0,16,0,16,0,4,21,0,0,0,0,0,0,0,0,1,1,0,0,0,0,0,0,0, 0,0]; [18,0,28,0,0,0,0,0,16,0,25,0,23,0,0,0,0,0,0,26,0,0,0,22,0,0,0,0,0,0,0,1,1,0,0,0,0, 0,0,0,0]; [23,0,0,0,0,0,0,26,0,0,0,25,24,0,0,18,19,24,0,0,0,0,0,0,0,0,0,0,0,0,1,0, 0,0,0,0,0,0]; [0,0,0,19,0,0,30,0,0,0,0,24,0,0,0,0,0,0,0,0,26,0,10,0,11,1,0,0,0,0,0,0,1, 1,0,0,0,0,0,0]; [0,0,0,0,11,0,0,0,20,0,0,0,0,0,6,17,0,2,0,0,0,0,24,3,0,0,0,0,0,0,0,0,0, 1,1,0,0,0,0,0]; [15,27,0,0,16,0,0,0,0,11,0,0,0,0,0,26,0,0,0,0,0,15,0,26,0,0,0,0,0,0,0, 0,0,0,1,1,0,0,0,0]; [9,0,17,0,23,0,0,24,0,0,0,0,0,0,0,0,0,30,0,0,0,18,0,0,5,0,0,0,0,0, 0,0,0,0,0,1,1,0,0,0]; [11,0,0,0,0,0,26,0,11,6,0,0,0,0,20,0,0,8,0,0,0,0,19,0,0,0,0,0,0, 0,0,0,0,0,0,0,1,1,0,0]; [0,0,0,7,0,0,0,0,24,0,0,11,30,0,0,0,0,22,10,0,0,7,0,0,0,0,0,0, 0,0,0,0,0,0,0,0,0,1,1,0]; [0,25,0,0,26,0,0,14,0,0,0,9,7,0,0,0,0,17,0,0,0,7,0,0,0,0,0, 0,0,0,0,0,0,0,0,0,0,1,1]; [0,0,0,0,7,15,0,0,6,0,24,0,2,28,0,0,0,0,0,0,0,0,29,0,0,2,0,0, 0,0,0,0,0,0,0,0,0,0,0,1]

It is noted that table C is also representable as an ordered set of vectors, each of which represent a line of table C:

[0,2,29,0,0,0,13,0,0,5,0,0,0,16,0,25,4,0,18,28,0,0,0,0,0,2,0,0,0,0,2,1,0,0,0,0,0,0,0, 0]; [10,0,26,0,0,0,0,17,0,0,0,26,6,0,24,0,0,27,0,0,0,0,24,0,0,0,27,0,0,15,0,1,1,0,0,0, 0,0,0]; [6,0,0,0,0,3,0,0,21,0,0,4,26,0,8,0,0,0,0,0,11,19,0,0,14,0,0,0,0,6,0,0,1,1,0, 0,0,0,0,0]; [0,0,0,12,0,16,20,0,0,0,30,0,0,0,0,0,8,0,4,30,0,8,0,0,12,26,0,0,0,0,0,0,0, 1,1,0,0,0,0,0]; [0,0,5,0,0,0,14,28,0,0,0,0,0,28,0,0,0,17,1,0,0,0,4,0,0,24,0,0,1,0,1,0, 0,0,1,1,0,0,0,0]; [27,27,0,0,6,0,0,0,28,21,0,0,14,0,0,18,0,0,0,0,0,0,0,18,0,0,0,19,24, 0,0,0,0,0,0,1,1,0,0,0]; [20,0,0,20,0,0,0,0,0,0,3,0,8,0,0,8,0,0,0,29,0,4,0,0,4,0,16,0,0, 12,0,0,0,0,0,0,1,1,0,0]; [25,0,0,0,23,0,0,0, 14,0,21,0,22,0,0,0,0,14,0,0,0,0,28,27,25, 0,0,11,0,0,0,0,0,0,0,0,0,1,1,0]; [0,26,0,0,12,0,17,0,0,23,0,0,0,12,0,0,0,0,11,0,1,0,0, 25,0,0,0,14,6,0,0,0,0,0,0,0,0,0,1,1]; [0,0,0,16,0,1,26,9,0,0,1,0,0,0,3,0,18,0,21,0,24, 0,0,0,0,0,13,0,0,0,2,0,0,0,0,0,0,0,0,1]

It is noted that table D is also representable as an ordered set of vectors, peach of which represent a line of table D:

[8,27,0,0,0,2,0,0,11,12,19,19,22,0,0,10,13,11,13,22,0,0,0,0,0,0,0,0,0,0,0,0,2,1,0,0, 0,0,0,0]; [18,0,0,4,0,9,0,0,0,9,0,0,0,22,0,16,0,0,0,15,13,0,12,0,0,0,28,1,24,0,0,1,0,1, 1,0,0,0,0,0]; [0,23,0,0,23,0,0,23,0,0,1,0,13,0,0,0,24,0,0,1,0,25,0,0,13,0,0,5,22,0,11, 2,0,0,1,1,0,0,0,0]; [0,0,0,12,18,19,0,0,29,0,0,0,0,0,25,0,0,13,0,0,0,11,0,16,20,0,11, 0,16,23,0,0,1,0,0,1,1,0,0,0]; [20,0,20,0,0,0,12,0,20,0,0,8,0,0,23,0,0,16,0,7,0,10,0,0, 3,16,0,0,0,11,13,0,0,0,0,0,1,1,0,0]; [13,0,9,0,0,0,8,0,0,0,23,14,0,0,0,17,0,0,27,29,0, 0,23,0,0,6,0,22,0,27,0,10,0,0,0,0,0,1,1,0]; [29,17,0,0,11,0,0,28,0,25,0,0,25,24,0,0,0, 0,19,11,11,0,0,25,0,0,0,0,0,0,0,0,0,0,0,0,0,0,1,1]; [26,0,7,19,0,0,11,7,0,0,0,0,0,19, 6,0,4,0,0,0,21,0,8,11,0,18,17,0,0,0,0,0,2,0,0,0,0,0,1]

It is noted that table E is also representable as an ordered set of vectors, each of which represent a line of table E:

[0,0,0,0,21,0,0,24,0,1,0,0,0,0,0,0,0,4,0,0,2,1,0,0,0,0,0,0,0,0,0,0,0,0,0,0,0,0,0,0,0, 0,0,0]; [0,0,20,19,0,18,0,0,0,0,0,0,0,14,0,0,0,0,0,0,0,1,1,0,0,0,0,0,0,0,0,0,0,0,0,0,0, 0,0,0,0,0,0,0]; [0,0,0,0,23,14,20,0,0,0,0,0,0,0,0,0,0,0,13,0,0,0,1,1,0,0,0,0,0,0,0,0,0, 0,0,0,0,0,0,0,0,0,0,0]; [4,0,0,0,0,0,0,14,0,0,0,0,0,0,0,0,29,17,0,0,0,0,0,1,1,0,0,0,0, 0,0,0,0,0,0,0,0,0,0,0,0,0,0,0]; [0,0,4,11,0,0,0,0,2,0,0,0,0,12,0,0,0,0,0,0,0,0,0,0,1,1, 0,0,0,0,0,0,0,0,0,0,0,0,0,0,0,0,0,0]; [0,0,0,0,9,0,0,0,0,0,0,0,0,0,0,11,0,11,14,0,0,0, 0,0,0,1,1,0,0,0,0,0,0,0,0,0,0,0,0,0,0,0,0,0]; [0,0,0,0,0,0,0,0,0,13,0,14,0,7,0,0,20,0, 0,0,0,0,0,0,0,0,1,1,0,0,0,0,0,0,0,0,0,0,0,0,0,0,0,0]; [0,0,0,0,6,0,28,0,9,0,0,25,0,0,0, 0,0,0,0,0,0,0,0,0,0,0,0,1,1,0,0,0,0,0,0,0,0,0,0,0,0,0,0,0]; [0,0,0,0,0,24,0,0,0,0,0,0,0, 0,0,15,0,0,15,23,0,0,0,0,0,0,0,1,1,0,0,0,0,0,0,0,0,0,0,0,0,0,0]; [0,3,0,0,0,0,16,29, 0,0,0,0,0,0,0,0,0,0,0,0,1,0,0,0,0,0,0,0,0,1,1,0,0,0,0,0,0,0,0,0,0,0,0,0]; [0,0,0,14,0,0, 0,0,18,0,0,0,0,0,0,0,0,0,0,19,0,0,0,0,0,0,0,0,0,0,1,1,0,0,0,0,0,0,0,0,0,0,0,0]; [0,0,0, 0,0,0,0,0,0,2,0,0,2,2,21,0,0,0,0,0,0,0,0,0,0,0,0,0,0,0,1,1,0,0,0,0,0,0,0,0,0,0,0]; [0, 7,0,0,0,0,0,0,0,0,0,1,23,0,0,0,22,0,0,0,0,0,0,0,0,0,0,0,0,0,0,0,1,1,0,0,0,0,0,0,0,0,0, 0]; [0,0,0,0,0,0,0,0,0,0,0,26,26,0,11,0,0,0,0,4,0,0,0,0,0,0,0,0,0,0,0,0,0,1,1,0,0,0,0, 0,0,0,0,0]; [8,0,1,0,0,0,0,0,0,0,0,0,0,0,0,8,0,0,0,0,0,0,0,0,0,0,0,0,0,0,0,0,0,0,1,1,0, 0,0,0,0,0,0,0]; [0,20,5,3,0,0,0,0,0,0,0,0,0,0,0,0,0,0,0,18,0,0,0,0,0,0,0,0,0,0,0,0,0,0, 0,1,1,0,0,0,0,0,0]; [15,0,0,0,0,0,0,0,27,0,17,0,0,0,17,0,0,0,0,0,0,0,0,0,0,0,0,0,0,0, 0,0,0,0,0,0,1,1,0,0,0,0,0,0]; [0,0,0,0,0,4,0,0,0,18,25,0,0,0,0,0,0,0,22,0,0,0,0,0,0,0, 0,0,0,0,0,0,0,0,0,0,0,1,1,0,0,0,0]; [0,24,0,0,0,0,0,0,0,0,0,0,16,0,0,0,0,0,0,0, 0,0,0,0,0,0,0,0,0,0,0,0,0,0,0,0,1,1,0,0,0,0]; [0,0,0,0,0,0,0,7,0,0,20,0,0,0,0,26,0,5,0, 0,2,0,0,0,0,0,0,0,0,0,0,0,0,0,0,0,0,0,0,1,0,0,0,0]; [0,0,0,0,0,0,13,0,0,0,0,20,0,0,0,0, 1,0,0,0,0,0,0,0,0,0,0,21,0,0,0,0,0,0,0,0,0,0,0,0,2,1,0,0]; [0,0,0,0,0,0,0,0,0,12,0,0,0, 0,0,0,0,0,0,10,0,0,0,19,0,0,0,0,0,0,0,0,0,0,0,0,0,0,0,0,1,1,1,0]; [0,0,2,0,0,0,0,0,0,0, 0,0,0,0,0,3,0,0,0,0,5,0,0,0,0,10,0,0,0,0,0,0,0,0,0,0,0,0,0,0,0,1,1]; [19,0,0,0,0,0,0, 0,16,0,0,0,26,0,3,0,0,0,0,0,0,0,0,0,0,0,0,0,0,0,0,0,0,0,0,0,0,0,0,0,2,0,0,1]

It is noted that table F is also representable as an ordered set of vectors, each of which represent a line of table F:

[0,0,0,0,13,0,0,0,0,18,11,0,14,0,9,0,0,0,20,0,0,0,022,0,2,1,0,0,0,0,0,0,0,0,0,0,0, 0,0,0,0,0]; [0,0,0,0,0,20,24,4,24,0,8,0,0,0,0,0,0,0,6,0,0,0,0,0,0,0,1,1,0,0,0,0,0,0,0, 0,0,0,0,0,0,0,0,0]; [0,0,0,0,0,0,0,0,0,0,0,0,0,23,0,0,0,1,11,29,17,27,0,0,0,0,0,1,1,0, 0,0,0,0,0,0,0,0,0,0,0,0,0,0]; [0,0,7,18,0,0,0,21,0,0,0,22,0,0,0,29,0,0,0,1,0,26,0,0,0, 0,0,0,1,1,0,0,0,0,0,0,0,0,0,0,0,0,0,0]; [0,0,19,1,0,0,0,0,0,0,0,0,0,0,22,0,24,0,0,0,0, 0,15,0,6,0,0,0,0,1,1,0,0,0,0,0,0,0,0,0,0,0,0,0]; [26,3,8,0,0,16,9,0,0,0,0,0,0,0,28,0,0, 0,0,0,0,0,0,0,0,0,0,0,0,0,1,1,0,0,0,0,0,0,0,0,0,0,0,0,0]; [4,0,0,0,0,12,22,0,18,0,0,0,9, 7,0,0,27,0,0,0,0,0,0,0,0,0,0,0,0,0,0,1,1,0,0,0,0,0,0,0,0,0,0,0]; [0,12,0,0,1,0,0,0,0,0, 0,0,21,0,0,17,0,0,0,0,4,0,0,4,0,1,0,0,0,0,0,0,1,1,0,0,0,0,0,0,0,0,0,0]; [0,0,0,8,0,0,0, 0,28,0,8,21,0,0,0,4,0,0,0,0,0,0,12,0,0,0,0,0,0,0,0,0,0,1,1,0,0,0,0,0,0,0,0,0]; [0,0,0, 0,0,0,0,0,0,7,26,0,0,0,23,0,0,0,0,0,0,0,9,3,28,0,0,0,0,0,0,0,0,0,1,1,0,0,0,0,0,0,0,0]; [9,0,0,0,0,0,0,30,29,0,0,0,0,10,0,0,0,17,0,0,0,4,0,0,0,0,0,0,0,0,0,0,0,0,0,1,1,0,0,0, 0,0,0,0]; [0,0,0,0,8,0,0,0,0,0,0,0,8,0,0,0,12,0,0,0,2,0,0,14,12,0,0,0,0,0,0,0,0,0,0,0, 1,1,0,0,0,0,0,0]; [0,0,6,20,17,0,0,2,0,0,0,17,0,0,0,26,0,0,0,0,0,0,0,0,0,0,0,0,0,0,0,0, 0,0,0,0,0,1,1,0,0,0,0,0]; [0,6,0,0,0,30,30,0,0,0,0,0,0,0,0,0,24,0,0,0,24,0,16,0,0,0,0, 0,0,0,0,0,0,0,0,0,0,0,1,1,0,0,0,0]; [0,0,0,0,0,0,0,0,0,6,0,30,0,5,0,0,0,27,0,21,0,1,0, 0,0,2,0,0,0,0,0,0,0,0,0,0,0,0,0,1,0,0,0,0]; [0,0,0,0,0,0,0,0,0,0,0,0,0,0,0,0,0,8,0,0,0, 0,0,0,9,0,0,0,0,0,26,0,2,25,14,0,0,6,0,0,2,1,0,0]; [0,0,0,0,0,0,0,0,0,0,0,0,0,0,0,0,20, 0,0,0,0,0,0,0,0,9,15,0,0,29,13,0,0,29,0,0,0,0,0,0,1,1,1,0]; [18,0,0,0,0,22,0,17,0,0,0, 0,0,0,0,0,0,0,3,0,0,0,0,0,0,0,22,0,2,10,0,0,0,0,0,0,0,0,0,0,0,0,1,1]; [0,0,0,0,0,0,0,0, 0,8,0,29,0,0,0,0,0,0,17,4,0,0,0,0,0,0,0,0,0,0,0,0,0,0,0,0,0,0,19,17,2,0,0,1]

It is noted that table G is also representable as an ordered set of vectors, each of which represent a line of table G:

[2,0,0,0,0,0,0,0,0,0,29,6,0,0,0,0,0,28,3,28,8,0,0,0,12,20,0,0,0,20,2,1,0,0,0,0,0,0,0, 0,0,0,0,0]; [7,0,0,0,7,9,0,16,0,5,0,0,24,0,0,0,0,17,0,0,0,27,0,0,0,0,0,0,8,3,0,1,1,0,0, 0,0,0,0,0,0,0,0,0]; [0,22,0,23,11,22,0,0,25,12,0,0,0,0,0,0,21,0,0,0,0,0,0,0,0,0,16,2, 22,0,0,0,1,1,0,0,0,0,0,0,0,0,0,0]; [0,25,7,0,0,0,1,0,14,0,0,0,0,0,27,16,23,0,27,0,0,0, 0,27,0,30,0,0,0,0,0,0,0,1,1,0,0,0,0,0,0,0,0,0]; [0,19,0,3,0,12,0,0,30,0,0,0,0,0,0,28,0, 0,28,0,0,0,28,0,0,22,0,0,0,29,1,0,0,0,1,1,0,0,0,0,0,0,0,0]; [0,0,9,0,0,0,0,4,0,0,0,0, 22,21,4,9,29,0,0,0,0,0,7,14,0,0,0,15,0,0,0,0,0,0,0,1,1,0,0,0,0,0,0,0]; [24,0,0,0,0,0,0, 0,0,0,12,25,28,29,30,0,0,0,0,18,20,13,0,11,0,0,0,0,0,0,0,0,0,0,0,0,1,1,0,0,0,0,0,0]; [0,29,0,0,0,4,6,0,25,6,0,0,0,0,0,0,0,0,0,11,0,29,0,0,5,0,12,0,7,0,0,0,0,0,0,0,0,1,1,0, 0,0,0,0]; [0,0,28,0,0,0,28,0,0,0,10,0,0,28,0,0,10,0,0,14,2,0,0,0,22,0,14,8,0,0,0,0,0,0, 0,0,0,0,1,1,0,0,0,0]; [0,0,0,7,19,0,0,22,0,0,6,4,0,0,0,0,0,7,0,0,5,0,20,0,0,0,0,5,0,8, 2,0,0,0,0,0,0,0,0,1,0,0,0,0]; [0,0,0,9,0,0,0,0,0,0,0,27,0,0,12,0,0,0,0,0,0,0,21,0,0,0, 0,0,0,0,0,0,0,14,0,0,17,22,0,0,2,1,0,0]; [27,0,0,0,0,0,0,0,0,0,0,0,15,21,0,0,0,0,18,0, 0,0,0,0,0,24,0,0,0,0,0,18,12,0,0,11,0,0,0,0,1,1,1,0]; [0,0,0,0,0,0,20,0,0,0,0,0,0,0,0, 0,0,0,0,0,0,0,0,0,0,0,0,0,0,0,0,0,4,26,30,0,0,0,0,17,0,0,1,1]; [0,0,0,0,8,0,0,0,0,1,0, 0,0,0,0,0,0,11,0,0,0,0,0,0,12,0,0,0,13,0,0,0,0,0,0,0,0,0,12,0,2,0,0,1]

It is noted that table TI is also representable as an ordered set of vectors, each of which represent a line of table H:

[0,0,0,23,0,0,0,0,12,25,12,24,0,0,0,0,23,0,0,0,3,13,0,13,0,28,0,15,11,0,0,29,2,1,0,0, 0,0,0,0,0,0,0,0]; [0,0,21,0,0,14,0,25,0,0,0,14,0,0,14,14,27,0,0,1,0,19,7,0,28,0,0,0,0, 8,8,0,0,1,1,0,0,0,0,0,0,0,0,0]; [19,0,16,0,0,5,0,18,0,0,0,0,6,2,0,17,0,0,14,20,0,0,25, 0,13,0,4,0,0,6,0,0,0,0,1,1,0,0,0,0,0,0,0,0]; [24,1,0,20,29,0,30,0,14,0,28,0,0,0,0,0,0, 2,20,0,0,0,0,17,0,0,0,0,22,0,0,6,1,0,0,1,1,0,0,0,0,0,0,0]; [15,11,11,0,23,27,14,0,0,0, 0,0,0,9,15,0,0,30,0,0,0,0,13,0,2,0,27,0,0,0,7,0,0,0,0,0,1,1,0,0,0,0,0,0]; [0,0,10,0,0, 0,0,20,0,14,0,22,9,14,0,28,0,0,0,17,0,0,0,0,19,19,8,2,0,15,0,0,0,0,0,0,0,1,1,0,0,0,0, 0]; [0,0,0,0,0,0,0,0,23,18,2,0,23,0,0,0,0,0,13,0,13,0,0,0,0,13,0,3,2,0,0,3,0,0,0,0,0,0, 1,1,0,0,0,0]; [0,19,0,9,6,0,20,0,0,0,19,0,0,0,27,0,24,17,0,0,12,9,0,12,0,0,0,0,6,0,10, 0,2,0,0,0,0,0,0,1,0,0,0,0]; [0,0,0,11,14,0,0,0,0,0,0,0,0,29,0,0,0,0,0,0,0,0,0,4,0,0,13, 0,0,0,0,0,2,0,0,11,28,25,0,0,2,1,0,0]; [0,0,0,0,0,25,0,0,0,0,0,0,0,0,0,0,2,0,0,0,0,0, 23,0,0,0,0,0,0,0,0,0,0,19,23,0,0,0,0,2,1,1,1,0]; [0,0,0,0,0,0,0,0,28,0,0,0,0,0,0,0,0,0, 0,0,0,0,0,0,0,0,0,0,0,0,0,0,0,1,0,0,3,8,5,0,0,0,1,1]; [0,0,0,0,0,0,0,0,28,0,0,0,0,0,0,0,0,0, 0,0,19,16,0,0,0,0,0,0,0,0,0,18,7,0,0,17,9,2,0,0,1]

It is noted that table I is also representable as an ordered set of vectors, each of which represent a line of table 1:

[0,0,0,0,24,0,25,0,0,0,0,0,0,0,12,0,0,0,0,0,0,0,0,0,0,0,0,0,0,30,0,0,0,0,0,0,0,0,0,0, 2,1,0,0]; [0,0,0,0,0,0,0,0,0,0,0,0,0,19,0,0,0,0,5,0,0,18,0,0,0,0,0,0,0,0,0,0,0,0,0,0,0, 0,0,0,1,1,1,0]; [0,0,6,0,0,0,0,0,0,0,0,0,16,0,0,0,0,3,0,0,0,0,0,0,0,0,0,7,0,0,0,0,0,0,0, 0,0,0,0,0,0,0,1,1]; [18,0,0,0,0,0,0,0,0,0,13,0,0,0,0,0,0,0,0,0,11,0,0,0,0,4,0,0,0,0,0, 0,0,0,0,0,0,0,0,0,2,0,0,1]

The LDPC codes suggested in tables A-D, and I may be used in very high data rates (e.g. 1024 mbps, they may be implemented for substantially other data rates as well). Other codes may be used.

It is noted that some of the above discussed implementations are manifested in those codes, e.g., the codes in some embodiments:
i. Are designed for 16 QAM modulation over OFDM, by prioritizing between odd and even LLRs.
ii. Work with QPSK to give improved high data rates up to 480 Mbps.
iii. Work with 64-QAM to allow rates up to 1440 Mbps and can go as high as 1536 with 4/5 code.
iv. Are 1200 bits long so the added latency of collecting the data and processing is very small and in fact equivalent to the latency of collecting the existing WiMedia interleaver data bit vectors that are 2400 bits long.

Other specific ranges may be used. According to an embodiment of the invention, the codes used for the first and/or the second parity check process implement one or more of the following:
i. Interleaving as part of the code thus vacating a need for a separate interleaver;
ii. The layers are organized to allow the use of simple memory during the data collection, iterations and data forwarding to the next block;
iii. The layered approach can be implemented even when there are common elements between the layers by simply using previous results for elements that are still not ready from the previous layer. The code is structured to give good performance even when the common elements between the layers are not used;
iv. The code structure gives good results for both believe propagation and min-sum decoding.
v. The code structure gives good results even under SNR estimation error using believe propagation. The code is sparse so the impact of SNR estimation is small. The receiver should make a deliberate error to minimize the maximal error under SNR estimation error conditions;
vi. The code is structured in a layered approach. This allows the receiver to start the decoding from the layer that has the best effective SNR. The receiver can also start from other groups of bits containing the best SNR. This mechanism improves the performance under bad channels since it allows the first iterations to converge to the correct direction.

According to an embodiment of the invention, the first and/or second parity check codes implement LDPC codes that are combined with dual-carrier modulation (DCM) transmission. DCM modulation allows transmission of the coded information on two tones. LDPC can be combined with DCM and with similar techniques that allow transmission of the coded information on more than two tones. The DCM can be used by the receiver to improve die LLRs for the LDPC decoder. The DCM can be used in an iterative way together with the LDPC decoder to improve the LLRs at the output of the DCM after each iteration.

While the codes and properties thereof where described in greater details, it is clear to a person who is skilled in the art that systems that utilize such codes—both transmitters and receivers (using encoders and decoders) are disclosed herein, as well as methods for encoding, decoding and designing such codes, an as well as computer program products that are used for encoding, decoding, and designing such codes.

Tables E through I disclose LDPC codes, and are incorporated herein by reference. The codes set forth in tables E-H conveniently allow better parallel implementation, which in turn allow higher bit rates using a given clock. Other codes may be used.

Referring now to encoder 220 and to the encoding of method 500, it is noted that according to an embodiment of the invention, the encoding of a packet of a fundamental code at the transmitter generates parity bits p=(p0, . . . , pm−1) based on an information block s=(s0, . . . , sk−1), and transmits the parity bits along with the information bits (combined as the first codeword portion) e.g. over the data tones. For the expanded code the transmitter also generates the extra set of parity bits pe=(pe, 0, . . . , pe, m−1) for the second codeword portion and transmits them over the guard tones.

The encoder receives the information block s=(s0, . . . , sk−1) and uses the expanded matrix H′ (or an equivalent process) in order to determine the parity bits and the extra parity-bits.

One method of encoding is to determine a generator matrix G from H′ such that GH′^{T}=0. A k-bit information block s1×k can be encoded by the code generator matrix Gk×n via the operation x=s G to become an n-bit codeword x1×n, with codeword

x=[sp pe]=[s0, s1, . . . , sk−1, p0, p1, . . . , pm−1, pe, 0, pe, 1, . . . , pe, m−1]

where p0, . . . pm−1 are the parity-check bits, pe, 0, . . . pe, m−1 are the extra parity-check bits and s0, . . . sk−1 are the information bits. Encoding an LDPC code from G has relatively high complexity (quadratic complexity in the code length n) since G is not sparse. Hence, a common method for encoding LDPC codes is to perform the encoding directly through the sparse parity-check matrix He by solving the following linear equations system: H′x^{T}=H′[s p pₑ]^{T}=0. It is noted that the solving may include, according to different embodiments of the invention, solving the linear equations system as is, and may also include providing a vector solution that satisfy the equations of the system otherwise.

It is noted that, according to several embodiments of the invention, encoder 220 (and/or the encoding of method 500) implements an encoding process which is, or which is an equivalent of, solving the linear equations system: H′x^{T}=H[s p pₑ]^{T}=0, for a matrix H′ which is disclosed in one of tables A-H. According to an embodiment of the invention, encoder 220 (and/or the encoding of method 500) implements a family of such encoding processes corresponding to the matrixes of tables A-H. Especially, according to an embodiment of the invention, encoder 220 implements a family of encoding processes which are, or which are the equivalents of, solving the linear equations systems: H′x^{T}=H[s p pₑ]^{T}=0, for the different matrixes H′ which are disclosed in tables E, F, G, and H. Other encoders 220 may implement families of encoding processes which corresponds to any two or three matrixes selected from this group.

By using a parity-check matrix with a lower triangular form efficient linear encoding complexity can be achieved [1]. In this case the encoding procedure is performed using a simple Gaussian elimination procedure In order to allow such linear encoding complexity, the proposed parity-check matrices are based on a dual diagonal form that allows simple lower triangulation of the parity-check matrix. This is done by replacing the last row of H with a block row that is the sum of all the block rows of H, and then set the last row to be the first one. This results in a lower triangular block matrix H_{LT}, which defines the same fundamental code. Furthermore, the first block row of the block matrix [C D] is replaced by the sum of all block rows of [C D], resulting in a lower triangular matrix [C. D_{LT}]. Then, the resulting matrix

$${H}_{e , LT} = [ \begin{matrix}{H}_{LT} & 0 \\ {C}_{*} & {D}_{LT}\end{matrix} ]$$

is a lower triangular matrix defining the same expanded code, which allows simple linear encoding via Gaussian elimination.

Table I includes an extension Matrix for LDPC codes, for expanding a 1200 bits code to a 1320 bit code by adding the extension as the lower part and adding zeros to the right, Such an expansion may be implemented in both encoding and decoding, according to different embodiments of the invention. Other matrices may be used.

Providing now an explanatory example for an expansion of code, as can be utilized in the invention. A 15/22 code currently used (for a first parity check process) can be described in the format of the existing standard as:

Use a 1/3 code as described in WiMedia and puncture using a 3/4 puncturing patterns Below is exemplified 5 repetition of the same 3/4 puncturing pattern (5 repetitions are presented in order to simplify the description of the extended code although one repetition is enough to explain the existing code):

### Source Data:

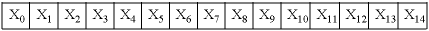

### Encoded Data: (Stolen Bits are Grayed).

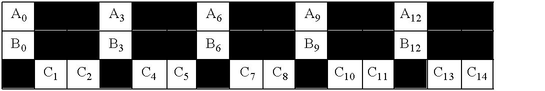

### Sent/Received Data:

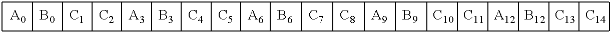

Bit Inserted Data: (Inserted Dummy Bits are grayed).

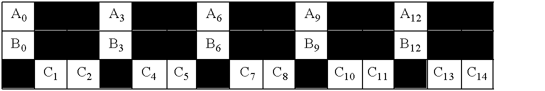

### Decoded Data:

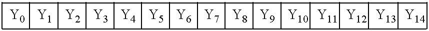

An extended code (which corresponds to the second parity check process, according to an embodiment of the invention) may de defined by a long puncturing pattern that adds more redundancy bits to an existing good code making them optional in both the transmitter and receiver. In the example bits B5 and A14 are added to add 10% additional redundancy over the guard tones creating an effective code of 15/22 that can be transmitted and/or received also as a good 3/4 code.

### Source Data:

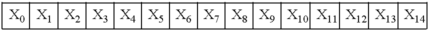

### Encoded Data: (Stolen Bits are Grayed).

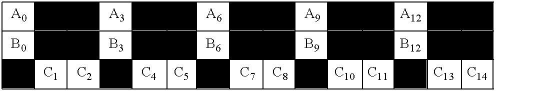

### Sent/Received Data:

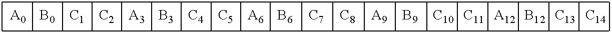

### Bit Inserted Data: (Inserted Dummy Bits are Grayed).

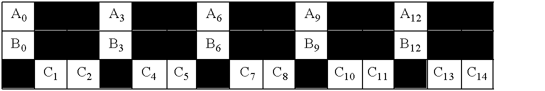

### Decoded Data:

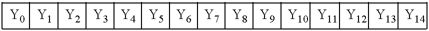

In the above given examples bits are transmitted up-down left to right. B5 and A14 are transmitted as the second codeword portion.

The following table illustrates performance improvement of expanded 15/22 code compared to the original rate 3/4 code, according to one embodiment:

| | | Mean improvement | |
|---|---|---|---|
| | | over all 100 | |
| CM | TFC | realizations | Comments |
| CM1 | 1 | 0.8243 dB | Packet length |
| | | | 1 Kbyte |
| CM2 | 1 | 0.7510 dB | Packet length |
| | | | 1 Kbyte |
| CM1 | 6 | 0.6724 dB | Packet length |
| | | | 1 Kbyte |
| CM2 | 6 | 0.6678 dB | Packet length |
| | | | 1 Kbyte |

Embodiments of the invention may include an article such as a computer or processor readable medium, or a computer or processor storage medium, such as for example a memory, a disk drive, or a USB flash memory, encoding, including or storing instructions, e.g. computer-executable instructions, which when executed by a processor or controller, carry out methods disclosed herein.

According to an embodiment of the invention, a first computer readable medium having a first computer readable code for transmitting information embodied therein is disclosed, the first computer readable code including instructions (which may be executed by one or more software or hardware processors) for: (a) encoding a data bit vector to provide an codeword that includes a first codeword portion and a second codeword portion; wherein the first codeword portion is decodable by a first parity check process to yield the data bit vector; wherein the codeword is decodable by a second parity check process to yield the data bit vector; and (b) transmitting the codeword.

According to an embodiment of the invention, the first computer readable code may further include instructions for transmitting the first and the second codeword portions in different communication channels.

According to an embodiment of the invention, the first computer readable code may further include instructions for transmitting the first codeword portion in a first communication channel, and for transmitting the second codeword portion in at least one sub-channel of the first communication channel in which the first codeword portion is not transmitted.

According to an embodiment of the invention, the first computer readable code may further include instructions for encoding the data bit vector to provide the codeword that is decodable by a second first low-density parity check (LDPC) process to yield the data bit vector, wherein the first codeword portion is decodable using a first LDPC process to yield the data bit vector.

According to an embodiment of the invention, the first computer readable code may further include instructions for providing the codeword in which information of a first bit is more useful for at least one of the first and the second parity-check processes than information of a second bit (e.g. for transmitting the first bit in a first symbol and the second bit in a second symbol, wherein the first symbol is less susceptible to errors during the transmitting than the second symbol).

According to an embodiment of the invention, a second computer readable medium, having a second computer readable code (which is executable by one or more software or hardware processors) for receiving information, the second computer readable code including instructions for: (a) attempting to receive a first codeword portion and a second codeword portion of a transmitted codeword, wherein the first codeword portion is of a first length; (b) selecting between a first parity check process and a second parity check process, wherein the first parity check process includes parity check of messages of the first length and the second parity check process includes parity check for longer messages; and (c) decoding at least a portion of the codeword by the selected parity check process, to receive a decoded data bit vector.

According to an embodiment of the invention, the second computer readable code may further include instructions for selecting the parity check process in response to a result of an evaluation of a reception of at least one of the first and the second codeword portions.

According to an embodiment of the invention, the second computer readable code may further include instructions for attempting to receive the first and the second codeword portions in different communication channels.

According to an embodiment of the invention, the second computer readable code may further include instructions for attempting to receive the first codeword portion in a first communication channel, and attempting to receive the second codeword portion in at least one sub-channel of the first communication channel in which the first codeword portion is not transmitted.

According to an embodiment of the invention, the second computer readable code may further include instructions for selecting between the first parity check process which is a first low-density parity check (LDPC) process and the second parity check process that is a second LDPC process.

According to an embodiment of the invention, the second computer readable code may further include instructions for selecting between a first parity check process which is equivalent to processing the first codeword portion based on a first parity check matrix and a second parity check process which is equivalent to processing the codeword based on a second parity check matrix that includes the first parity check matrix, According to an embodiment of the invention, the second parity check process may be equivalent to processing the codeword based on the second parity check matrix that is substantially the second parity check process matrix set out in an table out of tables A-H.

It is noted that also disclosed are different encoders and decoders, as well as methods and computer program products for encoding and decoding, which utilize encoding/decoding processes that correspond to the parity check matrixes that are disclosed in tables A-H, and especially in tables E, F, G, and H.

According to several embodiments of the invention, an encoder is disclosed (and correspondingly a method and/or a computer program product for encoding), wherein the encoder may be configured to code a data bit vector by an encoding process which is, or which is an equivalent of, solving the linear equations system: H′x^{T}=H[s p pₑ]^{T}=0, for a matrix H′ which is disclosed in one of tables A-H, and especially in table E, F, G, or H. According to an embodiment of the invention, such an encoder (and/or the encoding of such method or computer program product) implements a family of such encoding processes corresponding to the matrixes of tables A-H. Especially, according to an embodiment of the invention, such an encoder (and/or the encoding of such method or computer program product) implements a family of encoding processes which are, or which are the equivalents of, solving the linear equations systems: H′x^{T}=H[s p pₑ]^{T}=0, for the different matrixes H′ which are disclosed in tables E, F, G, and H. Other encoders and/or methods and/or computer program products may implement families of encoding processes which corresponds to any two or three matrixes selected from this group.

The present invention can be practiced by employing conventional tools, methodology, and components. Accordingly, the details of such tools, component, and methodology are not set forth herein in detail. In the previous descriptions, numerous specific details are set forth, in order to provide a thorough understanding of the present invention. However, it should be recognized that the present invention might be practiced without resorting to the details specifically set forth.

Only exemplary embodiments of the present invention and but a few examples of its versatility are shown and described in the present disclosure. It is to be understood that the present invention is capable of use in various other combinations and environments and is capable of changes or modifications within the scope of the inventive concept as expressed herein.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A transmitter, comprising:
an encoder configured to encode a data bit vector to provide a codeword that comprises a first codeword portion and a second codeword portion; wherein the first codeword portion is decodable by a first parity check process to yield the data bit vector; wherein the codeword is decodable by a second parity check process to yield the data bit vector; and
a communication module, for transmitting the codeword.

2. The transmitter according to claim 1, wherein the communication module is further adapted to transmit the first and the second codeword portions in different communication channels.

3. The transmitter according to claim 1, wherein the communication module is further adapted to transmit the first codeword portion in a first communication channel, and to transmit the second codeword portion in at least one sub-channel of the first communication channel in which the first codeword portion is not transmitted.

4. The transmitter according to claim 1, wherein the encoder is further adapted to encode the data bit vector to provide the codeword that is decodable by a second low-density parity check (LDPC) process to yield the data bit vector, wherein the first codeword portion is decodable using a first LDPC process to yield the data bit vector.

5. The transmitter according to claim 1, wherein the encoder may be adapted to provide the codeword in which information of a first bit is more useful for at least one of the first and the second parity-check processes than information of a second bit, and wherein the communication module may be adapted to transmit the codeword using quadrature amplitude modulation of an order of at least 16, and to transmit the first bit in a first symbol and the second bit in a second symbol, wherein the first symbol is less susceptible to errors during the transmitting than the second symbol.

6. The transmitter according to claim 1, wherein the encoder may be adapted to encode the data bit vector to provide the codeword x by solving the linear equations system: H′x^{T}=0, for a matrix H′ that includes elements P_{i,j}, wherein each of the elements P_{i,j} contains: (a) the value “0” if P_{i,j} represents a 30×30 zero matrix; or (b) a value equal to 1+s if P_{i,j}=I^{s}, wherein I^{s} is one of a set of 30×30 permutation matrices; wherein each permutation matrix is a cyclically right shifted identity matrix, denoted as I^{s} for a shift s, where s is an integer between 0 and 29, wherein the matrix H′ is representable as an ordered set of vectors selected from a group of ordered sets of vectors that consists the order sets of vectors HA, HB, HC, HD, HE, HF, HG, HH, and HI, wherein the first bits of the codewords are the bits of the data bit vector; wherein:
HA is ([0,0,25,0,0,0,30,0,0,0,0,0,0,0,7,26,0,0,0,0,2,1,0,0,0,0,0,0,0,0,0,0,0,0,0,0, 0,0,0,0,]; [0,0,0,11,0,0,0,0,0,30,12,0,9,0,0,0,0,0,0,0,1,1,0,0,0,0,0,0,0,0,0,0,0, 0,0,0,0,0,0]; [30,0,0,0,0,0,28,8,0,0,0,0,0,0,0,29,0,0,0,0,0,0,1,1,0,0,0,0,0,0,0,0,0,0, 0,0,0,0,0,0]; [0,0,0,0,0,29,0,0,12,0,0,4,0,0,0,0,0,0,17,0,0,0,0,1,1,0,0,0,0,0,0,0,0, 0,0,0,0,0,0,0]; [0,21,0,0,0,0,0,0,0,0,29,0,0,0,0,0,0,23,0,28,0,0,0,0,1,1,0,0,0,0,0,0, 0,0,0,0,0,0,0,0]; [24,0,0,0,0,0,23,0,0,0,0,0,0,0,26,7,0,0,0,0,0,0,0,0,0,1,1,0,0,0,0, 0,0,0,0,0,0,0,0,0]; [0,0,30,0,0,10,0,0,0,0,0,0,0,1,0,0,0,3,0,0,0,0,0,0,0,0,1,1,0,0,0, 0,0,0,0,0,0,0,0,0]; [0,0,0,3,9,0,0,0,0,6,0,0,27,0,0,0,0,0,0,0,0,0,0,0,0,0,0,1,1,0,0, 0,0,0,0,0,0,0,0,0]; [0,0,0,15,23,0,0,0,0,13,0,0,23,0,0,0,0,0,0,0,0,0,0,0,0,0,0,0,1,1, 0,0,0,0,0,0,0,0,0,0]; [0,0,0,0,0,0,0,0,0,0,0,13,0,0,0,0,17,0,0,3,1,0,0,0,0,0,0,0,0,1, 1,0,0,0,0,0,0,0,0,0]; [0,0,0,23,0,0,0,0,19,19,0,0,18,0,0,0,0,0,0,0,0,0,0,0,0,0,0,0,0, 0,1,1,0,0,0,0,0,0,0,0]; [10,0,0,0,0,0,25,29,0,0,0,0,0,0,0,2,0,0,0,0,0,0,0,0,0,0,0,0, 0,0,0,1,1,0,0,0,0,0,0,0]; [13,0,0,0,0,7,21,0,0,0,0,0,0,0,0,10,0,0,0,0,0,0,0,0,0,0,0, 0,0,0,0,0,1,1,0,0,0,0,0,0]; [0,0,15,29,0,0,0,0,0,17,0,0,13,0,0,0,0,0,0,0,0,0,0,0,0,0, 0,0,0,0,0,0,0,1,1,0,0,0,0,0]; [3,0,0,0,0,0,0,0,0,0,0,17,0,0,0,0,24,0,22,0,0,0,0,0,0, 0,0,0,0,0,0,0,0,0,1,1,0,0,0,0]; [0,13,0,0,0,0,0,0,0,0,22,0,0,0,2,0,22,0,0,0,0,0,0,0, 0,0,0,0,0,0,0,0,0,0,0,1,1,0,0,0]; [0,0,0,0,0,0,0,0,1,0,0,0,0,18,0,0,0,19,11,0,0,0,0, 0,0,0,0,0,0,0,0,0,0,0,0,0,1,1,0,0]; [15,5,0,0,0,0,6,0,0,0,0,0,0,0,0,19,0,0,0,0,0,0,0, 0,0,0,0,0,0,0,0,0,0,0,0,0,0,1,1,0]; [0,0,0,0,11,0,0,12,0,0,0,0,0,25,0,0,0,0,0,6,0,0, 0,0,0,0,0,0,0,0,0,0,0,0,0,0,0,0,1,1]; [0,0,0,7,0,0,0,0,0,16,0,0,4,0,0,0,0,0,15,0,2,0, 0,0,0,0,0,0,0,0,0,0,0,0,0,0,0,0,0,1]);
HB is ([7,0,0,0,10,5,15,0,1,0,0,0,15,0,0,0,0,27,0,0,0,0,0,0,0,2,1,0,0,0,0,0,0,0,0,0, 0,0,0,0]; [27,0,0,29,1,0,0,0,3,13,0,6,0,0,0,0,0,0,0,0,12,0,0,0,0,0,1,1,0,0,0,0,0,0,0, 0,0,0,0,0]; [0,3,0,0,0,0,0,0,0,0,0,0,21,0,11,0,2,10,0,24,0,0,3,0,0,0,0,1,1,0,0,0,0,0, 0,0,0,0,0,0]; [4,0,0,0,0,12,0,0,0,0,22,0,13,0,0,0,6,0,0,0,0,0,22,0,18,0,0,0,1,1,0,0, 0,0,0,0,0,0,0]; [0,0,11,0,13,0,0,17,0,0,0,0,0,0,0,16,0,16,0,4,21,0,0,0,0,0,0,0,0, 1,1,0,0,0,0,0,0,0,0,0]; [18,0,28,0,0,0,0,0,16,0,25,0,23,0,0,0,0,0,0,26,0,0,0,22,0,0, 0,0,0,0,1,1,0,0,0,0,0,0,0,0]; [23,0,0,0,0,0,0,0,26,0,0,0,25,24,0,0,18,19,24,0,0,0,0, 0,0,0,0,0,0,0,0,1,1,0,0,0,0,0,0,0]; [0,0,0,19,0,0,30,0,0,0,0,24,0,0,0,0,0,0,0,0,26,0, 10,0,11,1,0,0,0,0,0,0,1,1,0,0,0,0,0,0]; [0,0,0,0,11,0,0,0,20,0,0,0,0,0,6,17,0,2,0,0, 0,0,24,3,0,0,0,0,0,0,0,0,0,1,1,0,0,0,0,0]; [15,27,0,0,16,0,0,0,0,11,0,0,0,0,0,26,0, 0,0,0,0,15,0,26,0,0,0,0,0,0,0,0,0,0,1,1,0,0,0,0]; [9,0,17,0,23,0,0,24,0,0,0,0,0,0,0, 0,0,30,0,0,0,18,0,0,5,0,0,0,0,0,0,0,0,0,0,1,1,0,0,0]; [11,0,0,0,0,0,26,0,11,6,0,0,0, 0,20,0,0,8,0,0,0,0,19,0,0,0,0,0,0,0,0,0,0,0,0,0,1,1,0,0]; [0,0,0,7,0,0,0,0,24,0,0,11, 30,0,0,0,0,22,10,0,0,7,0,0,0,0,0,0,0,0,0,0,0,0,0,0,0,1,1,0]; [0,25,0,0,26,0,0,14,0, 0,0,0,9,7,0,0,0,0,17,0,0,0,7,0,0,0,0,0,0,0,0,0,0,0,0,0,0,0,1,1]; [0,0,0,0,7,15,0,0,6, 0,24,0,2,28,0,0,0,0,0,0,0,0,29,0,0,2,0,0,0,0,0,0,0,0,0,0,0,0,0,1]);
HC is ([0,2,29,0,0,0,13,0,0,5,0,0,0,16,0,25,4,0,18,28,0,0,0,0,0,2,0,0,0,0,2,1,0,0,0, 0,0,0,0,0]; [10,0,26,0,0,0,0,17,0,0,0,26,6,0,24,0,0,27,0,0,0,0,24,0,0,0,27,0,0,15,0, 1,1,0,0,0,0,0,0,0]; [6,0,0,0,0,3,0,0,21,0,0,4,26,0,8,0,0,0,0,0,11,19,0,0,14,0,0,0,0, 6,0,0,1,1,0,0,0,0,0,0]; [0,0,0,12,0,16,20,0,0,0,30,0,0,0,0,0,8,0,4,30,0,8,0,0,12,26, 0,0,0,0,0,0,0,1,1,0,0,0,0,0]; [0,0,5,0,0,0,14,28,0,0,0,0,0,28,0,0,0,17,1,0,0,0,4,0,0, 24,0,0,1,0,1,0,0,0,1,1,0,0,0,0]; [27,27,0,0,6,0,0,0,28,21,0,0,14,0,0,18,0,0,0,0,0,0, 0,18,0,0,0,19,24,0,0,0,0,0,0,1,1,0,0,0]; [20,0,0,20,0,0,0,0,0,0,3,0,8,0,0,8,0,0,0, 29,0,4,0,0,4,0,16,0,0,12,0,0,0,0,0,0,1,1,0,0]; [25,0,0,0,23,0,0,0,14,0,21,0,22,0,0, 0,0,14,0,0,0,0,28,27,25,0,0,11,0,0,0,0,0,0,0,0,0,1,1,0]; [0,26,0,0,12,0,17,0,0,23,0, 0,0,12,0,0,0,0,11,0,1,0,0,25,0,0,0,14,6,0,0,0,0,0,0,0,0,0,1,1]; [0,0,0,16,0,1,26,9, 0,0,0,1,0,0,3,0,18,0,21,0,24,0,0,0,0,0,13,0,0,0,2,0,0,0,0,0,0,0,0,1]);
HD is ([8,27,0,0,0,2,0,0,11,12,19,19,22,0,0,10,13,11,13,22,0,0,0,0,0,0,0,0,0,0,0,0, 2,1,0,0,0,0,0,0]; [18,0,0,4,0,9,0,0,0,9,0,0,0,22,0,16,0,0,0,15,13,0,12,0,0,0,28,1, 24,0,0,1,0,1,1,0,0,0,0,0]; [0,23,0,0,23,0,0,23,0,0,1,0,13,0,0,0,24,0,0,1,0,25,0,0, 13,0,0,5,22,0,11,2,0,0,1,1,0,0,0,0]; [0,0,0,12,18,19,0,0,29,0,0,0,0,0,25,0,0,13,0,0, 0,11,0,16,20,0,11,0,16,23,0,0,1,0,0,1,1,0,0,0]; [20,0,20,0,0,0,12,0,20,0,0,8,0,0,23, 0,0,16,0,7,0,10,0,0,3,16,0,0,0,11,13,0,0,0,0,0,1,1,0,0]; [13,0,9,0,0,0,8,0,0,0,23, 14,0,0,0,17,0,0,27,29,0,0,23,0,0,6,0,22,0,27,0,10,0,0,0,0,0,1,1,0]; [29,17,0,0,11,0, 0,28,0,25,0,0,25,24,0,0,0,0,19,11,11,0,0,28,0,0,0,0,0,0,10,0,0,0,0,0,0,0,1,1]; [26, 0,7,19,0,0,11,7,0,0,0,0,0,19,6,0,4,0,0,0,21,0,8,11,0,18,17,0,0,0,0,0,2,0,0,0,0,0,0, 1]);
HE is ([0,0,0,0,21,0,0,24,0,1,0,0,0,0,0,0,0,4,0,0,2,1,0,0,0,0,0,0,0,0,0,0,0,0,0,0,0, 0,0,0,0,0,0,0]; [0,0,20,19,0,18,0,0,0,0,0,0,0,14,0,0,0,0,0,0,0,1,1,0,0,0,0,0,0,0,0,0, 0,0,0,0,0,0,0,0,0,0,0,0,0]; [0,0,0,0,23,14,20,0,0,0,0,0,0,0,0,0,0,0,13,0,0,0,1,1,0,0,0, 0,0,0,0,0,0,0,0,0,0,0,0,0,0 0,0,0]; [4,0,0,0,0,0,0,14,0,0,0,0,0,0,0,0,29,17,0,0,0,0, 0,1,1,0,0,0,0,0,0,0,0 0,0,0,0,0,0,0,0,0,0,0,0]; [0,0,4,11,0,0,0,0,2,0,0,0,0,12,0,0,0,0, 0,0,0,0,0,0,1,1,0,0,0,0,0,0,0,0,0,0,0,0,0,0,0,0,0,0]; [0,0,0,0,9,0,0,0,0,0,0,0,0,0,0,0, 11,0,11,14,0,0,0,0,0,0,1,1,0,0,0,0,0,0,0,0,0,0,0,0,0,0,0,0,0,]; [0,0,0,0,6,0, 28,0,9,0,0,25,0,0,0,0,0,0,0,0,0,0,0,0,0,0,0,1,1,0,0,0,0,0,0,0,0,0,0,0,0,0,0,0]; [0,0, 0,0,0,24,0,0,0,0,0,0,0,0,0,15,0,0,15,23,0,0,0,0,0,0,0,0,1,1,0,0,0,0,0,0,0,0,0,0,0, 0,0,0]; [0,3,0,0,0,0,16,29,0,0,0,0,0,0,0,0,0,0,0,0,1,0,0,0,0,0,0,0,0,1,1,0,0,0,0,0,0, 0,0,0,0,0,0,0]; [0,0,0,14,0,0,0,0,18,0,0,0,0,0,0,0,0,0,0,19,0,0,0,0,0,0,0,0,0,0,1,1, 0,0,0,0,0,0,0,0,0,0,0,0]; [0,0,0,0,0,0,0,0,0,2,0,0,2,2,21,0,0,0,0,0,0,0,0,0,0,0,0,0, 0,0,0,1,1,0,0,0,0,0,0,0,0,0,0,0,]; [0,7,0,0,0,0,0,0,0,0,0,1,23,0,0,0,22,0,0,0,0,0,0,0, 0,0,0,0,0,0,0,0,1,1,0,0,0,0,0,0,0,0,0,0]; [0,0,0,0,0,0,0,0,0,0,0,26,26,0,11,0,0,0,0, 4,0,0,0,0,0,0,0,0,0,0,0,0,1,1,0,0,0,0,0,0,0,0,0]; [8,0,11,0,0,0,0,0,0,0,0,0,0,0,0, 8,0,0,0,0,0,0,0,0,0,0,0,0,0,0,0,0,0,0,1,1,0,0,0,0,0,0,0,0]; [0,20,5,3,0,0,0,0,0,0,0, 0,0,0,0,0,0,0,0,18,0,0,0,0,0,0,0,0,0,0,0,0,0,0,0,1,1,0,0,0,0,0,0,0]; [15,0,0,0,0,0,0, 0,27,0,17,0,0,0,17,0,0,0,0,0,0,0,0,0,0,0,0,0,0,0,0,0,0,0,0,0,1,1,0,0,0,0,0,0]; [0,0, 0,0,0,4,0,0,0,18,25,0,0,0,0,0,0,0,22,0,0,0,0,0,0,0,0,0,0,0,0,0,0,0,0,0,0,1,1,0,0,0, 0,0]; [0,24,0,0,0,0,0,0,0,0,0,16,0,16,0,0,0,0,0,0,0,0,0,0,0,0,0,0,0,0,0,0,0,0,0,0, 0,1,1,0,0,0,0]; [0,0,0,0,0,0,0,7,0,0,20,0,0,0,0,26,0,5,0,0,2,0,0,0,0,0,0,0,0,0,0,0,0, 0,0,0,0,0,0,1,0,0,0,0]; [0,0,0,0,0,0,13,0,0,0,0,20,0,0,0,0,1,0,0,0,0,0,0,0,0,0,0,21, 0,0,0,0,0,0,0,0,0,0,0,0,2,1,0,0]; [0,0,0,0,0,0,0,0,0,0,12,0,0,0,0,0,0,0,0,0,10,0,0,0, 19,0,0,0,0,0,0,0,0,0,0,0,0,0,0,0,0,1,1,1,0]; [0,0,2,0,0,0,0,0,0,0,0,0,0,0,0,3,0,0,0, 0,5,0,0,0,0,10,0,0,0,0,0,0,0,0,0,0,0,0,0,0,0,0,1,1]; [19,0,0,0,0,0,0,0,16,0,0,0,26,0, 3,0,0,0,0,0,0,0,0,0,0,0,0,0,0,0,0,0,0,0,0,0,0,0,0,0,2,0,0,1]);
HF is ([0,0,0,0,13,0,0,0,0,18,11,0,14,0,9,0,0,0,20,0,0,0,0,22,0,2,1,0,0,0,0,0,0,0,0, 0,0,0,0,0,0,0,0,0]; [0,0,0,0,0,20,24,4,24,0,8,0,0,0,0,0,0,0,6,0,0,0,0,0,0,0,1,1,0,0, 0,0,0,0,0,0,0,0,0,0,0,0,0,0]; [0,0,0,0,0,0,0,0,0,0,0,0,0,23,0,0,0,1,11,29,17,27,0,0, 0,0,0,1,1,0,0,0,0,0,0,0,0,0,0,0,0,0,0,0]; [0,0,7,18,0,0,0,21,0,0,0,0,22,0,0,0,29,0,0,0, 1,0,26,0,0,0,0,0,0,1,1,0,0,0,0,0,0,0,0,0,0,0,0,0,0]; [0,0,19,1,0,0,0,0,0,0,0,0,0,0, 22,0,24,0,0,0,0,0,15,0,6,0,0,0,0,1,1,0,0,0,0,0,0,0,0,0,0,0,0]; [26,3,8,0,0,16,9,0, 0,0,0,0,0,0,28,0,0,0,0,0,0,0,0,0,0,0,0,0,0,0,1,1,0,0,0,0,0,0,0,0,0,0,0,0]; [4,0,0,0, 0,12,22,0,18,0,0,0,9,7,0,0,27,0,0,0,0,0,0,0,0,0,0,0,0,0,0,1,1,0,0,0,0,0,0,0,0,0,0, 0]; [0,12,0,0,1,0,0,0,0,0,0,0,21,0,0,17,0,0,0,0,4,0,0,4,0,1,0,0,0,0,0,0,1,1,0,0,0,0,0, 0,0,0,0,0,0]; [0,0,0,8,0,0,0,0,28,0,8,21,0,0,0,4,0,0,0,0,0,0,12,0,0,0,0,0,0,0,0,0,0, 1,1,0,0,0,0,0,0,0,0]; [0,0,0,0,0,0,0,0,37,26,0,0,0,23,0,0,0,0,0,0,0,9,3,28,0,0,0, 0,0,0,0,0,0,1,1,0,0,0,0,0,0,0,0]; [9,0,0,0,0,0,0,30,29,0,0,0,0,10,0,0,0,17,0,0,0,4,0, 0,0,0,0,0,0,0,0,0,0,0,1,1,0,0,0,0,0,0,0]; [0,0,0,0,8,0,0,0,0,0,0,0,8,0,0,0,12,0,0, 0,2,0,0,14,12,0,0,0,0,0,0,0,0,0,0,0,1,1,0,0,0,0,0,0]; [0,0,6,20,17,0,0,2,0,0,0,17,0, 0,0,26,0,0,0,0,0,0,0,0,0,0,0,0,0,0,0,0,0,0,0,0,0,1,1,0,0,0,0,0]; [0,6,0,0,0,30,30,0, 0,0,0,0,0,0,0,0,24,0,0,0,24,0,16,0,0,0,0,0,0,0,0,0,0,0,0,0,0,0,1,1,0,0,0,0]; [0,0,0, 0,0,0,0,0,0,6,0,30,0,5,0,0,0,27,0,21,0,1,0,0,0,2,0,0,0,0,0,0,0,0,0,0,0,0,0,1,0,0,0, 0]; [0,0,0,0,0,0,0,0,0,0,0,0,0,0,0,0,0,8,0,0,0,0,0,0,9,0,0,0,0,0,26,0,2,25,14,0,0,6, 0,0,2,1,0,0]; [0,0,0,0,0,0,0,0,0,0,0,0,0,0,0,0,20,0,0,0,0,0,0,0,0,9,15,0,0,29,13,0,0, 29,0,0,0,0,0,0,1,1,1,0]; [18,0,0,22,0,17,0,0,0,0,0,0,0,0,0,0,3,0,0,0,0,0,0,0,22, 0,2,10,0,0,0,0,0,0,0,0,0,0,0,0,1,1]; [0,0,0,0,0,0,0,0,0,8,0,29,0,0,0,0,0,0,17,4,0,0, 0,0,0,0,0,0,0,0,0,0,0,0,0,0,0,0,19,17,2,0,0,1]);
HG is ([2,0,0,0,0,0,0,0,0,0,29,6,0,0,0,0,0,28,3,28,8,0,0,0,12,20,0,0,0,20,2,1,0,0,0, 0,0,0,0,0,0,0,0,0]; [7,0,0,0,7,9,0,16,0,5,0,0,24,0,0,0,0,17,0,0,0,27,0,0,0,0,0,0,8,3, 0,1,1,0,0,0,0,0,0,0,0,0,0,0]; [0,22,0,23,11,22,0,0,25,12,0,0,0,0,0,0,21,0,0,0,0,0,0, 0,0,0,16,2,22,0,0,0,1,1,0,0,0,0,0,0,0,0,0,0]; [0,25,7,0,0,0,1,0,14,0,0,0,0,0,27,16, 23,0,27,0,0,0,0,27,0,30,0,0,0,0,0,0,0,1,1,0,0,0,0 0,0,0,0,0]; [0,19,0,3,0,12,0,0,30, 0,0,0,0,0,0,28,0,0,28,0,0,0,28,0,0,22,0,0,0,29,1,0,0,0,1,1,0,0,0,0,0,0,0,0]; [0,0,9, 0,0,0,0,4,0,0,0,0,22,21,4,9,29,0,0,0,0,0,7,14,0,0,0,15,0,0,0,0,0,0,0,1,1,0,0,0,0,0, 0,0]; [24,0,0,0,0,0,0,0,0,0,12,25,28,29,30,0,0,0,0,18,20,13,0,11,0,0,0,0,0,0,0,0,0, 0,0,0,1,1,0,0,0,0,0,0]; [0,29,0,0,0,4,6,0,25,6,0,0,0,0,0,0,0,0,0,11,0,29,0,0,5,0,12, 0,7,0,0,0,0,0,0,0,0,1,1,0,0,0,0,0]; [0,0,28,0,0,0,28,0,0,0,10,0,0,28,0,0,10,0,0,14, 2,0,0,0,22,0,14,8,0,0,0,0,0,0,0,0,0,0,1,1,0,0,0,0]; [0,0,0,7,19,0,0,22,0,0,6,4,0,0,0, 0,0,7,0,0,5,0,20,0,0,0,0,5,0,8,2,0,0,0,0,0,0,0,0,1,0,0,0,0]; [0,0,0,9,0,0,0,0,0,0,0, 27,0,0,12,0,0,0,0,0,0,0,21,0,0,0,0,0,0,0,0,0,0,14,0,0,17,22,0,0,2,1,0,0]; [27,0,0,0, 0,0,0,0,0,0,0,0,15,21,0,0,0,0,18,0,0,0,0,0,0,24,0,0,0,0,0,18,12,0,0,11,0,0,0,0,1,1, 1,0]; [0,0,0,0,0,0,20,0,0,0,0,0,0,0,0,0,0,0,0,0,0,0,0,0,0,0,0,0,0,0,0,0,4,26,30,0,0, 0,0,17,0,0,1,1]; [0,0,0,0,8,0,0,0,0,1,0,0,0,0,0,0,0,11,0,0,0,0,0,0,12,0,0,0,13,0,0,0, 0,0,0,0,0,0,12,0,2,0,0,1]);
HH is ([0,0,23,0,0,0,0,12,25,12,24,0,0,0,0,23,0,0,0,3,13,0,13,0,28,0,15,11,0,0, 29,2,1,0,0,0,0,0,0,0,0,0,0]; [0,0,21,0,0,14,0,25,0,0,0,14,0,0,14,14,27,0,0,1,0,19,7, 0,28,0,0,0,0,8,8,0,0,1,1,0,0,0,0,0,0,0,0,0]; [19,0,16,0,0,5,0,18,0,0,0,0,6,2,0,17,0, 0,14,20,0,0,25,0,13,0,4,0,0,6,0,0,0,0,1,1,0,0,0,0,0,0,0,0]; [24,1,0,20,29,0,30,0,14, 0,28,0,0,0,0,0,0,2,20,0,0,0,0,17,0,0,0,0,22,0,0,6,1,0,0,1,1,0,0,0,0,0,0,0]; [15,11, 11,0,23,27,14,0,0,0,0,0,0,9,15,0,0,30,0,0,0,0,13,0,2,0,27,0,0,0,7,0,0,0,0,0,1,1,0, 0,0,0,0,0]; [0,0,10,0,0,0,0,20,0,14,0,22,9,14,0,28,0,0,0,17,0,0,0,0,19,19,8,2,0,15, 0,0,0,0,0,0,0,1,1,0,0,0,0,0]; [0,0,0,0,0,0,0,0,23,18,2,0,23,0,0,0,0,0,13,0,13,0,0,0, 0,13,0,3,2,0,0,3,0,0,0,0,0,0,1,1,0,0,0,0]; [0,19,0,9,6,0,20,0,0,0,19,0,0,0,27,0,24, 17,0,0,12,9,0,12,0,0,0,0,6,0,10,0,2,0,0,0,0,0,0,1,0,0,0,0]; [0,0,0,11,14,0,0,0,0,0, 0,0,0,29,0,0,0,0,0,0,0,0,0,4,0,0,13,0,0,0,0,0,2,0,0,1,28,25,0,0,2,1,0,0]; [0,0,0,0, 0,25,0,0,0,0,0,0,0,0,0,0,2,0,0,0,0,0,23,0,0,0,0,0,0,0,0,0,0,19,23,0,0,0,0,2,1,1,1, 0]; [0,0,0,0,0,0,0,0,28,0,0,0,0,0,0,0,0,0,0,0,0,0,0,0,0,0,0,0,0,0,0,0,0,1,0,0,3,8,5, 0,0,0,1,1]; [0,0,0,0,0,0,0,1,0,0,0,0,0,0,0,6,0,0,19,16,0,0,0,0,0,0,0,0,0,6,0,0,0,0, 18,7,0,0,17,9,2,0,0,1]); and
HI is ([0,0,0,0,24,0,25,0,0,0,0,0,0,0,12,0,0,0,0,0,0,0,0,0,0,0,0,0,0,30,0,0,0,0,0,0, 0,0,0,0,2,1,0,0]; [0,0,0,0,0,0,0,0,0,0,0,0,0,19,0,0,0,0,5,0,0,18,0,0,0,0,0,0,0,0,0,0, 0,0,0,0,0,0,0,0,1,1,1,0]; [0,0,6,0,0,0,0,0,0,0,0,0,16,0,0,0,0,3,0,0,0,0,0,0,0,0,0,7, 0,0,0,0,0,0,0,0,0,0,0,0,0,0,]; [18,0,0,0,0,0,0,0,0,0,13,0,0,0,0,0,0,0,0,0,0,11,0,0, 0,0,4,0,0,0,0,0,0,0,0,0,0,0,0,0,0,2,0,0,1]).

7. The transmitter according to claim 1, wherein the communication module may be adapted to transmit the codeword using modified dual-carrier modulation (MDCM)

8. The transmitter according to claim 1, wherein the encoder may be adapted to encode the data bit vector to provide the codeword x by solving the linear equations system: H′x^{T}=0, for a matrix H′ that includes elements P_{i,j}, wherein each of the elements P_{i,j} contains: (a) the value “0” if P_{i,j} represents a 30×30 zero matrix; or (b) a value equal to 1+s if P_{i,j}=I^{s}, wherein I^{s} is one of a set of 30×30 permutation matrices; wherein each permutation matrix is a cyclically right shifted identity matrix, denoted as I^{s} for a shift s, where s is an integer between 0 and 29, wherein the matrix H′ is representable as an ordered set of vectors HE wherein the first bits of the codewords are the bits of the data bit vector; wherein:
HE is ([0,0,0,0,21,0,0,24,0,1,0,0,0,0,0,0,0,4,0,0,2,1,0,0,0,0,0 0,0,0,0,0,0,0,0,0,0, 0,0,0,0,0,0,0]; [0,0,20,19,0,18,0,0,0,0,0,0,0,14,0,0,0,0,0,0,0,1,1,0,0,0,0,0,0,0,0,0, 0,0,0,0,0,0,0,0,0,0,0,0]; [0,0,0,0,23,14,20,0,0,0,0,0,0,0,0,0,0,0,13,0,0,0,1,1,0,0,0, 0,0,0,0,0,0,0,0,0,0,0,0,0,0,0,0,0]; [4,0,0,0,0,0,0,14,0,0,0,0,0,0,0,0,29,17,0,0,0,0, 0,1,1,0,0,0,0,0,0,0,0,0,0,0,0,0,0,0,0,0,0][0,0,4,11,0,0,0,0,2,0,0,0,0,12,0,0,0,0, 0,0,0,0,0,0,1,1,0,0,0,0,0,0,0,0,0,0,0,0,0,0,0,0,0,0]; [0,0,0,0,9,0,0,0,0,0,0,0,0,0,0, 11,0,11,14,0,0,0,0,0,1,1,0,0,0,0,0,0,0,0,0,0,0,0,0,0,0,0,0]; [0,0,0,0,0,0,0,0,0,13, 0,14,0,7,0,0,20,0,0,0,0,0,0,0,0,0,1,1,0,0,0,0,0,0,0,0,0,0,0,0,0,0,0]; [0,0,0,0,6,0, 28,0,9,0,0,25,0,0,0,0,0,0,0,0,0,0,0,0,0,0,0,1,1,0,0,0,0,0,0,0,0,0,0,0,0,0,0,0]; [0,0, 0,0,0,24,0,0,0,0,0,0,0,0,0,15,0,0,15,23,0,0,0,0,0,0,0,0,1,1,0,0,0,0,0,0,0,0,0,0,0, 0,0,0]; [0,3,0,0,0,0,16,29,0,0,0,0,0,0,0,0,0,0,0,0,1,0,0,0,0,0,0,0,0,1,1,0,0,0,0,0,0, 0,0,0,0,0,0,0]; [0,0,0,14,0,0,0,0,18,0,0,0,0,0,0,0,0,0,0,19,0,0,0,0,0,0,0,0,0,0,1,1, 0,0,0,0,0,0,0,0,0,0,0,0]; [0,0,0,0,0,0,0,0,0,2,0,0,2,2,21,0,0,0,0,0,0,0,0,0,0,0,0, 0,0,0,1,1,0,0,0,0,0,0,0,0,0,0,0]; [0,7,0,0,0,0,0,0,0,0,0,1,23,0,0,0,22,0,0,0,0,0,0,0, 0,0,0,0,0,0,0,0,1,1,0,0,0,0,0,0,0,0,0,0]; [0,0,0,0,0,0,0,0,0,0,0,26,26,0,11,0,0,0,0, 4,0,0,0,0,0,0,0,0,0,0,0,0,0,1,1,0,0,0,0,0,0,0,0,0]; [8,0,11,0,0,0,0,0,0,0,0,0,0,0,0, 8,0,0,0,0,0,0,0,0,0,0,0,0,0,0,0,0,0,1,1,0,0,0,0,0,0,0,0]; [0,20,5,3,0,0,0,0,0,0,0, 0,0,0,0,0,0,0,0,18,0,0,0,0,0,0,0,0,0,0,0,0,0,0,0,1,1,0,0,0,0,0,0,0]; [15,0,0,0,0,0,0, 0,27,0,17,0,0,0,17,0,0,0,0,0,0,0,0,0,0,0,0,0,0,0,0,0,0,0,0,0,1,1,0,0,0,0,0,0]; [0,0, 0,0,0,4,0,0,0,18,25,0,0,0,0,0,0,0,22,0,0,0,0,0,0,0,0,0,0,0,0,0,0,0,0,0,0,1,1,0,0,0, 0,0]; [0,24,0,0,0,0,0,0,0,0,0,0,16,0,16,0,0,0,0,0,0,0,0,0,0,0,0,0,0,0,0,0,0,0,0,0,0, 0,1,1,0,0,0,0]; [0,0,0,0,0,0,0,7,0,0,20,0,0,0,0,26,0,5,0,0,2,0,0,0,0,0,0,0,0,0,0,0,0, 0,0,0,0,0,0,1,0,0,0,0]; [0,0,0,0,0,0,13,0,0,0,0,0,20,0,0,0,0,1,0,0,0,0,0,0,0,0,0,21, 0,0,0,0,0,0,0,0,0,0,0,0,2,1,0,0]; [0,0,0,0,0,0,0,0,0,12,0,0,0,0,0,0,0,0,0,10,0,0,0, 19,0,0,0,0,0,0,0,0,0,0,0,0,0,0,0,0,1,1,1,0]; [0,0,2,0,0,0,0,0,0,0,0,0,0,0,0,3,0,0,0, 0,5,0,0,0,0,10,0,0,0,0,0,0,0,0,0,0,0,0,0,0,0,0,1,1]; [19,0,0,0,0,0,0,0,16,0,0,0,26,0, 3,0,0,0,0,0,0,0,0,0,0,0,0,0,0,0,0,0,0,0,0,0,0,0,0,2,0,0,1]).

9. The transmitter according to claim 1, wherein the encoder may be adapted to encode the data bit vector to provide the codeword x by solving the linear equations system: H′x^{T}=0, for a matrix H′ that includes elements P_{i,j} wherein each of the elements P_{i,j} contains: (a) the value “0” if P_{i,j} represents a 30×30 zero matrix; or (b) a value equal to 1+s if P_{i,j}=I^{s}, wherein I^{s} is one of a set of 30×30 permutation matrices; wherein each permutation matrix is a cyclically right shifted identity matrix, denoted as I^{s} for a shift s, where s is an integer between 0 and 29, wherein the matrix H′ is representable as an ordered set of vectors HF wherein the first bits of the codewords are the bits of the data bit vector; wherein:
HF is ([0,0,0,0,13,0,0,0,0,18,11,0,14,0,9,0,0,0,20,0,0,0,0,22,0,2,1,0,0,0,0,0,0,0,0, 0,0,0,0,0,0,0,0,0]; [0,0,0,0,0,20,24,4,24,0,8,0,0,0,0,0,0,0,6,0,0,0,0,0,0,0,1,1,0,0, 0,0,0,0,0,0,0,0,0,0,0,0,0,0]; [0,0,0,0,0,0,0,0,0,0,0,0,0,23,0,0,0,1,11,29,17,27,0,0, 0,0,0,1,1,0,0,0,0,0,0,0,0,0,0,0,0,0,0,0]; [0,0,7,18,0,0,0,21,0,0,0,22,0,0,0,29,0,0,0, 1,0,26,0,0,0,0,0,0,1,1,0,0,0,0,0,0,0,0,0,0,0,0,0,0]; [0,0,19,1,0,0,0,0,0,0,0,0,0,0, 22,0,24,0,0,0,0,0,15,0,6,0,0,0,0,1,1,0,0,0,0,0,0,0,0,0,0,0,0,0]; [26,3,8,0,0,16,9,0, 0,0,0,0,0,0,28,0,0,0,0,0,0,0,0,0,0,0,0,0,0,0,1,1,0,0,0,0,0,0,0,0,0,0,0,0]; [4,0,0,0, 0,12,22,0,18,0,0,0,9,7,0,0,27,0,0,0,0,0,0,0,0,0,0,0,0,0,0,1,1,0,0,0,0,0,0,0,0,0,0, 0]; [0,12,0,0,1,0,0,0,0,0,0,0,21,0,0,17,0,0,0,0,4,0,0,4,0,1,0,0,0,0,0,0,1,1,0,0,0,0, 0,0,0,0,0,0]; [0,0,0,8,0,0,0,0,28,0,8,21,0,0,0,4,0,0,0,0,0,0,12,0,0,0,0,0,0,0,0,0,0, 1,1,0,0,0,0,0,0,0,0,0]; [0,0,0,0,0,0,0,0,0,7,26,0,0,0,23,0,0,0,0,0,0,0,9,3,28,0,0,0, 0,0,0,0,0,0,1,1,0,0,0,0,0,0,0,0]; [9,0,0,0,0,0,0,30,29,0,0,0,0,10,0,0,0,17,0,0,0,4,0, 0,0,0,0,0,0,0,0,0,0,0,0,1,1,0,0,0,0,0,0,0]; [0,0,0,0,8,0,0,0,0,0,0,0,8,0,0,0,12,0,0, 0,2,0,0,14,12,0,0,0,0,0,0,0,0,0,0,0,1,1,0,0,0,0,0,0]; [0,0,6,20,17,0,0,2,0,0,0,17,0, 0,0,26,0,0,0,0,0,0,0,0,0,0,0,0,0,0,0,0,0,0,0,0,0,1,1,0,0,0,0,0]; [0,6,0,0,0,30,30,0, 0,0,0,0,0,0,0,0,24,0,0,0,0,24,0,16,0,0,0,0,0,0,0,0,0,0,0,0,0,0,0,1,1,0,0,0,0]; [0,0,0, 0,0,0,0,0,0,6,0,30,0,5,0,0,0,27,0,21,0,1,0,0,0,2,0,0,0,0,0,0,0,0,0,0,0,0,0,1,0,0,0, 0]; [0,0,0,0,0,0,0,0,0,0,0,0,0,0,0,0,0,8,0,0,0,0,0,0,9,0,0,0,0,0,26,0,2,25,14,0,0,6, 0,0,2,1,0,0]; [0,0,0,0,0,0,0,0,0,0,0,0,0,0,0,0,20,0,0,0,0,0,0,0,0,9,15,0,0,29,13,0,0, 29,0,0,0,0,0,0,1,1,1,0]; [18,0,0,0,0,22,0,17,0,0,0,0,0,0,0,0,0,0,0,0,0,0,0,0,0,22, 0,2,10,0,0,0,0,0,0,0,0,0,0,0,0,1,1]; [0,0,0,0,0,0,0,0,0,8,0,29,0,0,0,0,0,0,17,4,0,0, 0,0,0,0,0,0,0,0,0,0,0,0,0,0,0,0,19,17,2,0,0,1]).

10. The transmitter according to claim 1, wherein the encoder may be adapted to encode the data bit vector to provide the codeword x by solving the linear equations system: H′x^{T}=0, for a matrix H′ that includes elements P_{i,j} wherein each of the elements P_{i,j} contains: (a) the value “0” if P_{i,j} represents a 30×30 zero matrix; or (b) a value equal to 1+s if P_{i,j}=I^{s}, wherein I^{s} is one of a set of 30×30 permutation matrices; wherein each permutation matrix is a cyclically right shifted identity matrix, denoted as I^{s} for a shift s, where s is an integer between 0 and 29, wherein the matrix H′ is representable as an ordered set of vectors HG wherein the first bits of the codewords are the bits of the data bit vector; wherein:
HG is ([2,0,0,0,0,0,0,0,0,0,29,6,0,0,0,0,0,28,3,28,8,0,0,0,12,20,0,0,0,20,2,1,0,0,0, 0,0,0,0,0,0,0,0,0]; [7,0,0,0,7,9,0,16,0,5,0,0,24,0,0,0,0,17,0,0,0,2 0,0,0,0,0,0,8,3, 0,1,1,0,0,0,0,0,0,0,0,0,0,0]; [0,22,0,23,11,22,0,0,25,12,0,0,0,0,0,0,21,0,0,0,0,0,0, 0,0,0,16,2,22,0,0,0,1,1,0,0,0,0,0,0,0,0,0]; [0,25,7,0,0,0,1,0,14,0,0,0,0,0,27,16, 23,0,27,0,0,0,0,27,0,30,0,0,0,0,0,0,0,1,1,0,0,0,0,0,0,0,0,0]; [0,19,0,3,0,12,0,0,30, 0,0,0,0,0,0,28,0,0,28,0,0,0,28,0,0,22,0,0,0,29,1,0,0,0,1,1,0,0,0,0,0,0,0,0]; [0,0,9, 0,0,0,0,4,0,0,0,0,22,21,4,9,29,0,0,0,0,0,7,14,0,0,0,15,0,0,0,0,0,0,0,1,1,0,0,00,0, 0,0]; [24,0,0,0,0,0,0,0,0,0,12,25,28,29,30,0,0,0,0,18,20,13,0,11,0,0,0,0,0,0,0,0,0, 0,0,0,1,1,0,0,0,0,0,0]; [0,29,0,0,0,4,6,0,25,6,0,0,0,0,0,0,0,0,0,11,0,29,0,0,5,0,12, 0,7,0,0,0,0,0,0,0,0,1,1,0,0,0,0,0]; [0,0,28,0,0,0,28,0,0,0,10,0,0,28,0,0,10,0,0,14, 2,0,0,0,22,0,14,8,0,0,0,0,0,0,0,0,0,0,1,1,0,0,0,0]; [0,0,0,7,19,0,0,22,0,0,6,4,0,0,0, 0,0,7,0,0,5,0,20,0,0,0,0,5,0,20,0,0,0,05,0,8,2,0,0,0,0,0,0,0,0,1,0,0,0,0]; [0,0,0,9,0,0,0,0,0,0,0, 27,0,0,12,0,0,0,0,0,0,0,21,0,0,0,0,0,0,0,0,0,0,14,0,0,17,22,0,0,2,1,0,0]; [27,0,0,0, 0,0,0,0,0,0,0,0,15,21,0,0,0,18,0,0,0,0,0,0,24,0,0,0,0,0,18,12,0,0,11,0,0,0,0,1,1, 1,0]; [0,0,0,0,0,0,20,0,0,0,0,0,0,0,0,0,0,0,0,0,0,0,0,0,0,0,0,0,0,0,0,4,26,30,0,0, 0,0,17,0,0,1,1]; [0,0,0,0,8,0,0,0,0,1,0,0,0,0,0,0,0,11,0,0,0,0,0,0,12,0,0,0,13,0,0,0, 0,0,0,0,0,0,12,0,2,0,0,1]).

11. The transmitter according to claim 1, wherein the encoder may be adapted to encode the data bit vector to provide the codeword x by solving the linear equations system: H′x^{T}=0, for a matrix H′ that includes elements P_{i,j}, wherein each of the elements P_{i,j} contains: (a) the value “0” if P_{i,j} represents a 30×30 zero matrix; or (b) a value equal to 1+s if P_{i,j}=I^{s}, wherein I^{s} is one of a set of 30×30 permutation matrices; wherein each permutation matrix is a cyclically right shifted identity matrix, denoted as I^{s} for a shift s, where s is an integer between 0 and 29, wherein the matrix H′ is representable as an ordered set of vectors HH wherein the first bits of the codewords are the bits of the data bit vector; wherein:
HH is ([0,0,0,23,0,0,0,0,12,25,12,24,0,0,0 0,23,0,0,0,3,13,0,13,0,28,0,15,11,0,0, 29,2,1,0,0,0,0,0,0,0,0,0,0]; [0,0,21,0,0,14,0,25,0,0,0,14,0,0,14,14,27,0,0,1,0,19,7, 0,28,0,0,0,0,8,8,0,0,1,1,0,0,0,0,0,0,0,0,0]; [19,0,16,0,0,5,0,0,5,0,18,0,0,0,0,6,2,0,17,0, 0,14,20,0,0,25,0,13,0,4,0,0,6,0,0,0,0,1,0,0,0,0,0,0,0,0]; [24,1,0,20,29,0,30,0,14, 0,28,0,0,0,0,0,0,2,20,0,0,0,0,17,0,0,0,0,22,0,0,6,1,0,0,1,1,0,0,0,0,0,0,0]; [15,11, 11,0,23,27,14,0,0,0,0,0,0,9,15,0,0,30,0,0,0,0,3,0,2,0,27,0,0,0,7,0,0,0,0,0,1,1,0, 0,0,0,0,0]; [0,0,10,0,0,0,0,20,0,14,0,22,9,14,0,28,0,0,0,17,0,0,0,0,19,19,8,2,0,15, 0,0,0,0,0,1,1,0,0,0,0,0]; [0,0,0,0,0,0,0,0,23,18,2,0,23,0,0,0,0,0,13,0,13,0,0,0, 0,13,0,3,2,0,0,3,0,0,0,0,0,0,1,1,0,0,0,0]; [0,19,0,9,6,0,20,0,0,0,19,0,0,0,27,0,24, 17,0,0,12,9,0,12,0,0,0,0,6,0,10,0,2,0,0,0,0,0,0,1,0,0,0,0]; [0,0,0,1,14,0,0,0,0,0, 0,0,0,29,0,0,0,0,0,0,0,0,0,4,0,0,13,0,0,0,0,0,2,0,0,11,28,25,0,0,2,1,0,0]; [0,0,0,0, 0,25,0,0,0,0,0,0,0,0,0,0,2,0,0,0,0,0,23,0,0,0,0,0,0,0,0,0,0,19,23,0,0,0,0,2,1,1,1, 0]; [0,0,0,0,0,0,0,0,28,0,0,0,0,0,0,0,0,0,0,0,0,0,0,0,0,0,0,0,0,0,0,0,0,1,0,0,3,8,5, 0,0,0,1,1]; [0,0,0,0,0,0,0,1,0,0,0,0,0,0,0,6,0,0,19,16,0,0,0,0,0 0,0,0,0,6,0,0,0,0, 18,7,0,0,17,9,2,0,0,1]).

12. A method for transmitting information, the method comprising:
encoding a data bit vector to provide a codeword that comprises a first codeword portion and a second codeword portion; wherein the first codeword portion is decodable by a first parity check process to yield the data bit vector; wherein the codeword is decodable by a second parity check process to yield the data bit vector; and
transmitting the codeword.

13. The method according to claim 12, comprising transmitting the first and the second codeword portions in different communication channels.

14. The method according to claim 12, comprising transmitting the first codeword portion in a first communication channel, and transmitting the second codeword portion in at least one sub-channel of the first communication channel in which the first codeword portion is not transmitted.

15. The method according to claim 12, comprising encoding the data bit vector to provide the codeword that is decodable by a second first low-density parity check (LDPC) process to yield the data bit vector, wherein the first codeword portion is decodable using a first LDPC process to yield the data bit vector.

16. The method according to claim 12, comprising transmitting the codeword using quadrature amplitude modulation (QAM) modulation of an order of at least 16, wherein the encoding of the data bit vector to provide the codeword comprises providing the codeword in which information of a first bit is more useful for at least one of the first and the second parity-check processes than information of a second bit, wherein the transmitting comprises transmitting the first bit in a first symbol and the second bit in a second symbol, wherein the first symbol is less susceptible to errors during the transmitting than the second symbol.

17. The method according to claim 12, wherein the encoding comprises solving a linear equations system: H′x^{T}=0, for a matrix H′ that includes elements P_{i,j}, wherein each of the elements P_{i,j} contains: (a) the value “0” if P_{i,j} represents a 30×30 zero matrix; or (b) a value equal to 1+s if P_{i,j}=I^{s}, wherein I^{s} is one of a set of 30×30 permutation matrices; wherein each permutation matrix is a cyclically right shifted identity matrix, denoted as I^{s} for a shift s, where s is an integer between 0 and 29, wherein the matrix H′ is representable as an ordered set of vectors selected from a group of ordered sets of vectors that consists the order sets of vectors HA, HB, HC, HD, HE, HF, HG, HH, and HI, wherein the first bits of the codewords are the bits of the data bit vector; wherein:
HA is ([0,0,25,0,0,0,30,0,0,0,0,0,0,0,7,26,0,0,0,0,2,1,0,0,0,0,0,0,0,0,0,0,0,0,0,0, 0,0,0,0]; [0,0,0,11,0,0,0,0,0,30,12,0,9,0,0,0,0,0,0,0,0,1,1,0,0,0,0,0,0,0,0,0,0,0,0, 0,0,0,0,0]; [30,0,0,0,0,0,28,8,0,0,0,0,0,0,0,29,0,0,0,0,0,0,1,1,0,0,0,0,0,0,0,0,0,0, 0,0,0,0,0,0]; [0,0,0,0,0,29,0,0,12,0,0,4,0,0,0,0,0,0,17,0,0,0,0,1,1,0,0,0,0,0,0,0,0, 0,0,0,0,0,0,0]; [0,21,0,0,0,0,0,0,0,0,29,0,0,0,0,0,0,23,0,28,0,0,0,0,1,1,0,0,0,0,0,0, 0,0,0,0,0,0,0,0]; [24,0,0,0,0,0,23,0,0,0,0,0,0,0,26,7,0,0,0,0,0,0,0,0,0,1,1,0,0,0,0, 0,0,0,0,0,0,0,0,0]; [0,0,30,0,0,10,0,0,0,0,0,0,0,1,0,0,0,0,0,0,0,0,1,1,0,0,0, 0,0,0,0,0,0,0,0,0]; [0,0,0,3,9,0,0,0,0,6,0,0,27,0,0,0,0,0,0,0,0,0,0,0,0,0,1,1,0,0, 0,0,0,0,0,0,0,0,0]; [0,0,0,15,23,0,0,0,0,13,0,0,23,0,0,0,0,0,0,0,0,0,0,0,0,0,0,0,1,1, 0,0,0,0,0,0,0,0,0,0][0,0,0,0,0,0,0,0,0,0,13,0,0,0,0,17,0,0,3,1,0,0,0,0,0,0,0,0,1, 1,0,0,0,0,0,0,0,0,0]; [0,0,23,0,0,0,0,19,19,0,0,18,0,0,0,0,0,0,0,0,0,0,0,0,0,0,0,0, 0,1,1,0,0,0,0,0,0,0,0]; [10,0,0,0,0,0,25,29,0,0,0,0,0,0,0,2,0,0,0,0,0,0,0,0,0,0,0,0, 0,0,0,1,1,0,0,0,0,0,0,0]; [13,0,0,0,0,07,21,0,0,0,0,0,0,0,0,10,0,0,0,0,0,0,0,0,0,0,0, 0,0,0,0,0,1,1,0,0,0,0,0,0]; [0,0,15,29,0,0,0,0,17,0,0,13,0,0,0,0,0,0,0,0,0,0,0,0,0, 0,0,0,0,0,0,0,1,1,0,0,0,0,0]; [3,0,0,0,0,0,0,0,0,0,0,17,0,0,0,0,24,0,22,0,0,0,0,0,0, 0,0,0,0,0,0,0,0,1,1,0,0,0,0]; [0,13,0,0,0,0,0,0,0,0,22,0,0,0,2,0,22,0,0,0,0,0,0, 0,0,0,0,0,0,0,0,0,0,0,1,1,0,0,0]; [0,0,0,0,0,0,0,0,1,0,0,0,0,18,0,0,0,19,11,0,0,0,0, 0,0,0,0,0,0,0,0,0,0,0,0,0,1,1,0,0]; [15,5,0,0,0,0,6,0,0,0,0,0,0,0,0,19,0,0,0,0,0,0,0, 0,0,0,0,0,0,0,0,0,0,0,0,0,0,1,0]; [0,0,0,0,11,0,0,12,0,0,0,0,0,25,0,0,0,0,6,0,0, 0,0,0,0,0,0,0,0,0,0,0,0,0,0,0,0,1,1]; [0,0,0,7,0,0,0,0,0,16,0,0,4,0,0,0,0,0,15,0,2,0, 0,0,0,0,0,0,0,0,0,0,0,0,0,0,0,0,1]);
HB is ([7,0,0,0,10,5,15,0,1,0,0,0,15,0,0,0,0,27,0,0,0,0,0,0,0,2,1,0,0,0,0,0,0,0,0,0, 0,0,0,0]; [27,0,0,29,1,0,0,0,3,13,0,6,0,0,0,0,0,0,0,0,12,0,0,0,0,0,1,1,0,0,0,0,0,0,0, 0,0,0,0,0]; [0,3,0,0,0,0,0,0,0,0,0,0,21,0,11,0,2,10,0,24,0,0,3,0,0,0,0,1,1,0,0,0,0,0, 0,0,0,0,0,0]; [4,0,0,0,0,12,0,0,0,0,22,0,13,0,0,0,6,0,0,0,0,0,22,0,18,0,0,0,1,1,0,0, 0,0,0,0,0,0,0,0]; [0,0,11,0,13,0,0,17,0,0,0,0,0,0,0,16,0,16,0,4,21,0,0,0,0,0,0,0,0, 1,1,0,0,0,0,0,0,0,0,0]; [18,0,28,0,0,0,0,0,16,0,25,0,23,0,0,0,0,0,0,26,0,0,0,22,0,0, 0,0,0,0,1,1,0,0,0,0,0,0,0,0]; [23,0,0,0,0,0,0,0,26,0,0,0,25,24,0,0,18,19,24,0,0,0,0, 0,0,0,0,0,0,0,0,1,1,0,0,0,0,0,0,0]; [0,0,0,19,0,0,30,0,0,0,0,24,0,0,0,0,0,0,0,0,26,0, 10,0,11,1,0,0,0,0,0,0,1,1,0,0,0,0,0,0]; [0,0,0,0,11,0,0,0,20,0,0,0,0,0,6,17,0,2,0,0, 0,0,24,3,0,0,0,0,0,0,0,0,0,1,1,0,0,0,0,0]; [15,27,0,0,16,0,0,0,0,11,0,0,0,0,0,26,0, 0,0,0,0,15,0,26,0,0,0,0,0,0,0,0,0,0,1,1,0,0,0,0]; [9,0,17,0,23,0,0,24,0,0,0,0,0,0,0, 0,0,30,0,0,0,18,0,0,5,0,0,0,0,0,0,0,0,0,0,1,1,0,0,0]; [11,0,0,0,0,0,26,0,11,6,0,0,0, 0,20,0,0,8,0,0,0,0,19,0,0,0,0,0,0,0,0,0,0,0,0,0,0,1,1,0,0]; [0,0,0,7,0,0,0,0,24,0,0,11, 30,0,0,0,0,22,10,0,0,7,0,0,0,0,0,0,0,0,0,0,0,0,0,0,1,1,0]; [0,25,0,0,26,0,0,14,0, 0,0,0,9,7,0,0,0,0,17,0,0,0,7,0,0,0,0,0,0,0,0,0,0,0,0,0,0,0,1,1]; [0,0,0,0,7,15,0,0,6, 0,24,0,2,28,0,0,0,0,0,0,0,0,29,0,0,2,0,0,0,0,0,0,0,0,0,0,0,0,0,1]);
HC is ([0,2,29,0,0,0,13,0,0,5,0,0,0,16,0,25,4,0,18,28,0,0,0,0,0,2,0,0,0,0,2,1,0,0,0, 0,0,0,0,0]; [10,0,26,0,0,0,0,17,0,0,0,26,6,0,24,0,0,27,0,0,0,0,24,0,0,0,27,0,0,15,0, 1,1,0,0,0,0,0,0,0]; [6,0,0,0,0,3,0,0,21,0,0,4,26,0,8,0,0,0,0,0,11,19,0,0,14,0,0,0,0, 6,0,0,1,1,0,0,0,0,0,0]; [0,0,0,12,0,16,20,0,0,0,30,0,0,0,0,0,8,0,4,30,0,8,0,0,12,26, 0,0,0,0,0,0,0,1,1,0,0,0,0,0]; [0,0,5,0,0,0,14,28,0,0,0,0,0,28,0,0,0,17,1,0,0,0,4,0,0, 24,0,0,1,0,1,0,0,0,1,1,0,0,0,0]; [27,27,0,0,6,0,0,0,28,21,0,0,14,0,0,18,0,0,0,0,0,0, 0,18,0,0,0,19,24,0,0,0,0,0,0,1,1,0,0,0]; [20,0,0,20,0,0,0,0,0,0,3,0,8,0,0,8,0,0,0, 29,0,4,0,0,4,0,16,0,0,12,0,0,0,0,0,0,1,1,0,0]; [25,0,0,0,23,0,0,0,14,0,21,0,22,0,0, 0,0,14,0,0,0,0,28,27,25,0,0,11,0,0,0,0,0,0,0,0,0,1,1,0]; [0,26,0,0,12,0,17,0,0,23,0, 0,0,12,0,0,0,0,11,0,1,0,0,25,0,0,0,14,6,0,0,0,0,0,0,0,0,0,1,1]; [0,0,0,16,0,1,26,9, 0,0,0,1,0,0,3,0,18,0,21,0,24,0,0,0,0,0,13,0,0,0,2,0,0,0,0,0,0,0,0,1]);
HD is ([8,27,0,0,0,2,0,0,11,12,19,19,22,0,0,10,13,11,13,22,0,0,0,0,0,0,0,0,0,0,0,0, 2,1,0,0,0,0,0,0]; [18,0,0,4,0,9,0,0,0,9,0,0,0,22,0,16,0,0,0,15,13,0,12,0,0,0,28,1, 24,0,0,1,0,1,1,0,0,0,0,0]; [0,23,0,0,23,0,0,23,0,0,1,0,13,0,0,0,24,0,0,1,0,25,0,0, 13,0,0,5,22,0,11,2,0,0,1,1,0,0,0,0]; [0,0,0,12,18,19,0,0,29,0,0,0,0,0,25,0,0,13,0,0, 0,11,0,16,20,0,11,0,16,23,0,0,1,0,0,1,1,0,0,0]; [20,0,20,0,0,0,12,0,20,0,0,8,0,0,23, 0,0,16,0,7,0,10,0,0,3,16,0,0,0,11,13,0,0,0,0,0,1,1,0,0]; [13,0,9,0,0,0,8,0,0,0,23, 14,0,0,0,17,0,0,27,29,0,0,23,0,0,6,0,22,0,27,0,10,0,0,0,0,0,1,1,0]; [29,17,0,0,11,0, 0,28,0,25,0,0,25,24,0,0,0,0,19,11,11,0,0,25,0,0,0,0,0,0,10,0,0,0,0,0,0,0,1,1]; [26, 0,7,19,0,0,11,7,0,0,0,0,0,19,6,0,4,0,0,0,21,0,8,11,0,18,17,0,0,0,0,0,2,0,0,0,0,0,0, 1]);
HE is ([0,0,0,0,21,0,0,24,0,1,0,0,0,0,0,0,0,0,4,0,0,2,1,0,0,0,0,0,0,0,0,0,0,0,0,0,0,0, 0,0,0,0,0,0,0]; [,0,20,19,0,18,0,0,0,0,0,0,0,14,0,0,0,0,0,0,0,1,1,0,0,0,0,0,0,0,0,0, 0,0,0,0,0,0,0,0,0,0,0,0]; [0,0,0,0,23,14,20,0,0,0,0,0,0,0,0,0,0,0,13,0,0,0,1,1,0,0,0, 0,0,0,0,0,0,0,0,0,0,0,0,0,0,0,0,0]; [4,0,0,0,0,0,0,14,0,0,0,0,0,0,0,0,29,17,0,0,0,0, 0,1,1,0,0,0,0,0,0,0,0,0,0,0,0,0,0,0,0,0,0,0]; [0,0,4,11,0,0,0,0,2,0,0,0,0,12,0,0,0,0, 0,0,0,0,0,0,1,1,0,0,0,0,0,0,0,0,0,0,0,0,0,0,0,0,0,0,]; [0,0,0,0,9,0,0,0,0,0,0,0,0,0,0, 11,0,11,14,0,0,0,0,0,0,1,1,0,0,0,0,0,0,0,0,0,0,0,0,0,0,0,0]; [0,0,0,0,0,0,0,0,0,13, 0,14,0,7,0,0,20,0,0,0,0,0,0,0,0,0,1,10,0,0,0,0,0,0,0,0,0,0,0,0,0,0,0]; [0 0,0,0,6,0, 28,0,9,0,0,25,0,0,0,0,0,0,0,0,0,0,0,0,0,0,0,1,1,0,0,0,0,0,0,0,0,0,0,0,0,0,0,0]; [0,0, 0,0,0]; [0,3,0,0,0,0,16,29,0,0,0,0,0,0,0,0,0,0,0,0,1,0,0,0,0,0,0,0,0,1,1,0,0,0,0,0,0, 0,0,0,0,0,0,0]; [0,0,0,14,0,0,0,0,18,0,0,0,0,0,0,0,0,0,00,19,0,0,0,0,0,0,0,0,0,0,1,1, 0,0,0,0,0,0,0,0,0,0,0,0]; [0,0,0,0,0,0,0,0,0,2,0,0,2,2,21,0,0,0,0,0,0,0,0,0,0,0,0,0, 0,0,0,1,1,0,0,0,0,0,0,0,0,0,0,0]; [0,7,0,0,0,0,0,0,0,0,0,1,23,0,0,0,22,0,0,0,0,0,0,0, 0,0,0,0,0,0,0,0,1,1,0,0,0,0,0,0,0,0,0,0]; [0,0,0,0,0,0,0,0,0,0,0,26,26,0,11,0,0,0,0, 4,0,0,0,0,0,0,0,0,0,0,0,0,0,1,1,0,0,0,0,0,0,0,0,0]; [8,0,11,0,0,0,0,0,0,0,0,0,0,0,0, 8,0,0,0,0,0,0,0,0,0,0,0,0,0,0,0,0,0,1,1,0,0,0,0,0,0,0,0]; [0,20,5,3,0,0,0,0,0,0, 0,0,0,0,0,0,0,0,18,0,0,0,0,0,0,0,0,0,0,0,0,0,0,0,1,1,0,0,0,0,0,0,0]; [15,0,0,0,0,0,0, 0,27,0,17,0,0,0,17,0,0,0,0,0,0,0,0,0,0,0,0,0,0,0,0,0,0,0,0,0,1,1,0,0,0,0,0,0]; [0,0, 0,0,0,4,0,0,0,18,25,0,0,0,0,0,0,0,22,0,0,0,0,0,0,0,0,0,0,0,0,0,0,0,0,0,0,1,1,0,0,0, 0,0]; [0,24,0,0,0,0,0,0,0,0,0,0,16,0,16,0,0,0,0,0,0,0,0,0,0,0,0,0,0,0,0,0,0,0,0,0,0, 0,1,1,0,0,0,0]; [0,0,0,0,0,0,0,7,0,0,20,0,0,0,0,26,0,5,0,0,2,0,0,0,0,0,0,0,0,0,0,0,0, 0,0,0,0,0,0,1,0,0,0,0]; [0,0,0,0,0,0,13,0,0,0,0,20,0,0,0,0,1,0,0,0,0,0,0,0,0,0,0,21, 0,0,0,0,0,0,0,0,0,0,0,0,2,1,0,0]; [0,0,0,0,0,0,0,0,0,12,0,0,0,0,0,0,0,0,0,10,0,0,0, 19,0,0,0,0,0,0,0,0,0,0,0,0,0,0,0,0,1,1,0]; [0,0,2,0,0,0,0,0,0,0,0,0,0,0,0,3,0,0,0, 0,5,0,0,0,0,10,0,0,0,0,0,0,0,0,0,0,0,0,0,0,0,0,1,1]; [19,0,0,0,0,0,0,16,0,0,0,26,0, 3,0,0,0,0,0,0,0,0,0,0,0,0,0,0,0,0,0,0,0,0,0,0,0,0,0,2,0,0,1]);
HF is ([0,0,0,0,13,0,0,0,0,18,11,0,14,0,9,0,0,0,20,0,0,0,0,22,0,2,1,0,0,0,0,0,0,0,0, 0,0,0,0,0,0,0,0,0]; [0,0,0,0,20,24,4,24,0,8,0,0,0,0,0,0,6,0,0,0,0,0,0,0,1,1,0,0, 0,0,0,0,0,0,0,0,0,0,0,0,0,0]; [0,0,0,0,0,0,0,0,0,0,0,0,0,23,0,0,0,1,11,29,17,27,0,0, 0,0,0,1,1,0,0,0,0,0,0,0,0,0,0,0,0,0,0,0]; [0,0,7,18,0,0,0,21,0,0,0,22,0,0,0,29,0,0,0, 1,0,26,0,0,0,0,0,0,1,1,0,0,0,0,0,0,0,0,0,0,0,0,0,0]; [0,0,19,1,0,0,0,0,0,0,0,0,0,0, 22,0,24,0,0,0,0,0,15,0,6,0,0,0,0,1,1,0,0,0,0,0,0,0,0,0,0,0,0,0]; [26,3,8,0,0,16,9,0, 0,0,0,0,0,0,28,0,0,0,0,0,0,0,0,0,0,0,0,0,0,0,1,1,0,0,0,0,0,0,0,0,0,0,0,0]; [4,0,0,0, 0,12,22,0,18,0,0,0,9,7,0,0,27,0,0,0,0,0,0,0,0,0,0,0,0,0,0,1,1,0,0,0,0,0,0,0,0,0,0, 0]; [0,12,0,0,1,0,0,0,0,0,0,0,21,0,0,17,0,0,0,0,4,0,0,4,0,1,0,0,0,0,0,0,1,1,0,0,0,0, 0,0,0,0,0,0]; [0,0,0,8,0,0,0,0,28,0,8,21,0,0,0,4,0,0,0,0,0,0,12,0,0,0,0,0,0,0,0,0,0, 1,1,0,0,0,0,0,0,0,0,0]; [0,0,0,0,0,0,0,0,0,7,26,0,0,0,23,0,0,0,0,0,0,0,9,3,28,0,0,0, 0,0,0,0,0,0,1,1,0,0,0,0,0,0,0,0]; [9,0,0,0,0,0,0,30,29,0,0,0,0,10,0,0,0,17,0,0,0,4,0, 0,0,0,0,0,0,0,0,0,0,0,0,1,1,0,0,0,0,0,0,0]; [0,0,0,0,8,0,0,0,0,0,0,0,8,0,0,0,12,0,0, 0,2,0,0,14,12,0,0,0,0,0,0,0,0,0,0,0,1,1,0,0,0,0,0,0]; [0,0,6,20,17,0,0,2,0,0,0,17,0, 0,0,26,0,0,0,0,0,0,0,0,0,0,0,0,0,0,0,0,0,0,0,0,0,1,1,0,0,0,0,0]; [0,6,0,0,0,30,30,0, 0,0,0,0,0,0,0,0,24,0,0,0,24,0,16,0,0,0,0,0,0,0,0,0,0,0,0,0,0,0,1,1,0,0,0,0]; [0,0,0, 0,0,0,0,0,0,6,0,30,0,5,0,0,0,27,0,21,0,1,0,0,0,2,0,0,0,0,0,0,0,0,0,0,0,0,1,0,0,0, 0]; [0,0,0,0,0,0,0,0,0,0,0,0,0,0,0,0,0,8,0,0,0,0,0,0,9,0,0,0,0,0,26,0,2,25,14,0,0,6, 0,0,2,1,0,0]; [0,0,0,0,0,0,0,0,0,0,0,0,0,0,0,0,20,0,0,0,0,0,0,0,0,9,15,0,0,29,13,0,0, 29,0,0,0,0,0,0,1,1,1,0]; [18,0,0,0,0,22,0,17,0,0,0,0,0,0,0,0,0,0,3,0,0,0,0,0,0,0,22, 0,2,10,0,0,0,0,0,0,0,0,0,0,0,0,1,1]; [0,0,0,0,0,0,0,0,0,8,0,29,0,0,0,0,0,0,17,4,0,0, 0,0,0,0,0,0,0,0,0,0,0,0,0,0,0,0,19,17,2,0,0,1]);
HG is ([2,0,0,0,0,0,0,0,0,0,29,6,0,0,0,0,0,28,3,28,8,0,0,0,12,20,0,0,0,20,2,1,0,0 0, 0,0,0,0,0,0,0,0,0]; [7,0,0,0,7,9,0,16,0,5,0,0,24,0,0,0,0,17,0,0,0,27,0,0,0,0,0,0,8,3, 0,1,1,0,0,0,0,0,0,0,0,0,0,0]; [0,22,0,23,11,22,0,0,25,12,0,0,0,0,0,0,21,0,0,0,0,0,0, 0,0,0,16,2,22,0,0,0,1,1,0,0,0,0,0,0,0,0,0,0]; [0,25,7,0,0,0,1,0,14,0,0,0,0,0,27,16, 23,0,27,0,0,0,0,27,0,30,0,0,0,0,0,0,0,01,1,0,0,0,0,0,0,0,0,0]; [0,19,0,3,0,12,0,0,30, 0,0,0,0,0,0,28,0,0,28,0,0,0,28,0,0,22,0,0,0,29,1,0,0,0,1,1,0,0,0,0,0,0,0,0]; [0,0,9, 0,0,0,0,4,0,0,0,0,22,21,4,9,29,0,0,0,0,0,7,14,0,0,0,15,0,0,0,0,0,0,0,1,1,0,0,0,0,0, 0,0]; [24,0,0,0,0,0,0,0,0,0,12,25,28,29,30,0,0,0,0,18,20,13,0,11,0,0,0,0,0,0,0,0,0, 0,0,0,1,1,0,0,0,0,0,0]; [0,29,0,0,0,4,6,0,25,6,0,0,0,0,0,0,0,0,0,11,0,29,0,0,5,0,12, 0,7,0,0,0,0,0,0,0,0,1,1,0,0,0,0,0]; [0,0,28,0,0,0,10,0,0,28,0,0,10,0,0,14, 2,0,0,0,22,0,14,8,0,0,0,0,0,0,0,0,0,0,1,1,0,0,0,0]; [0,0,0,7,19,0,0,22,0,0,6,4,0,0,0, 0,0,7,0,0,5,0,20,0,0,0,0,5,0,8,2,0,0,0,0,0,0,0,0,1,0,0,0,0]; [0,0,0,9,0,0,0,0,0,0,0, 27,0,0,12,0,0,0,0,0,0,0,21,0,0,0,0,0,0,0,0,0,0,14,0,0,17,22,0,0,2,1,0,0]; [27,0,0,0, 0,0,0,0,0,0,0,0,15,21,0,0,0,0,18,0,0,0,0,0,0,24,0,0,0,0,0,18,12,0,0,11,0,0,0,0,1,1, 1,0]; [0,0,0,0,0,0,20,0,0,0,0,0,0,0,0,0,0,0,0,0,0,0,0,0,0,0,0,0,0,0,0,0,4,26,30,0,0, 0,0,17,0,0,1,1]; [0,0,0,0,8,0,0,0,0,1,0,0,0,0,0,0,0, 11,0,0,0,0,0,0,12,0,0,0,13,0,0,0, 0,0,0,0,0,0,12,0,2,0,0,1]);
HH is ([0,0,0,23,0,0,0,0,12,25,12,24,0,0,0,0,23,0,0,0,3,13,0,13,0,28,0,15,11,0,0, 29,2,1,0,0,0,0,0,0,0,0,0,0]; [0,0,21,0,0,14,0,25,0,0,0,14,0,0,14,14,27,0,0,1,0,19,7, 0,28,0,0,0,0,8,8,0,0,1,1,0,0,0,0,0,0,0,0,0]; [19,0,16,0,0,5,0,18,0,0,0,0,6,2,0,17,0, 0,14,20,0,0,25,0,13,0,4,0,0,6,0,0,0,0,1,1,0,0,0,0,0,0,0,0]; [24,1,0,20,29,0,30,0,14, 0,28,0,0,0,0,0,0,2,20,0,0,0,0,17,0,0,0,0,22,0,0,6,1,0,0,1,1,0,0,0,0,0,0,0]; [15,11, 11,0,23,27,14,0,0,0,0,0,0,9,15,0,0,30,0,0,0,0,13,0,2,0,27,0,0,0,7,0,0,0,0,0,1,1,0, 0,0,0,0,0]; [0,0,10,0,0,0,0,20,0,14,0,22,9,14,0,28,0,0,0,17,0,0,0,0,19,19,8,2,0,15, 0,0,0,0,0,0,0,1,1,0,0,0,0,0]; [0,0,0,0,0,0,0,23,18,2,0,23,0,0,0,0,0,13,0,13,0,0,0, 0,13,0,3,2,0,0,3,0,0,0,0,0,0,1,1,0,0,0,0]; [0,19,0,9,6,0,20,0,0,0,19,0,0,0,27,0,24, 17,0,0,12,9,0,12,0,0,0,0,6,10,0,2,0,0,0,0,0,0,1,0,0,0,0]; [0,0,0,11,14,0,0,0,0,0, 0,0,0,29,0,0,0,0,0,0,0,0,0,4,0,0,13,0,0,0,0,0,2,0,0,11,28,25,0,0,2,1,0,0]; [0,0,0,0, 0,25,0,0,0,0,0,0,0,0,0,0,2,0,0,0,0,0,23,0,0,0,0,0,0,0,0,0,0,19,23,0,0,0,0,2,1,1,1, 0]; [0,0,0,0,0,0,0,0,28,0,0,0,0,0,0,0,0,0,0,0,0,0,0,0,0,0,0,0,0,0,0,0,1,0,0,3,8,5, 0,0,0,1,1]; [0,0,0,0,0,0,0,1,0,0,0,0,0,0,0,6,0,0,19,16,0,0,0,0,0,0,0,0,0,6,0,0,0,0, 18,7,0,0,17,9,2,0,0, 1]); and
HI is ([0,0,0,0,24,0,25,0,0,0,0,0,0,0,12,0,0,0,0,0,0,0,0,0,0,0,0,0,0,30,0,0,0,0,0,0, 0,0,0,0,2,1,0,0]; [0,0,0,0,0,0,0,0,0,0,0,0,0,19,0,0,0,0,5,0,0,18,0,0,0,0,0,0,0,0,0,0, 0,0,0,0,0,0,0,0,1,1,1,0]; [0,0,6,0,0,0,0,0,0,0,0,0,16,0,0,0,0,3,0,0,0,0,0,0,0,0,0,7, 0,0,0,0,0,0,0,0,0,0,0,0,0,0,1,1]; [18,0,0,0,0,0,0,0,0,0,13,0,0,0,0,0,0,0,0,0,11,0,0, 0,0,4,0,0,0,0,0,0,0,0,0,0,0,0,0,0,2,0,0,1]).

18. The method according to claim 12, wherein the encoding comprises solving a linear equations system: H′x^{T}=0, for a matrix H′ that includes elements P_{i,j}, wherein each of the elements P_{i,j} contains: (a) the value “0” if P_{i,j} represents a 30×30 zero matrix; or (b) a value equal to 1+s if P_{i,j}=I^{s}, wherein I³ is one of a set of 30×30 permutation matrices; wherein each permutation matrix is a cyclically right shifted identity matrix, denoted as I^{s} for a shift s, where s is an integer between 0 and 29, wherein the matrix H′ is representable as an ordered set of vectors selected from a group of ordered sets of vectors that consists the order sets of vectors HE, HF, HG, and HH, wherein the first bits of the codewords are the bits of the data bit vector; wherein:
HE is ([0,0,0,0,21,0,0,24,0,1,0,0,0,0,0,0,0,4,0,0,2,1,0,0,0,0,0,0,0,0,0,0,0,0,0,0,0, 0,0,0,0,0,0,0]; [0,0,20,19,0,18,0,0,0,0,0,0,0,14,0,0,0,0,0,0,0,1,1,0,0,0,0,0,0,0,0, 0,0,0,0,0,0,0,0,0,0,0,0]; [0,0,0,0,23,14,20,0,0,0,0,0,0,0,0,0,0,0,13,0,0,0,1,1,0,0,0, 0,0,0,0,0,0,0,0,0,0,0,0,0,0,0,0,0]; [4,0,0,0,0,0,0,14,0,0,0,0,0,0,0,0,29,17,0,0,0,0, 0,1,1,0,0,0,0,0,0,0,0,0,0,0,0,0,0,0,0,0,0,0]; [0,0,4,11,0,0,0,0,2,0,0,0,0,12,0,0,0,0, 0,0,0,0,0,0,1,1,0,0,0,0,0,0,0,0,0,0,0,0,0,0,0,0,0,0]; [0,0,0,0,9,0,0,0,0,0,0,0,0,0,0, 11,0,11,14,0,0,0,0,0,0,1,1,0,0,0,0,0,0,0,0,0,0,0,0,0,0,0,0,0]; [0,0,0,0,0,0,0,0,0,13, 0,14,0,7,0,0,20,0,0,0,0,0,0,0,0,0,1,1,0,0,0,0,0,0,0,0,0,0,0,0,0,0,0,0]; [0,0,0,0,6,0, 28,0,9,0,0,25,0,0,0,0,0,0,0,0,0,0,0,0,0,0,1,1,0,0,0,0,0,0,0,0,0,0]; [0,0,0,0,6,0, 0,0,0,24,0,0,0,0,0,0,0,0,0,15,0,0,15,23,0,0,0,0,0,0,0,0,1,1,0,0,0,0,0,0,0,0,0,0,0, 0,0,0]; [0,3,0,0,0,0,16,29,0,0,0,0,0,0,0,0,0,0,0,0,10,0,0,0,0,0,0,1,1,0,0,0,0,0,0, 0,0,0,0,0,0,0]; [0,0,0,14,0,0,0,0,18,0,0,0,0,0,0,0,0,0,0,19,0,0,0,0,0,0,0,0,0,0,1,1, 0,0,0,0,0,0,0,0,0,0,0]; [0,0,0,0,0,0,0,0,0,2,0,0,2,2,21,0,0,0,0,0,0,0,0,0,0,0,0,0, 0,0,0,1,1,0,0,0,0,0,0,0,0,0,0,0]; [0,7,0,0,0,0,0,0,0,0,0,1,23,0,0,0,22,0,0,0,0,0,0,0, 0,0,0,0,0,0,0,0,1,1,0,0,0,0,0,0,0,0,0,0]; [0,0,0,0,0,0,0,0,0,0,0,26,26,0,11,0,0,0,0, 4,0,0,0,0,0,0,0,0,0,0,0,0,0,1,1,0,0,0,0,0,0,0,0,0]; [8,0,11,0,0,0,0,0,0,0,0,0,0,0,0, 8,0,0,0,0,0,0,0,0,0,0,0,0,0,0,0,0,1,1,0,0,0,0,0,0,0,0]; [0,20,5,3,0,0,0,0,0,0,0, 0,0,0,0,0,0,0,0,18,0,0,0,0,0,0,0,0,0,0,0,0,0,0,0,1,1,0,0,0,0,0,0,0]; [15,0,0,0,0,0,0, 0,27,0,17,0,0,0,17,0,0,0,0,0,0,0,0,0,0,0,0,0,0,0,0,0,0,0,0,0,1,1,0,0,0,0,0,0]; [0,0, 0,0,0,4,0,0,0,18,25,0,0,0,0,0,0,0,22,0,0,0,0,0,0,0,0,0,0,0,0,0,0,0,0,0,0,1,1,0,0,0, 0,0]; [0,24,0,0,0,0,0,0,0,0,0,0,16,0,16,0,0,0,0,0,0,0,0,0,0,0,0,0,0,0,0,0,0,0,0,0,0, 0,1,1,0,0,0,0]; [0,0,0,0,0,0,0,7,0,0,20,0,0,0,0,26,0,5,0,0,2,0,0,0,0,0,0,0 0,0,0,0,0,0, 0,0,0,0,0,0,1,0,0,0,0]; [0,0,0,0,0,0,13,0,20,0,0,0,0,1,0,0,0,0,0,0,0,0,0,0,21, 0,0,0,0,0,0,0,0,0,0,0,0,2,1,0,0]; [0,0,0,0,0,0,0,0,0,12,0,0,0,0,0,0,0,0,0,10,0,0,0, 19,0,0,0,0,0,0,0,0,0,0,0,0,0,0,0,0,1,1,1,0]; [0,0,2,0,0,0,0,0,0,0,0,0,0,0,03,0,0,0, 0,5,0,0,0,0,10,0,0,0,0,0,0,0,0,0,0,0,0,0,0,0,0,1,1]; [19,0,0,0,0,0,0,0,16,0,0,0,26,0, 3,0,0,0,0,0,0,0,0,0,0,0,0,0,0,0,0,0,0,0,0,0,0,0,0,0,2,0,0,1]);
HF is ([0,0,0,0,13,0,0,0,0,18,11,0,14,0,9,0,0,0,20,0,0,0,0,22,0,2,1,0,0,0,0,0,0,0, 0,0,0,0,0,0,0,0][0,0,0,0,0,20,24,4,24,0,8,0,0,0,0,0,0,0,6,0,0,0,0,0,0,0,1,1,0,0, 0,0,0,0,0,0,0,0,0,0,0,0,0,0]; [0,0,0,0,0,0,0,0,0,0,0,0,0,23,0,0,0,1,11,29,17,27,0,0, 0,0,0,1,1,0,0,0,0,0,0,0,0,0,0,0,0,0,0,0]; [0,0,7,18,0,0,0,21,0,0,0,22,0,0,0,29,0,0,0, 1,0,26,0,0,0,0,0,0,1,1,0,0,0,0,0,0,0,0,0,0,0,0,0,0]; [0,0,19,1,0,0,0,0,0,0,0,0,0,0, 22,0,24,0,0,0,0,0,15,0,6,0,0,0,0,1,1,0,0,0,0,0,0,0,0,0,0,0,0]; [26,3,8,0,0,16,9,0, 0,0,0,0,0,0,28,0,0,0,0,0,0,0,0,0,0,0,0,0,0,1,1,0,0,0,0,0,0,0,0,0,0,0,0]; [4,0,0,0, 0,12,22,0,18,0,0,0,9,7,0,0,27,0,0,0,0,0,0,0,0,0,0,0,0,0,0,1,1,0,0,0,0,0,0,0,0,0,0, 0]; [0,12,0,0,1,0,0,0,0,0,0,0,21,0,0,17,0,0,0,0,4,0,0,4,0,1,0,0,0,0,0,0,1,1,0,0,0,0, 0,0,0,0,0,0]; [0,0,0,8,0,0,0,0,28,0,8,21,0,0,0,4,0,0,0,0,0,0,12,0,0,0,0,0,0,0,0,0,0, 1,1,0,0,0,0,0,0,0,0,0]; [0,0,0,0,0,0,0,0,0,7,26,0,0,0,23,0,0,0,0,0,0,0,9,3,28,0,0,0, 0,0,0,0,0,0,1,1,0,0,0,0,0,0,0,0]; [9,0,0,0,0,0,0,30,29,0,0,0,0,10,0,0,0,17,0,0,0,4,0, 0,0,0,0,0,0,0,0,0,0,0,0,1,1,0,0,0,0,0,0,0]; [0,0,0,0,8,0,0,0,0,0,0,0,8,0,0,0,12,0,0, 0,2,0,0,14,12,0,0,0,0,0,0,0,0,0,0,1,1,0,0,0,0,0,0]; [0,0,6,20,17,0,0,2,0,0,0,17,0, 0,0,26,0,0,0,0,0,0,0,0,0,0,0,0,0,0,0,0,0,0,0,0,0,1,1,0,0,0,0,0]; [0,6,0,0,0,30,30,0, 0,0,0,0,0,0,0,0,24,0,0,0,24,0,16,0,0,0,0,0,0,0,0,0,0,0,0,0,0,0,1,1,0,0,0,0]; [0,0,0, 0,0,0,0,0,0,6,0,30,0,5,0,0,0,27,0,21,0,1,0,0,0,2,0,0,0,0,0,0,0,0,0,0,0,0,0,1,0,0,0, 0]; [0,0,0,0,0,0,0,0,0,0,0,0,0,0,0,0,0,8,0,0,0,0,0,0,9,0,0,0,0,0,26,0,2,25,14,0,0,6, 0,0,2,1,0,0]; [0,0,0,0,0,0,0,0,0,0,0,0,0,0,0,0,20,0,0,0,0,0,0,0,0,9,15,0,0,29,13,0,0, 29,0,0,0,0,0,0,1,1,1,0]; [18,0,0,0,0,22,0,17,0,0,0,0,0,0,0,0,0,0,3,0,0,0,0,0,0,0,22, 0,2,10,0,0,0,0,0,0,0,0,0,0,0,0,1,1][0,0,0,0,0,0,0,0,0,8,0,29,0,0,0,0,0,0,17,4,0,0, 0,0,0,0,0,0,0,0,0,0,0,0,0,0,0,0,19,17,2,0,0,1]);
HG is ([2,0,0,0,0,0,0,0,0,0,29,6,0,0,0,0,0,28,3,28,8,0,0,0,12,20,0,0,0,20,2,1,0,0,0, 0,0,0,0,0,0,0,0,0]; [7,0,0,0,7,9,0,16,0,5,0,0,24,0,0,0,0,17,0,0,0,27,0,0,0,0,0,0,8,3, 0,1,1,0,0,0,0,0,0,0,0,0,0,0]; [0,22,0,23,11,22,0,0,25,12,0,0,0,0,0,0,21,0,0,0,0,0,0, 0,0,0,16,2,22,0,0,0,1,1,0,0,0,0,0,0,0,0,0,0]; [0,25,7,0,0,0,1,0,14,0,0,0,0,0,27,16, 23,0,27,0,0,0,0,27,0,30,0,0,0,0,0,0,0,1,1,0,0,0,0,0,0,0,0,0]; [0,19,0,3,0,12,0,0,30, 0,0,0,0,0,0,28,0,0,28,0,0,0,28,0,0,22,0,0,0,29,1,0,0,0,1,1,0,0,0,0,0,0,0,0]; [0,0,9, 0,0,0,0,4,0,0,0,0,22,21,4,9,29,0,0,0,0,0,7,14,0,0,0,15,0,0,0,0,0,0,0,1,1,0,0,0, 0,0]; [24,0,0,0,0,0,0,0,0,0,12,25,28,29,30,0,0,0,0,18,20,13,0,11,0,0,0,0,0,0,0,0,0, 0,0,0,1,0,0,0,0,0,0]; [0,29,0,0,0,4,6,0,25,60,0,0,0,0,0,0,0,0,11,0,29,0,0,5,0,12, 0,7,0,0,0,0,0,0,0,0,1,1,0,0,0,0,0]; [0,0,28,0,0,0,28,0,0,0,10,0,0,28,0,0,10,0,0,14, 2,0,0,0,22,0,14,8,0,0,0,0,0,0,0,0,0,0,1,1,0,0,0,0]; [0,0,0,7,19,0,0,22,0,0,6,4,0,0,0, 0,0,7,0,0,5,0,20,0,0,0,0,5,0,8,2,0,0,0,0,0,0,0,0,1,0,0,0,0]; [0,0,0,9,0,0,0,0,0,0,0, 27,0,0,12,0,0,0,0,0,0,0,21,0,0,0,0,0,0,0,0,0,0,14,0,0,17,22,0,0,2,1,0,0]; [27,0,0,0, 0,0,0,0,0,0,0,0,15,21,0,0,0,0,18,0,0,0,0,0,0,24,0,0,0,0,0,18,12,0,0,11,0,0,0,0,1,1, 1,0]; [0,0,0,0,0,0,20,0,0,0,0,0,0,0,0,0,0,0,0,0,0,0,0,0,0,0,0,0,0,0,0,0,4,26,30,0,0, 0,0,17,0,0,1,1]; [0,0,0,0,8,0,0,0,0,1,0,0,0,0,0,0,0,11,0,0,0,0,0,0,12,0,0,0,13,0,0,0, 0,0,0,0,0,0,12,0,2,0,1]); and
HH is ([0,0,0,23,0,0,0,0,12,25,12,24,0,0,0,0,23,0,0,0,3,13,0,13,0,28,0,15,11,0,0, 29,2,1,0,0,0,0,0,0,0,0,0,0]; [0,0,21,0,0,14,0,25,0,0,0,14,0,0,14,14,27,0,0,1,0,19,7, 0,28,0,0,0,0,8,8,0,0,1,1,0,0,0,0,0,0,0,0,0]; [19,0,16,0,0,5,0,18,0,0,0,0,6,2,0,17,0, 0,14,20,0,0,25,0,13,0,4,0,0,6,0,0,0,0,1,1,0,0,0,0,0,0,0,0]; [24,1,0,20,29,0,30,0,14, 0,28,0,0,0,0,0,0,2,20,0,0,0,0,17,0,0,0,0,22,0,0,6,1,0,0,1,1,0,0,0,0,0,0,0]; [15,11, 11,0,23,27,14,0,0,0,0,0,0,9,15,0,0,30,0,0,0,0,13,0,2,0,27,0,0,0,7,0,0,0,0,0,1,1,0, 0,0,0,0,0]; [0,0,10,0,0,0,0,20,0,14,0,22,9,14,0,28,0,0,0,17,0,0,0,0,19,19,8,2,0,15, 0,0,0,0,0,0,0,1,1,0,0,0,0,0]; [0,0,0,0,0,0,0,0,23,18,2,0,23,0,0,0,0,13,0,13,0,0,0, 0,13,0,3,2,0,0,3,0,0,0,0,0,0,1,1,0,0,0,0]; [0,19,0,9,6,0,20,0,0,0,19,0,0,0,27,0,24, 17,0,0,12,9,0,12,0,0,0,0,6,0,10,0,2,0,0,0,0,0,0,1,0,0,0,0]; [0,0,0,11,14,0,0,0,0,0, 0,0,0,29,0,0,0,0,0,0,0,0,0,4,0,0,13,0,0,0,0,0,2,0,0,11,28,25,0,0,2,1,0,0]; [0,0,0,0, 0,25,0,0,0,0,0,0,0,0,0,0,2,0,0,0,0,0,23,0,0,0,0,0,0,0,0,0,0,19,23,0,0,0,0,2,1,1,1, 0]; [0,0,0,0,0,0,0,0,28,0,0,0,0,0,0,0,0,0,0,0,0,0,0,0,0,0,0,0,0,0,0,0,0,0,1,0,0,3,8,5, 0,0,0,1,1]; [0,0,0,0,0,0,0,1,0,0,0,0,0,0,0,6,0,0,19,16,0,0,0,0,0,0,0,0,0,6,0,0,0,0, 18,7,0,0,17,9,2,0,0,1]).

19. The method according to claim 12, wherein the transmitting comprises transmitting the codeword using modified dual-carrier modulation.

20. A receiver, comprising:
a communication module configured to attempt to receive a first codeword portion and a second codeword portion of a transmitted codeword, wherein the first codeword portion is of a first length;
a processor for selecting between a first parity check process and a second parity check process, wherein the first parity check process comprises parity check of messages of the first length and the second parity check process comprises parity check for longer messages; and
a decoder configured to decode at least a portion of the codeword by the selected parity check process, to receive a decoded data bit vector.

21. The receiver according to claim 20, wherein the communication module is further adapted to attempt to receive the first and the second codeword portions in different communication channels.

22. The receiver according to claim 20, wherein the communication module is further adapted to attempt to receive the first codeword portion in a first communication channel, and to attempt to receive the second codeword portion in at least one sub-channel of the first communication channel in which the first codeword portion is not transmitted.

23. The receiver according to claim 20, wherein the processor may be adapted to select between a first parity check process which is equivalent to processing the first codeword portion based on a first parity check matrix and a second parity check process which is equivalent to processing the codeword based on a second parity check matrix that comprises the first parity check matrix.

24. The receiver according to claim 23, wherein the second parity check process may be equivalent to processing the codeword based on a second parity check matrix H′, for a matrix H′ that includes elements P_{i,j}, wherein each of the elements P_{i,j} contains: (a) the value “0” if P_{i,j} represents a 30×30 zero matrix; or (b) a value equal to 1+s if P_{i,j}=I^{s}, wherein I^{s} is one of a set of 30×30 permutation matrices; wherein each permutation matrix is a cyclically right shifted identity matrix, denoted as I^{s} for a shift s, where s is an integer between 0 and 29, wherein the matrix H′ is representable as an ordered set of vectors selected from a group of ordered sets of vectors that consists the order sets of vectors HA, HB, HC, HD, HE, HF, HG, HH, and HI, wherein the first bits of the codewords are the bits of the data bit vector; wherein:
HA is ([0,0,25,0,0,0,30,0,0,0,0,0,0,0,7,26,0,0,0,0,2,1,0,0,0,0,0,0,0,0,0,0,0,0,0,0, 0,0,0,0]; [0,0,0,11,0,0,0,0,0,30,12,0,9,0,0,0,0,0,0,0,0,1,1,0,0,0,0,0,0,0 0,0,0,0,0,0, 0,0,0,0,0]; [30,0,0,0,0,0,28,8,0,0,0,0,0,0,0,29,0,0,0,0,0,0,1,1,0,0,0,0,0,0,0,0,0,0,0 0,0,0,0,0,0]; [0,0,0,0,0,29,0,0,12,0,0,4,0,0,0,0,0,0,17,0,0,0,0,1,1,0,0,0,0,0,0,0,0, 0,0,0,0,0,0,0]; [0,21,0,0,0,0,0,0,0,0,29,0,0,0,0,0,0,23,0,28,0,0,0,0,1,1,0,0,0,0,0,0, 0,0,0,0,0,0,0,0]; [24,0,0,0,0,0,23,0,0,0,0,0,0,0,26,7,0,0,0,0,0,0,0,0,1,1,0,0,0,0, 0,0,0,0,0,0,0,0,0]; [0,0,30,0,0,1,0,0,0,0,0,0,0,0,0,0,0,3,0,0,0,0,0,0,0,0,1,1,0,0,0, 0,0,0,0,0,0,0,0,0]; [0,0,0,3,9,0,0,0,0,6,0,0,27,0,0,0,0,0,0,0,0,0,0,0,0,0,0,1,1,0,0, 0,0,0,0,0,0,0,0,0]; [0,0,0,15,23,0,0,0,0,13,0,0,23,0,0,0,0,0,0,0,0,0,0,0,0,0,0,0,1,1, 0,0,0,0,0,0,0,0,0]; [0,0,0,0,0,0,0,0,0,0,0,13,0,0,0,0,17,0,0,3,1,0,0,0,0,0,0,0,0,1, 1,0,0,0,0,0,0,0,0,0]; [0,0,0,23,0,0,0,0,19,19,0,0,18,0,0,0,0,0,0,0,0,0,0,0,0,0,0,0,0, 0,1,1,0,0,0,0,0,0,0,0]; [10,0,0,0,0,0,25,29,0,0,0,0,0,0,0,2,0,0,0,0,0,0,0,0,0,0,0,0, 0,0,0,1,1,0,0,0,0,0,0,0]; [13,0,0,0,0,7,21,0,0,0,0,0,0,0,0,10,0,0,0,0,0,0,0,0,0,0,0, 0,0,0,0,0,1,1,0,0,0,0,0,0]; [0,0,15,29,0,0,0,0,0,17,0,0,13,0,0,0,0,0,0,0,0,0,0,0,0, 0,0,0,0,0,0,0,1,1,0,0,0,0,0]; [3,0,0,0,0,0,0,0,0,0,0,17,0,0,0,0,24,0,22,0,0,0,0,0,0, 0,0,0,0,0,0,0,1,1,0,0,0,0,0]; [0,13,0,0,0,0,0,0,0,0,22,0,0,0,2,0,22,0,0,0,0,0,0,0, 0,0,0,0,0,0,0,0,0,0,0,1,1,0,0,0]; [0,0,0,0,0,0,0,0,1,0,0,0,0,18,0,0,0,19,11,0,0,0,0, 0,0,0,0,0,0,0,0,0,0,0,0,0,1,1,0,0]; [15,5,0,0,0,0,6,0,0,0,0,0,0,0,0,19,0,0,0,0,0,0,0, 0,0,0,0,0,0,0,0,0,0,0,0,0,0,1,1,0]; [0,0,0,0,11,0,0,12,0,0,0,0,0,25,0,0,0,0,0,6,0,0, 0,0,0,0,0,0,0,0,0,0,0,0,0,0,0,0,1,1]; [0,0,0,7,0,0,0,0,0,16,0,0,4,0,0,0,0,0,15,0,2,0, 0,0,0,0,0,0,0,0,0,0,0,0,0,0,0,0,0,1]);
HB is ([7,0,0,0,10,5,15,0,1,0,0,0,15,0,0,0,0, 27,0,0,0,0,0,0,0,2,1,0,0,0,0,0,0,0,0,0, 0,0,0,0]; [27,0,0,29,1,0,0,0,3,13,0,6,0,0,0,0,0,0,0,0,12,0,0,0,0,0,1,1,0,0,0,0,0,0,0, 0,0,0,0,0]; [0,3,0,0,0,0,0,0,0,0,0,0,21,0,11,0,2,10,0,24,0,0,3,0,0,0,0,1,1,0,0,0,0,0, 0,0,0,0,0,0]; [4,0,0,0,0,12,0,0,0,0,22,0,13,0,0,0,6,0,0,0,0,0,22,0,18,0,0,0,1,1,0,0, 0,0,0,0,0,0,0,0]; [0,0,11,0,13,0,0,17,0,0,0,0,0,0,0,16,0,16,0,4,21,0,0,0,0,0,0,0, 1,1,0,0,0,0,0,0,0,0,0]; [18,0,28,0,0,0,0,0,16,0,25,0,23,0,0,0,0,0,0,26,0,0,0,22,0,0, 0,0,0,0,1,1,0,0,0,0,0,0,0,0]; [23,0,0,0,0,0,0,0,26,0,0,25,24,0,0,18,19,24,0,0,0,0, 0,0,0,0,0,0,0,0,1,1,0,0,0,0,0,0,0]; [0,0,0,19,0,0,30,0,0,0,20,24 0,0,0,0,0,0,0,0,26,0, 10,0,11,1,0,0,0,0,0,0,1,1,0,0,0,0,0,0]; [0,0,0,0,11,0,0,0,20,0,0,0,0,0,6,17,0,2,0,0, 0,0,24,3,0,0,0,0,0,0,0,0,0,1,1,0,0,0,0,0]; [15,27,0,0, 16,0,0,0,0,11,0,0,0,0,0,26,0, 0,0,0,0,15,0,26,0,0,0,0,0,0,0,0,0,0,1,1,0,0,0,0]; [9,0,17,0,23,0,0,24,0,0,0,0,0,0, 0,0,30,0,0,0,18,0,0,5,0,0,0,0,0,0,0,0,0,0,1,1,0,0,0]; [11,0,0,0,0,0,26,0,11,6,0,0,0, 0,20,0,0,8,0,0,0,0,19,0,0,0,0,0,0,0,0,0,0,0,0,0,1,1,0,0]; [0,0,0,7,0,0,0,0,24,0,0,11, 30,0,0,0,0,22,10,0,0,7,0,0,0,0,0,0,0,0,0,0,0,0,0,0,0,1,1,0]; [0,25,0,0,26,0,0,14,0, 0,0,0,9,7,0,0,0,0,17,0,0,0,7,0,0,0,0,0,0,0,0,0,0,0,0,0,0,0,1,1]; [0,0,0,0,7,15,0,0,6, 0,24,0,2,28,0,0,0,0,0,0,0,0,29,0,0,2,0,0,0,0,0,0,0,0,0,0,0,0,0,1]);
HC is ([0,2,29,0,0,0,13,0,0,5,0,0,0,16,0,25,4,0,18,28,0,0,0,0,0,2,0,0,0,0,2,1,0,0,0, 0,0,0,0,0]; [10,0,26,0,0,0,0,17,0,0,0,26,6,0,24,0,0,27,0,0,0,0,24,0,0,0,27,0,0,15,0, 1,1,0,0,0,0,0,0,0]; [6,0,0,0,0,3,0,0,21,0,0,4,26,0,8,0,0,0,0,0,11,19,0,0,14,0,0,0,0, 6,0,0,1,1,0,0,0,0,0,0]; [0,0,0,12,0,16,20,0,0,0,30,0,0,0,0,0,8,0,4,30,0,8,0,0,12,26, 0,0,0,0,0,0,0,1,1,0,0,0,0,0]; [0,0,5,0,0,0,14,28,0,0,0,0,0,28,0,0,0,17,1,0,0,0,4,0,0, 24,0,0,1,0,1,0,0,0,1,1,0,0,0,0]; [27,27,0,6,0,0,0,28,21,0,0,14,0,0,18,0,0,0,0,0, 0,18,0,0,0,19,24,0,0,0,0,0,0,1,1,0,0,0]; [20,0,0,20,0,0,2,0,0,0,0,3,0,8,0,0,8,0,0,0, 29,0,4,0,0,4,0,16,0,0,12,0,0,0,0,0,0,1,1,0,0]; [25,0,0,0,23,0,0,0,14,0,21,0,22,0,0, 0,0,14,0,0,0,0,28,27,25,0,0,11,0,0,0,0,0,0,0,0,0,1,1,0]; [0,26,0,0,12,0,17,0,0,23,0, 0,0,12,0,0,0,0,11,0,1,0,0,25,0,0,0,14,6,0,0,0,0,0,0,0,0,0,1,1]; [0,0,0,16,0,1,26,9, 0,0,0,1,0,0,3,0,18,0,21,0,24,0,0,0,0,0,13,0,0,0,2,0,0,0,0,0,0,0,0,1]);
HD is ([8,27,0,0,0,2,0,0,11,12,19,19,22,0,0,10,13,11,13,22,0,0,0,0,0,0,0,0,0,0,0,0, 2,1,0,0,0,0,0,0]; [18,0,0,4,0,9,0,0,0,9,0,0,0,22,0,16,0,0,0,5,13,0,12,0,0,0,28,1, 24,0,0,1,0,1,1,0,0,0,0,0]; [0,23,0,0,23,0,0,23,0,0,1,0,13,0,0,0,24,0,0,1,0,25,0,0, 13,0,0,5,22,0,11,2,0,0,1,1,0,0,0,0]; [0,0,0,12,18,19,0,0,29,0,0,0,0,0,25,0,0,13,0,0, 0,11,0,16,20,0,11,0,16,23,0,0,1,0,0,1,1,0,0,0]; [20,0,20,0,0,0,12,0,20,0,0,8,0,0,23, 0,0,16,0,7,0,10,0,0,3,16,0,0,0,11,13,0,0,0,0,0,1,1,0,0]; [13,0,9,0,0,0,8,0,0,0,23, 14,0,0,0,17,0,0,27,29,0,0,23,0,0,6,0,22,0,27,0,10,0,0,0,0,0,1,1,0]; [29,17,0,0,11,0, 0,28,0,25,0,0,25,24,0,0,0,0,19,11,11,0,0,25,0,0,0,0,0,0,10,0,0,0,0,0,0,0,1,1]; [26, 0,7,19,0,0,11,7,0,0,0,0,0,19,6,0,4,0,0,0,21,0,8,11,0,18,17,0,0,0,0,0,2,0,0,0,0,0,0, 1]);
HE is ([0,0,0,0,21,0,0,24,0,1,0,0,0,0,0,0,0,4,0,0,2,1,0,0,0,0,0,0,0,0,0,0,0,0,0,0,0, 0,0,0,0,0,0,0]; [0,0,20,19,0,18,0,0,0,0,0,0,0,14,0,0,0,0,0,0,0,1,1,0,0,0,0,0,0,0,0,0, 0,0,0,0,0,0,0,0,0,0,0,0]; [0,0,0,0,23,14,20,0,0,0,0,0,0,0,0,0,0,0,13,0,0,0,1,1,0,0,0, 0,0,0,0,0,0,0,0,0,0,0,0,0,0,0,0,0]; [4,0,0,0,0,0,0,14,0,0,0,0,0,0,0,0,29,17,0,0,0,0, 0,1,1,0,0,0,0,0,0,0,0,0,0,0,0,0,0,0,0]; [0,0,4,11,0,0,0,0,2,0,0,0,0,12,0,0,0,0, 0,0,0,0,0,0,1,1,0,0,0,0,0,0,0,0,0,0,0,0,0,0,0,0,0]; [0,0,0,0,9,0,0,0,0,0,0,0,0,0,0, 11,0,11,14,0,0,0,0,0,0,1,1,0,0,0,0,0,0,0,0,0,0,0,0,0,0,0,0,0]; [0,0,0,0,0,0,0,0,0,13, 0,14,0,7,0,0,20,0,0,0,0,0,0,0,0,0,1,1,0,0,0,0,0,0,0,0,0,0,0,0,0,0,0,0]; [0,0,0,0,6,0, 28,0,9,0,0,25,0,0,0,0,0,0,0,0,0,0,0,0,0,0,0,1,1,0,0,0,0,0,0,0,0,0,0,0,0,0,0,0]; [0,0, 0,0,0,24,0,0,0,0,0,0,0,0,0,15,0,0,15,23,0,0,0,0,0,0,0,0,1,1,0,0,0,0,0,0,0,0,0,0,0, 0,0,0]; [0,3,0,0,0,0,16,29,0,0,0,0,0,0,0,0,0,0,0,0,1,0,0,0,0,0,0,0,0,1,1,0,0,0,0,0,0, 0,0,0,0,0,0,0]; [0,0,0,14,0,0,0,0,18,0,0,0,0,0,0,0,0,0,0,19,0,0,0,0,0,0,0,0,0,0,1,1, 0,0,0,0,0,0,0,0,0,0,0,0]; [0,0,0,0,0,0,0,0,0,2,0,0,2,2,21,0,0,0,0,0,0,0,0,0,0,0,0,0, 0,0,0,1,1,0,0,0,0,0,0,0,0,0,0,0]; [0,7,0,0,0,0,0,0,0,0,0,1,23,0,0,0,22,0,0,0,0,0,0,0, 0,0,0,0,0,0,0,0,1,1,0,0,0,0,0,0,0,0,0,0]; [0,0,0,0,0,0,0,0,0,0,0,26,26,0,1,1,0,0,0,0, 4,0,0,0,0,0,0,0,0,0,0,0,0,0,1,1,0,0,0,0,0,0,0,0,0]; [8,0,11,0,0,0,0,0,0,0,0,0,0,0,0, 8,0,0,0,0,0,0,0,0,0,0,0,0,0,0,0,0,0,0,1,1,0,0,0,0,0,0,0,0]; [0,20,5,3,0,0,0,0,0,0,0, 0,0,0,0,0,0,0,0,18,0,0,0,0,0,0,0,0,0,0,0,0,0,0,0,1,1,0,0,0,0,0,0,0]; [15,0,0,0,0,0,0, 0,27,0,17,0,0,0,17,0,0,0,0,0,0,0,0,0,0,0,0,0,0,0,0,0,0,0,1,1,0,0,0,0,0,0]; [0,0, 0,0,0,4,0,0,0,18,25,0,0,0,0,0,0,0,22,0,0,0,0,0,0,0,0,0,0,0,0,0,0,0,0,0,0,1,1,0,0,0, 0,0]; [0,24,0,0,0,0,0,0,0,0,0,0,16,0,16,0,0,0,0,0,0,0,0,0,0,0,0,0,0,0,0,0,0,0,0,0,0, 0,1,1,0,0,0,0]; [0,0,0,0,0,0,0,7,0,0,20,0,0,0,0,26,0,5,0,0,2,0,0,0,0,0,0,0,0,0,0,0,0, 0,0,0,0,0,0,1,0,0,0,0]; [0,0,0,0,0,0,13,0,0,0,0,20,0,0,0,0,1,0,0,0,0,0,0,0,0,0,0,21, 0,0,0,0,0,0,0,0,0,0,0,0,2,1,0,0]; [0,0,0,0,0,0,0,0,0,12,0,0,0,0,0,0,0,0,0,10,0,0,0, 19,0,0,0,0,0,0,0,0,0,0,0,0,0,0,0,0,1,1,1,0]; [0,0,2,0,0,0,0,0,0,0,0,0,0,0,0,3,0,0,0, 0,5,0,0,0,0,10,0,0 0,0,0,0,0,0,0,0,0,0,0,0,0,0,1,1]; [19,0,0,0,0,0,0,0,16,0,0,0,26,0, 3,0,0,0,0,0,0,0,0,0,0,0,0,0,0,0,0,0,0,0,0,0,0,2,0,0,1]);
HF is ([0,0,0,0,13,0,0,0,0,18,11,0,14,0,9,0,0,0,20,0,0,0,0,22,0,2,1,0,0,0,0,0,0,0,0 0,0,0,0,0,0,0,0,0]; [0,0,0,0,0,20,24,4,24,0,8,0,0,0,0,0,0,0,6,0,0,0,0,0,0,0,1,1,0,0, 0,0,0,0,0,0,0,0,0,0,0,0,0,0]; [0,0,0,0,0,0,0,0,0,0,0,0,0,23,0,0,0,1,11,29,17,27,0,0, 0,0,0,1,1,0,0,0,0,0,0,0,0,0,0,0,0,0,0,0]; [0,0,7,18,0,0,0,21,0,0,0,22,0,0,0,29,0,0,0, 1,0,26,0,0,0,0,0,0,1,1,0,0,0,0,0,0,0,0,0,0,0,0,0]; [0,0,19,1,0,0,0,0,0,0,0,0,0,0, 22,0,24,0,0,0,0,0,15,0,6,0,0,0,0,1,1,0,0,0,0,0,0,0,0,0,0,0,0,0]; [26,3,8,0,0,16,9,0, 0,0,0,0,0,0,28,0,0,0,0,0,0,0,0,0,0,0,0,0,0,0,1,1,0,0,0,0,0,0,0,0,0,0,0,0,0]; [4,0,0,0, 0,12,22,0,18,0,0,0,9,7,0,0,27,0,0,0,0,0,0,0,0,0,0,0,0,0,0,1,1,0,0,0,0,0,0,0,0,0,0, 0]; [0,12,0,0,1,0,0,0,0,0,0,0,21,0,0,17,0,0,0,0,4,0,0,4,0,1,0,0,0,0,0,0,1,1,0,0,0,0, 0,0,0 0,0,0]; [0,0,0,8,0,0,0,0,28,0,8,21,0,0,0,4,0,0,0,0,0,0,12,0,0,0,0,0,0,0,0,0,0, 1,1,0,0,0,0,0,0,0,0,0]; [0,0,0,0,0,0,0,0,0, 7,26,0,0,0,23,0,0,0,0,0,0,0,9,3,28,0,0,0, 0,0,0,0,0,0,1,1,0,0,0,0,0,0,0,0]; [9,0,0,0,0,0,0,30,29,0,0,0,0,10,0,0,0,17,0,0,0,4,0, 0,0,0,0,0,0,0,0,0,0,0,0,1,1,0,0,0,0,0,0,0]; [0,0,0,0,8,0,0,0,0,0,0,0,8,0,0,0,12,0,0, 0,2,0,0,14,12,0,0,0,0,0,0,0,0,0,0,0,1,1,0,0,0,0,0,0]; [0,0,6,20,17,0,0,25,0,0,0,17,0, 0,0,26,0,0,0,0,0,0,0,0,0,0,0,0,0,0,0,0,0,0,0,0,0,1,1,0,0,0,0,0]; [0,6,0,0,0,30,30,0, 0,0,0,0,0,0,0,0,24,0,0,0,24,0,16,0,0,0,0,0,0,0,0,0,0,0,0,0,0,0,1,1,0,0,0,0]; [0,0,0, 0,0,0,0,0,0,6,0,30,0,5,0,0,0,27,0,21,0,1,0,0,0,2,0,0,0,0,0,0,0,0,0,0,0,0,0,1,0,0,0, 0]; [0,0,0,0,0,0,0,0,0,0,0,0,0,0,0,0,0,8,0,0,0,0,0,0,9,0,0,0,0,0,26,0,2,25,14,0,0,6, 0,0,2,1,0,0]; [0,0,0,0,0,0,0,0,0,0,0,0,0,0,0,0,20,0,0,0,0,0,0,0,0,9,15,0,0,29,13,0,0, 29,0,0,0,0,0,0,1,1,1,0]; [18,0,0,0,0,22,0,17,0,0,0,0,0,0,0,0,0,0,3,0,0,0,0,0,0,0,22, 0,2,10,0,0,0,0,0,0,0,0,0,0,0,0,1,1]; [0,0,0,0,0,0,0,0,0,8,0,29,0,0,0,0,0,0,17,4,0,0, 0,0,0,0,0,0,0,0,0,0,0,0,0,0,0,0,19,17,2,0,0,1])
HG is ([2,0,0,0,0,0,0,0,0,0,29,6,0,0,0,0,0,28,3,28,8,0,0,0,12,20,0,0,0,20,2,1,0,0,0, 0,0,0,0,0,0,0,0,0]; [7,0,0,0,7,9,0,16,0,5,0,0,24,0,0,0,0,17,0,0,0,27,0,0,0,0,0,0,8,3, 0,1,1,0,0,0,0,0,0,0,0,0,0,0]; [0,22,0,23,11,22,0,0,25,12,0,0,0,0,0,0,21,0,0,0,0,0,0, 0,0,0,16,2,22,0,0,0,1,1,0,0,0,0,0,0,0,0,0,0]; [0,25,7,0,0,0,1,0,14,0,0,0,0,0,27,16, 23,0,27,0,0,0,0,27,0,30,0,0,0,0,0,0,0,1,1,0,0,0,0,0,0,0,0,0]; [0,19,0,3,0,12,0,0,30, 0,0,0,0,0,0,28,0,0,28,0,0,0,28,0,0,22,0,0,0,29,1,0,0,0,1,1,0,0,0,0,0,0,0.0]; [0,0,9, 0,0,0,0,4,0,0,0,0,22,21,4,9,29,0,0,0,0,0,7,14,0,0,0,15,0,0,0,0,0,0,0,1,1,0,0,0,0,0, 0,0]; [24,0,0,0,0,0,0,0,0,0,12,25,28,29,30,0,0,0,0,18,20,13,0,11,0,0,0,0,0,0,0,0,0, 0,0,0,1,0,0,0,0,0,0]; [0,29,0,0,0,4,6,0,25,60,0,0,0,0,0,0,0,0,11,0,29,0,0,5,0,12, 0,7,0,0,0,0,0,0,0,0,1,1,0,0,0,0,0]; [0,0,28,0,0,0,28,0,0,0,10,0,0,28,0,0,10,0,0,14, 2,0,0,0,22,0,14,8,0,0,0,00,0,0,0,0,0,1,1,0,0,0,0]; [0,0,0,7,19,0,0,22,0,0,6,4,0,0,0, 0,0,7,0,0,5,0,20,0,0,0,0,5,0,8,2,0,0,0,0,0,0,0,0,1,0,0,0,0]; [0,0,0,9,0,0,0,0,0,0,0, 27,0,0,12,0,0,0,0,0,0,0,21,0,0,0,0,0,0,0,0,0,0,14,0,0,17,22,0,0,2,1,0,0]; [27,0,0,0, 0,0,0,0,0,0,0,0,15,21,0,0,0,0,18,0,0,0,0,0,0,24,0,0,0,0,0,18,12,0,0,11,0,0,0,0,1,1, 1,0]; [0,0,0,0,0,0,20,0,0,0,0,0,0,0,0,0,0,0,0,0,0,0,0,0,0,0,0,0,0,0,0,0,4,26,30,0,0, 0,0,17,0,0,1,1]; [0,0,0,0,8,0,0,0,0,1,0,0,0,0,0,0,0,11,0,0,0,0,0,0,12,0,0,0,13,0,0,0, 0,0,0,0,0,0,12,0,2,0,0,1]);
HH is ([0,0,0, 23,0,0,0,0,12,25,12,24,0,0,0,0,23,0,0,0,3,13,0,13,0,28,0,15,11,0,0, 29,2,1,0,0,0,0,0,0,0,0,0,0]; [0,0, 21,0,0,14,0,25,0,0,0,14,0,0,14,14,27,0,0,1,0,19,7, 0,28,0,0,0,0,8,8,0,0,1,1,0,0,0,0,0,0,0,0,0]; [19,0,16,0,0,5,0,18,0,0,0,0,6,2,0,17,0, 0,14,20,0,0,25,0,13,0,4,0,0,6,0,0,0,0,1,1,0,0,0,0,0,0,0]; [24,1,0,20,29,0,30,0,14, 0,28,0,0,0,0,0,0,2,20,0,0,0,0,17,0,0,0,0,22,0,0,6,1,0,0,1,1,0,0,0,0,0,0,0]; [15,11, 11,0,23,27,14,0,0,0,0,0,0,9,15,0,0,30,0,0,0,0,13,0,2,0,27,0,0,0,7,0,0,0,0,0,1,1,0, 0,0,0,0,0]; [0,0,10,0,0,0,0,20,0,14,0,22,9,14,0,28,0,0,0,17,0,0,0,0,19,19,8,2,0,15, 0,0,0,0,0,0,0,1,1,0,0,0,0,0]; [0,0,0,0,0,0,0,0,23,18,2,0,23,0,0,0,0,0,13,0,13,0,0, 0,13,0,3,2,0,0,3,0,0,0,0,0,0,1,1,0,0,0,0]; [0,19,0,9,6,0,20,0,0,0,19,0,0,0,27,0,24, 17,0,0,12,9,0,12,0,0,0,0,6,0,10,0,2,0,0,0,0,0,0,1,0,0,0,0]; [0,0,0,11,14,0,0,0,0,0, 0,0,0,29,0,0,0,0,0,0,0,0,0,4,0,0,13,0,0,0,0,0,2,0,0,11,28,25,0,0,2,1,0,0]; [0,0,0,0, 0,25,0,0,0,0,0,0,0,0,0,0,2,0,0,0,0,0,23,0,0,0,0,0,0,0,0,0,0,19,23,0,0,0,0,2,1,1,1, 0]; [0,0,0,0,0,0,0,0,28,0,0,0,0,0,0,0,0,0,0,0,0,0,0,0,0,0,0,0,0,0,0,0,0,1,0,0,3,8,5, 0,0,0,1,1]; [0,0,0,0,0,0,0,1,0,0,0,0,0,0,0, 6,0,0,19,16,0,0,0,0,0,0,0,0,0,6,0,0,0,0, 18,7,0,0,17,9,2,0,0,1]); and
HI is ([0,0,0,0,24,0,25,0,0,0,0,0,0,0,12,0,0,0,0,0,0,0,0,0,0,0,0,0,0,30,0,0,0,0,0,0, 0,0,0,0,2,1,0,0]; [0,0,0,0,0,0,0,0,0,0,0,0,0,19,0,0,0,0,5,0,0,18,0,0,0,0,0,0,0,0,0,0, 0,0,0,0,0,0,0,0,1,1,1,0]; [0,0,6,0,0,0,0,0,0,0,0,0,16,0,0,0,0,3,0,0,0,0,0,0,0,0,0,7, 0,0,0,0,0,0,0,0,0,0,1,1]; [18,0,0,0,0,0,0,0,0,0,0,13,0,0,0,0,0,0,0,0,0,11,0,0, 0,0,4,0,0,0,0,0,0,0,0,0,0,0,0,0,0,2,0,0,1]).

25. A method for receiving information, the method comprising:
attempting to receive a first codeword portion and a second codeword portion of a transmitted codeword, wherein the first codeword portion is of a first length;
selecting between a first parity check process and a second parity check process, wherein the first parity check process comprises parity check of messages of the first length and the second parity check process comprises parity check for longer messages; and
decoding at least a portion of the codeword by the selected parity check process, to receive a decoded data bit vector.

26. The method according to claim 25, comprising attempting to receive the first codeword portion in a first communication channel, and attempting to receive the second codeword portion in at least one sub-channel of the first communication channel in which the first codeword portion is not transmitted.

27. The method according to claim 25, comprising selecting between the first parity check process which is a first low-density parity check (LDPC) process and the second parity check process which is a second LDPC process.

28. The method according to claim 25, comprising selecting between a first parity check process which is equivalent to processing the first codeword portion based on a first parity check matrix and a second parity check process which is equivalent to processing the codeword based on a second parity check matrix that comprises the first parity check matrix, wherein the second parity check process may be equivalent to multiplying the codeword by the second parity check matrix H′, for a matrix H′ that includes elements P_{i,j}, wherein each of the elements P_{i,j} contains: (a) the value “0” if P_{i,j} represents a 30×30 zero matrix; or (b) a value equal to 1+s if P_{i,j}=I^{s}, wherein I^{s} is one of a set of 30×30 permutation matrices; wherein each permutation matrix is a cyclically right shifted identity matrix, denoted as I^{s} for a shift s, where s is an integer between 0 and 29, wherein the matrix H′ is representable as an ordered set of vectors selected from a group of ordered sets of vectors that consists the order sets of vectors HE, HF, HG, and HH, wherein the first bits of the codewords are the bits of the data bit vector; wherein:
HE is ([0,0,0,0,21,0,0,24,0,1,0,0,0,0,0,0,0,4,0,0,2,1,0,0,0,0,0,0,0,0,0,0,0,0,0,0,0, 0,0,0,0,0,0,0]; [0,0,20,19,0,18,0,0,0,0,0,0,0,14,0,0,0,0,0,0,0,1,1,0,0,0,0,0,0,0,0,0,0,0,0,0,0,0, 0,0,0,0,0,0,0,0,0,0,0,0]; [0,0,0,0,23,14,20,0,0,0,0,0,0,0,0,0,0,13,0,0,0,1,1,0,0,0, 0,0,0,0,0,0,0,0,0,0,0,0,0,0,0,0,0]; [4,0,0,0,0,0,0,14,0,0,0,0,0,0,0,0,29,17,0,0,0,0, 0,1,1,0,0,0,0,0,0,0,0,0,0,0,0,0,0,0,0,0,0,0]; [0,0,4,11,0,0,0,0,2,0,0,0,0,12,0,0,0,0, 0,0,0,0,0,0,1,1,0,0,0,0,0,0,0,0,0,0,0,0,0,0,0,0,0]; [0,0,0,0,9,0,0,0,0,0,0,0,0,0,0, 11,0,11,14,0,0,0,0,0,0,1,1,0,0,0,0,0,0,0,0,0,0,0,0,0,0,0,0,0]; [0,0,0,0,0,0,0,0,0,13, 0,14,0,7,0,0,20,0,0,0,0,0,0,0,0,0,1,1,0,0,0,0,0,0,0,0,0,0,0,0,0,0,0,0]; [0,0,0,0,6,0, 28,0,9,0,0,25,0,0,0,0,0,0,0,0,0,0,0,0,0,0,0,1,1,0,0,0,0,0,0,0,0,0,0,0,0,0,0,0]; [0,0, 0,0,0,24,0,0,0,0,0,0,0,15,0,0,15,23,0,0,0,0,0,0,0,0,1,1,0,0,0,0,0,0,0,0,0,0,0, 0,0,0]; [0,3,0,0,0,0,16,29,0,0,0,0,0,0,0,0,0,0,0,0,1,0,0,0,0,0,0,0,0,1,1,0,0,0,0,0,0, 0,0,0,0,0,0,0]; [0,0,0,14,0,0,0,0,18,0,0,0,0,0,0,0,0,0,0,19,0,0,0,0,0,0,0,0,0,0,1,1, 0,0,0,0,0,0,0,0,0,0,0,0]; [0,0,0,0,0,0,0,0,0,2,0,0,2,2,21,0,0,0,0,0,0,0,0,0,0,0,0,0, 0,0,0,1,1,0,0,0,0,0,0,0,0,0,0,0]; [0,7,0,0,0,0,0,0,0,0,0,1,23,0,0,0,22,0,0,0,0,0,0,0, 0,0,0,0,0,0,0,0,1,1,0,0,0,0,0,0,0,0,0,0]; [0,0,0,0,0,0,0,0,0,0,0,26,26,0,11,0,0,0,0, 4,0,0,0,0,0,0,0,0,0,0,0,0,0,1,1,0,0,0,0,0,0,0,0,0]; [8,0,11,0,0,0,0,0,0,0,0,0,0,0,0, 8,0,0,0,0,0,0,0,0,0,0,0,0,0,0,0,0,0,0,1,1,0,0,0,0,0,0,0,0]; [0,20,5,3,0,0,0,0,0,0,0, 0,0,0,0,0,0,0,0,18,0,0,0,0,0,0,0,0,0,0,0,0,0,0,0,1,1,0,0,0,0,0,0,0][15,0,0,0,0,0,0, 0,27,0,17,0,0,0,17,0,0,0,0,0,0,0,0,0,0,0,0,0,0,0,0,0,0,0,0,0,1,1,0,0,0,0,0,0]; [0,0,0,0,0,4,0,0,0,18,25,0,0,0,0,0,0,0,22,0,0,0,0,0,0,0,0,0,0,0,0,0,0,0,0,0,1,1,0,0,0, 0,0]; [0,24,0,0,0,0,0,0,0,0,0,0,16,0,16,0,0,0,0,0,0,0,0,0,0,0,0,0,0,0,0,0,0,0,0,0,0, 0,1,1,0,0,0,0]; [0,0,0,0,0,0,0,7,0,0,20,0,0,0,0,26,0,5,0,0,2,0,0,0,0,0,0,0,0,0,0,0,0, 0,0,0,0,0,0,1,0,0,0,0]; [0,0,0,0,0,0,13,0,0,0,0,20,0,0,0,0,1,0,0,0,0,0,0,0,0,0,0,21, 0,0,0,0,0,0,0,0,0,0,0,0,2,1,0,0]; [0,0,0,0,0,0,0,0,0,12,0,0,0,0,0,0,0,0,0,10,0,0,0, 19,0,0,0,0,0,0,0,0,0,0,0,0,0,0,0,0,1,1,1,0]; [0,0,2,0,0,0,0,0,0,0,0,0,0,0,0,3,0,0,0, 0,5,0,0,0,0,10,0,0,0,0,0,0,0,0,0,0,0,0,0,0,0,0,1,1]; [19,0,0,0,0,0,0,0,16,0,0,0,26,0, 3,0,0,0,0,0,0,0,0,0,0,0,0,0,0,0,0,0,0,0,0,0,0,0,0,0,2,0,0,1]);
HF is ([0,0,0,0,13,0,0,0,0,18,11,0,14,0,9,0,0,0,20,0,0,0,0,22,0,2,1,0,0,0,0,0,0,0,0, 0,0,0 0,0,0,0,0,0]; [0,0,0,0,0,20,24,4,24,0,8,0,0,0,0,0,0,0,6,0,0,0,0,0,0,0,1,1,0,0, 0,0,0,0,0,0,0,0,0,0,0,0,0,0]; [0,0,0,0,0,0,0,0,0,0,0,0,0,23,0,0,0,1,11,29,17,27,0,0, 0,0,0,1,1,0,0,0,0,0,0,0,0,0,0,0,0,0,0,0]; [0,0,7,18,0,0,0,21,0,0,0,22,0,0,0,29,0,0,0, 1,0,26,0,0,0,0,0,0,1,1,0,0,0,0,0,0,0,0,0,0,0,0,0,0]; [0,0,19,1,0,0,0,0,0,0,0,0,0,0, 22,0,24,0,0,0,0,0,15,0,6,0,0,0,0,1,1,0,0,0,0,0,0,0,0,0,0,0,0,0]; [26,3,8,0,0,16,9,0, 0,0,0,0,0,0,28,0,0,0,0,0,0,0,0,0,0,0,0,0,0,0,1,1,0,0,0,0,0,0,0,0,0,0,0,0]; [4,0,0,0, 0,12,22,0,18,0,0,0,9,7,0,0,27,0,0,0,0,0,0,0,0,0,0,0,0,0,0,1,1,0,0,0,0,0,0,0,0,0,0, 0]; [0,12,0,0,1,0,0,0,0,0,0,0,21,0,0,17,0,0,0,0,4,0,0,4,0,1,0,0,0,0,0,0,1,1,0,0,0,0, 0,0,0,0,0,0]; [0,0,0,8,0,0,0,0,28,0,8,21,0,0,0,4,0,0,0,0,0,0,12,0,0,0,0,0,0,0,0,0,0, 1,1,0,0,0,0,0,0,0,0,0]; [0,0,0,0,0,0,0,0,0,7,26,0,0,0,23,0,0,0,0,0,0,0,9,3,28,0,0,0, 0,0,0,0,0,0,1,1,0,0,0,0,0,0,0,0]; [9,0,0,0,0,0,0, 30,29,0,0,0,0,10,0,0,0,7,0,0,0,4,0, 0,0,0,0,0,0,0,0,0,0,0,0,1,1,0,0,0,0,0,0,0]; [0,0,0,0,8,0,0,0,0,0,0,0,8,0,0,0,12,0,0, 0,2,0,0,14,12,0,0,0,0,0,0,0,0,0,0,0,1,1,0,0,0,0,0,0]; [0,0,6,20,17,0,0,2,0,0,0,17,0, 0,0,26,0,0,0,0,0,0,0,0,0,0,0,0,0,0,0,0,0,0,0,0,0,1,1,0,0,0,0,0]; [0,6,0,0,0,30,30,0, 0,0,0,0,0,0,0,0,24,0,0,0,24,0,16,0,0,0,0,0,0,0,0,0,0,0,0,0,0,0,1,1,0,0,0,0]; [0,0,0, 0,0,0,0,0,0,6,0,30,0,5,0,0,0,27,0,21,0,1,0,0,0,2,0,0,0,0,0,0,0,0,0,0,0,0,0,1,0,0,0, 0]; [0,0,0,0,0,0,0,0,0,0,0,0,0,0,0,0,8,0,0,0,0,0,0,9,0,0,0,0,0,26,0,2,25,14,0,0,6, 0,0,2,1,0,0]; [0,0,0,0,0,0,0,0,0,0,0,0,0,0,0,0,20,0,0,0,0,0,0,0,0,9,15,0,0,29,13,0,0, 29,0,0,0,0,0,0,1,1,1,1,0]; [18,0,0,0,0,22,0,17,0,0,0,0,0,0,0,0,0,0,3,0,0,0,0,0,0,0,22, 0,2,10,0,0,0,0,0,0,0,0,0,0,0,0,1,1]; [0,0,0,0,0,0,0,0,0,8,0,29,0,0,0,0,0,0,17,4,0,0, 0,0,0,0,0,0,0,0,0,0,0,0,0,0,0,19,17,2,0,0,1]);
HG is ([2,0,0,0,0,0,0,0,0,0,29,6,0,0,0,0,0,28,3,28,8,0,0,0,12,20,0,0,0,20,2,1,0,0,0, 0,0,0,0,0,0,0,0,0]; [7,0,0,0,7,9,0,16,0,5,0,0,24,0,0,0,0,17,0,0,0,27,0,0,0,0,0,0,8,3, 0,1,1,0,0,0,0,0,0,0,0,0,0,0]; [0,22,0,23,11,22,0,0,25,12,0,0,0,0,0,0,21,0,0,0,0,0,0, 0,0,0,16,2,22,0,0,0,1,1,0,0,0,0,0,0,0,0,0,0]; [0,25,7,0,0,0,10,14,0,0,0,0,0,27,16, 23,0,27,0,0,0,0,27,0,30,0,0,0,0,0,0,0,1,1,0,0,0,0,0,0,0,0,0]; [0,19,0,3,0,12,0,0,30, 0,0,0,0,0,0,28,0,0,28,0,0,0,28,0,0,22,0,0,0,29,1,0,0,0,1,1,0,0,0,0,0,0,0,0]; [0,0,9, 0,0,0,0,4,0,0,0,0,22,21,4,9,29,0,0,0,0,0,7,14,0,0,0,15,0,0,0,0,0,0,0,1,1,0,0,0,0,0, 0,0]; [24,0,0,0,0,0,0,0,0,0,12,25,28,29,30,0,0,0,0,18,20,13,0,11,0,0,0,0,0,0,0,0,0, 0,0,0,1,1,0,0,0,0,0,0]; [0,29,0,0,0,4,6,0,25,6,0,0,0,0,0,0,0,0,0,11,0,29,0,0,5,0,12, 0,7,0,0,0,0,0,0,0,0,1,1,0,0,0,0,0]; [0,0,28,0,0,0,28,0,0,0,10,0,0,28,0,0,10,0,0,14, 2,0,0,0,22,0,14,8,0,0,0,0,0,0,0,0,0,0,1,1,0,0,0,0]; [0,0,0,7,19,0,0,22,0,0,6,4,0,0,0, 0,0,7,0,0,5,0,20,0,0,0,0,5,0,8,2,0,0,0,0,0,0,0,0,1,0,0,0,0]; [0,0,0,9,0,0,0,0,0,0,0, 27,0,0,12,0,0,0,0,0,0,0,21,0,0,0,0,0,0,0,0,0,0,14,0,0,17,22,0,0,2,1,0,0]; [27,0,0,0, 0,0,0,0,0,0,0,0,15,21,0,0,0,0,18,0,0,0,0,0,0,24,0,0,0,0,0,18,12,0,0,11,0,0,0,0,1,1, 1,0]; [0,0,0,0,0,0,20,0,0,0,0,0,0,0,0,0,0,0,0,0,0,0,0,0,0,0,0,0,0,0,0,0,4,26,30,0,0, 0,0,17,0,0,1,1]; [0,0,0,0,8,0,0,0,0,1,0,0,0,0,0,0,0,11,0,0,0,0,0,0,12,0,0,0,13,0,0,0, 0,0,0,0,0,0,12,0,2,0,0,1]); and
HH is ([0,0,0,23,0,0,0,0,12,25,12,24,0,0,0,0,23,0,0,0,3,13,0,13,0,28,0,15, 11,0,0, 29,2,1,0,0,0,0,0,0,0,0,0,0]; [0,0,21,0,0,14,0,25,0,0,0, 14,0,0,14,14,27,0,0,1,0,19,7, 0,28,0,0,0,0,8,8,0,0,1,1,0,0,0,0,0,0,0,0,0]; [19,0,16,0,0,5,0,18,0,0,0,0,6,2,0,17,0, 0,14,20,0,0,25,0,13,0,4,0,0,6,0,0,0,0,1,1,0,0,0,0,0,0,0,0]; [24,1,0,20,29,0,30,0,14, 0,28,0,0,0,0,0,0,2,20,0,0,0,0,17,0,0,0,0,22,0,0,6,1,0,0,1,1,0,0,0,0,0,0,0]; [15,11, 11,0,23,27,14,0,0,0,0,0,0,9,15,0,0,30,0,0,0,0,13,0,2,0,27,0,0,0,7,0,0,0,0,0,1,1,0, 0,0,0,0,0]; [0,0,10,0,0,0,0,20,0,14,0,22,9,14,0,28,0,0,0,17,0,0,0,0,19,19,8,2,0,15, 0,0,0,0,0,0,0,1,1,0,0,0,0,0]; [0,0,0,0,0,0,0,0,23,18,2,0,23,0,0,0,0,0,13,0,13,0,0,0, 0,13,0,3,2,0,0,3,0,0,0,0,0,0,1,1,0,0,0,0]; [0,19,0,9,6,0,20,0,0,0,19,0,0,0,27,0,24, 17,0,0,12,9,0,12,0,0,0,0,6,0,10,0,2,0,0,0,0,0,0,1,0,0,0,0]; [0,0,0,11,14,0,0,0,0,0, 0,0,0,29,0,0,0,0,0,0,0,0,0,4,0,0,13,0,0,0,0,0,2,0,0,11,28,25,0,0,2,1,0,0]; [0,0,0,0, 0,25,0,0,0,0,0,0,0,0,0,0,2,0,0,0,0,0,23,0,0,0,0,0,0,0,0,0,0,19,23,0,0,0,0,2,1,1,1, 0]; [0,0,0,0,0,0,0,0,28,0,0,0,0,0,0,0,0,0,0,0,0,0,0,0,0,0,0,0,0,0,0,0,0,1,0,0,3,8,5, 0,0,0,1,1]; [0,0,0,0,0,0,0,1,0,0,0,0,0,0,6,0,0,19,16,0,0,0,0,0,0,0,0,0,6,0,0,0,0, 18,7,0,0,17,9,2,0,0,1]).
